(19) United States
(12) Patent Application Publication
(10) Pub. No.: US 2014/0353740 A1
(43) Pub. Date: Dec. 4, 2014

(54) SEMICONDUCTOR DEVICE AND MANUFACTURING METHOD THEREOF

(71) Applicant: Renesas Electronics Corporation, Kawasaki-shi (JP)

(72) Inventors: Akio Nishida, Kanagawa (JP); Kota Funayama, Kanagawa (JP)

(73) Assignee: Renesas Electronics Corporation, Kawasaki-shi (JP)

(21) Appl. No.: 14/283,245

(22) Filed: May 21, 2014

(30) Foreign Application Priority Data
May 29, 2013 (JP) 2013-113328

(51) Int. Cl. H01L 27/115; H01L 21/8238; H01L 27/12; H01L 29/78

(52) U.S. Cl. CPC H01L 27/11568; H01L 29/7831; H01L 21/823814; H01L 27/1203
USPC 257/326; 438/154

(57) ABSTRACT

Improvements are achieved in the characteristics of a semiconductor device having a nonvolatile memory (MONOS). In a SOI substrate having a supporting substrate, an insulating layer formed thereover, and a silicon layer formed thereover, the MONOS is formed. The MONOS has a control gate electrode and a memory gate electrode formed so as to be adjacent to the control gate electrode above the semiconductor layer. The MONOS also has a first impurity region formed in the supporting substrate under the control gate electrode and a second impurity region formed in the supporting substrate under the memory gate electrode and having an effective carrier concentration lower than that of the first impurity region. By thus providing the first and second impurity regions for adjusting the respective thresholds of the control transistor and the memory transistor, variations in the thresholds of the individual transistors are reduced to reduce GiDL.

### CROSS-REFERENCE TO RELATED APPLICATIONS

The disclosure of Japanese Patent Application No. 2013-113328 filed on May 29, 2013 including the specification, drawings and abstract is incorporated herein by reference in its entirety.

### BACKGROUND

The present invention relates to a semiconductor device and a manufacturing method thereof which can be used appropriately for, e.g., a semiconductor device having a nonvolatile memory.

As an electrically writable/erasable nonvolatile semiconductor storage device, an EEPROM (Electrically Erasable and Programmable Read Only Memory) has been used widely. For example, there is a nonvolatile semiconductor storage device of a type which has, under the gate electrode of a MISFET, a conductive floating gate or a trapping insulating film surrounded by an oxide film. A charge stored state in the floating gate or the trapping insulating film is used as stored information, which is read as the threshold of the transistor.

There is a split-gate storage device using a MONOS (Metal-Oxide-Nitride-Oxide-Semiconductor) film which uses, as the trapping insulating, film, an insulating film capable of storing therein charges, such as a silicon nitride film, and in which the threshold of the MISFET is shifted by the injection/release of charges into/from a charge storage region.

Japanese Unexamined Patent Publication No. 2008-159804 (Patent Document 1) discloses a nonvolatile semiconductor memory in which, over a SOI layer formed of a microcrystal layer, a NAND flash memory is formed and, over a semiconductor substrate, a peripheral transistor is formed.

Japanese Unexamined Patent Publication No. 2012-4374 (Patent Document 2) discloses a semiconductor device in which, in a semiconductor layer in a SOI region, a MISFET forming a SRAM is formed and, in a semiconductor substrate in a bulk region, a MISFET forming a circuit other than a memory is formed.

### RELATED ART DOCUMENTS

### Patent Documents

### [Patent Document 1]

Japanese Unexamined Patent Publication No. 2008-159804

### [Patent Document 2]

Japanese Unexamined Patent Publication No. 2012-4374

### SUMMARY

A split-gate storage device using a MONOS film has a control transistor and a memory transistor. The study conducted by the present inventors has proved that, in improving the performance of such a storage device, there is a room for improvement in the configuration of the device or the manufacturing process thereof.

Other problems and novel features of the present invention will become apparent from a statement in the present specification and the accompanying drawings.

The following is a brief description of the outline of a configuration shown in a representative embodiment disclosed in the present application.

A semiconductor device shown in the representative embodiment disclosed in the present application includes a substrate having a semiconductor substrate, an insulating layer formed thereover, and semiconductor layer formed thereover, a first gate electrode formed above the semiconductor layer, and a second gate electrode formed so as to be adjacent to the first gate electrode. The semiconductor device also includes a first semiconductor region formed in the semiconductor substrate under the first gate electrode, and a second semiconductor region formed in the semiconductor substrate under the second gate electrode and having an effective carrier concentration lower than that of the first semiconductor region.

Alternatively, the semiconductor device shown in the representative embodiment disclosed in the present application includes a first element and a second element each formed in a substrate having a semiconductor substrate having a first region and a second region, an insulating layer formed over the first region of the semiconductor substrate, and a semiconductor layer formed over the insulating layer.

The first element is formed in a main surface of the semiconductor layer located in the first region. The second element is formed in a main surface of the semiconductor substrate located in the second region.

The first element includes a first gate electrode formed above the semiconductor layer, and a second gate electrode formed so as to be adjacent to the first gate electrode. The first element also includes a first semiconductor region formed in the semiconductor substrate under the first gate electrode, and a second semiconductor region formed in the semiconductor substrate under the second gate electrode and having an effective carrier concentration lower than that of the first semiconductor region. The second element also includes a third gate electrode formed above the semiconductor substrate.

A method of manufacturing the semiconductor device shown in the representative embodiment disclosed in the present application includes the step of ion-implanting an impurity of a first conductivity type into the semiconductor substrate of the substrate including the semiconductor substrate, the insulating layer formed over the semiconductor substrate, and the semiconductor layer formed over the insulating layer through the semiconductor layer and the insulating layer to form the first semiconductor region. The method of manufacturing the semiconductor device also includes the step of forming the first gate electrode over the semiconductor layer located above the first semiconductor region via the first insulating film. The method of manufacturing the semiconductor device also includes the step of ion-implanting an impurity of a second conductivity type opposite to the first conductivity type using the first gate electrode as a mask to form the second semiconductor region in the first semiconductor region. The method of manufacturing the semiconductor device also includes the step of forming the second gate electrode over the semiconductor layer located above the semiconductor region via the second insulating film.

The semiconductor device shown in the representative embodiment disclosed in the present application allows improvements in the characteristics of the semiconductor device.

The method of manufacturing the semiconductor device shown in the representative embodiment disclosed in the present application allows the semiconductor device having excellent characteristics to be manufactured.

### BRIEF DESCRIPTION OF THE DRAWINGS

FIG. 1 is a plan view showing an example of a microcomputer chip (SOC) to which a semiconductor device of Embodiment 1 is applied;

FIG. 2 is a cross-sectional view showing a configuration of the semiconductor device of Embodiment 1;

FIG. 3 is a cross-sectional view showing the configuration of the semiconductor device of Embodiment 1;

FIG. 4 is a cross-sectional view showing a configuration of a memory cell in the semiconductor device of Embodiment 1;

FIG. 5 is a cross-sectional view showing a manufacturing process of the semiconductor device of Embodiment 1;

FIG. 6 is a cross-sectional view showing the manufacturing process of the semiconductor device of Embodiment 1;

FIG. 7 is a cross-sectional view showing the manufacturing process of the semiconductor device of Embodiment 1, which is subsequent to FIG. 5;

FIG. 8 is a cross-sectional view showing the manufacturing process of the semiconductor device of Embodiment 1, which is subsequent to FIG. 6;

FIG. 9 is a cross-sectional view showing the manufacturing process of the semiconductor device of Embodiment 1, which is subsequent to FIG. 7;

FIG. 10 is a cross-sectional view showing the manufacturing process of the semiconductor device of Embodiment 1, which is subsequent to FIG. 8;

FIG. 11 is a cross-sectional view showing the manufacturing process of the semiconductor device of Embodiment 1, which is subsequent to FIG. 9;

FIG. 12 is a cross-sectional view showing the manufacturing process of the semiconductor device Embodiment 1, which is subsequent to FIG. 10;

FIG. 13 is a cross-sectional view showing the manufacturing process of the semiconductor device of Embodiment 1, which is subsequent to FIG. 11;

FIG. 14 is a cross-sectional view showing the manufacturing process of the semiconductor device of Embodiment 1, which is subsequent to FIG. 12;

FIG. 15 is a cross-sectional view showing the manufacturing process of the semiconductor device of Embodiment 1, which is subsequent to FIG. 13;

FIG. 16 is a cross-sectional view showing the manufacturing process of the semiconductor device of Embodiment 1, which is subsequent to FIG. 14;

FIG. 17 is a cross-sectional view showing the manufacturing process of the semiconductor device of Embodiment 1, which is subsequent to FIG. 15;

FIG. 18 is a cross-sectional view showing the manufacturing process of the semiconductor device of Embodiment 1, which is subsequent to FIG. 16;

FIG. 19 is a cross-sectional view showing the manufacturing process of the semiconductor device of Embodiment 1, which is subsequent to FIG. 17;

FIG. 20 is a cross-sectional view showing the manufacturing process of the semiconductor device of Embodiment 1, which is subsequent to FIG. 18;

FIG. 21 is a cross-sectional view showing the manufacturing process of the semiconductor device of Embodiment 1, which is subsequent to FIG. 19;

FIG. 22 is a cross-sectional view showing the manufacturing process of the semiconductor device of Embodiment 1, which is subsequent to FIG. 20;

FIG. 23 is a cross-sectional view showing the manufacturing process of the semiconductor device of Embodiment 1, which is subsequent to FIG. 21;

FIG. 24 is a cross-sectional view showing the manufacturing process of the semiconductor device of Embodiment 1, which is subsequent to FIG. 22;

FIG. 25 is a cross-sectional view showing the manufacturing process of the semiconductor device of Embodiment 1, which is subsequent to FIG. 23;

FIG. 26 is a cross-sectional view showing the manufacturing process of the semiconductor device of Embodiment 1, which is subsequent to FIG. 24;

FIG. 27 is a cross-sectional view showing the manufacturing process of the semiconductor device of Embodiment 1, which is subsequent to FIG. 25;

FIG. 28 is a cross-sectional view showing the manufacturing process of the semiconductor device of Embodiment 1, which is subsequent to FIG. 26;

FIG. 29 is a cross-sectional view showing the manufacturing process of the semiconductor device of Embodiment 1, which is subsequent to FIG. 27;

FIG. 30 is a cross-sectional view showing the manufacturing process of the semiconductor device of Embodiment 1, which is subsequent to FIG. 28;

FIG. 31 is a cross-sectional view showing the manufacturing process of the semiconductor device of Embodiment 1, which is subsequent to FIG. 29;

FIG. 32 is a cross-sectional view showing the manufacturing process of the semiconductor device of Embodiment 1, which is subsequent to FIG. 30;

FIG. 33 is a cross-sectional view showing the manufacturing process of the semiconductor device Embodiment 1, which is subsequent to FIG. 31;

FIG. 34 is a cross-sectional view showing the manufacturing process of the semiconductor device of Embodiment 1, which is subsequent to FIG. 32;

FIG. 35 is a cross-sectional view showing the manufacturing process of the semiconductor device of Embodiment 1, which is subsequent to FIG. 33;

FIG. 36 is a cross-sectional view showing the manufacturing process of the semiconductor device of Embodiment 1, which is subsequent to FIG. 34;

FIG. 37 is a cross-sectional view showing the manufacturing process of the semiconductor device of Embodiment 1, which is subsequent to FIG. 35;

FIG. 38 is a cross-sectional view showing the manufacturing process of the semiconductor device of Embodiment 1, which is subsequent to FIG. 36;

FIG. 39 is a cross-sectional view showing the manufacturing process of the semiconductor device of Embodiment 1, which is subsequent to FIG. 37;

FIG. 40 is a cross-sectional view showing the manufacturing process of the semiconductor device of Embodiment 1, which is subsequent to FIG. 38;

FIG. 41 is a cross-sectional view showing the manufacturing process of the semiconductor device of Embodiment 1, which is subsequent to FIG. 39;

FIG. 42 is a cross-sectional view showing the manufacturing process of the semiconductor device of Embodiment 1, which is subsequent to FIG. 40;

FIG. 43 is a cross-sectional view showing the manufacturing process of the semiconductor device of Embodiment 1, which is subsequent to FIG. 41;

FIG. 44 is a cross-sectional view showing the manufacturing process of the semiconductor device of Embodiment 1, which is subsequent to FIG. 42;

FIG. 45 is a cross-sectional view showing the manufacturing process of the semiconductor device of Embodiment 1, which is subsequent to FIG. 43;

FIG. 46 is a cross-sectional view showing the manufacturing process of the semiconductor device of Embodiment 1, which is subsequent to FIG. 44;

FIG. 47 is a cross-sectional view showing the manufacturing process of the semiconductor device of Embodiment 1, which is subsequent to FIG. 45;

FIG. 48 is a cross-sectional view showing the manufacturing process of the semiconductor device of Embodiment 1, which is subsequent to FIG. 46;

FIG. 49 is a cross-sectional view showing the manufacturing process of the semiconductor device of Embodiment 1, which is subsequent to FIG. 47;

FIG. 50 is a cross-sectional view showing the manufacturing process of the semiconductor device of Embodiment 1, which is subsequent to FIG. 48;

FIG. 51 is a cross-sectional view showing the manufacturing process of the semiconductor device of Embodiment 1, which is subsequent to FIG. 49;

FIG. 52 is a cross-sectional view showing the manufacturing process of the semiconductor device of Embodiment 1, which is subsequent to FIG. 50;

FIG. 53 is a cross-sectional view showing the manufacturing process of the semiconductor device of Embodiment 1, which is subsequent to FIG. 51;

FIG. 54 is a cross-sectional view showing the manufacturing process of the semiconductor device of Embodiment 1, which is subsequent to FIG. 52;

FIG. 55 is a cross-sectional view showing the manufacturing process of the semiconductor device of Embodiment 1, which is subsequent to FIG. 53;

FIG. 56 is a cross-sectional view showing the manufacturing process of the semiconductor device of Embodiment 1, which is subsequent to FIG. 54;

FIG. 57 is a cross-sectional view showing the manufacturing process of the semiconductor device of Embodiment 1, which is subsequent to FIG. 55;

FIG. 58 is a cross-sectional view showing the manufacturing process of the semiconductor device of Embodiment 1, which is subsequent to FIG. 56;

FIG. 59 is a cross-sectional view showing the manufacturing process of the semiconductor device of Embodiment 1, which is subsequent to FIG. 57;

FIG. 60 is a cross-sectional view showing the manufacturing process of the semiconductor device of Embodiment 1, which is subsequent to FIG. 58;

FIG. 61 is a plan view showing an example of a microcomputer chip (SOC) to which a semiconductor device of Embodiment 2 is applied;

FIG. 62 is an equivalent circuit diagram showing an example of a memory cell in a SRAM;

FIG. 63 is a cross-sectional view showing a configuration of the semiconductor device of Embodiment 2;

FIG. 64 is a cross-sectional view showing the configuration of the semiconductor device of Embodiment 2;

FIG. 65 is a cross-sectional view showing the configuration of the semiconductor device of Embodiment 2;

FIG. 66 is a cross-sectional view showing a manufacturing process of the semiconductor device of Embodiment 2;

FIG. 67 is a cross-sectional view showing the manufacturing process of the semiconductor device of Embodiment 2;

FIG. 68 is a cross-sectional view showing the manufacturing process of the semiconductor device of Embodiment 2;

FIG. 69 is a cross-sectional view showing the manufacturing process of the semiconductor device of Embodiment 2, which is subsequent to FIG. 66;

FIG. 70 is a cross-sectional view showing the manufacturing process of the semiconductor device of Embodiment 2, which is subsequent to FIG. 67;

FIG. 71 is a cross-sectional view showing the manufacturing process of the semiconductor device of Embodiment 2, which is subsequent to FIG. 68;

FIG. 72 is a cross-sectional view showing the manufacturing process of the semiconductor device of Embodiment 2, which is subsequent to FIG. 69;

FIG. 73 is a cross-sectional view showing the manufacturing process of the semiconductor device of Embodiment 2, which is subsequent to FIG. 70;

FIG. 74 is a cross-sectional view showing the manufacturing process of the semiconductor device of Embodiment 2, which is subsequent to FIG. 71;

FIG. 75 is a cross-sectional view showing the manufacturing process of the semiconductor device of Embodiment 2, which is subsequent to FIG. 72;

FIG. 76 is a cross-sectional view showing the manufacturing process of the semiconductor device of Embodiment 2, which is subsequent to FIG. 73;

FIG. 77 is a cross-sectional view showing the manufacturing process of the semiconductor device of Embodiment 2, which is subsequent to FIG. 74;

FIG. 78 is a cross-sectional view showing the manufacturing process of the semiconductor device of Embodiment 2, which is subsequent to FIG. 75;

FIG. 79 is a cross-sectional view showing the manufacturing process of the semiconductor device of Embodiment 2, which is subsequent to FIG. 76;

FIG. 80 is a cross-sectional view showing the manufacturing process of the semiconductor device of Embodiment 2, which is subsequent to FIG. 77;

FIG. 81 is a cross-sectional view showing the manufacturing process of the semiconductor device of Embodiment 2, which is subsequent to FIG. 78;

FIG. 82 is a cross-sectional view showing the manufacturing process of the semiconductor device of Embodiment 2, which is subsequent to FIG. 79;

FIG. 83 is a cross-sectional view showing the manufacturing process of the semiconductor device of Embodiment 2, which is subsequent to FIG. 80;

FIG. 84 is a cross-sectional view showing the manufacturing process of the semiconductor device of Embodiment 2, which is subsequent to FIG. 81;

FIG. 85 is a cross-sectional view showing the manufacturing process of the semiconductor device of Embodiment 2, which is subsequent to FIG. 82;

FIG. 86 is a cross-sectional view showing the manufacturing process of the semiconductor device of Embodiment 2, which is subsequent to FIG. 83;

FIG. 87 is a cross-sectional view showing the manufacturing process of the semiconductor device of Embodiment 2, which is subsequent to FIG. 84;

FIG. 88 is a cross-sectional view showing the manufacturing process of the semiconductor device of Embodiment 2, which is subsequent to FIG. 85;

FIG. 89 is a cross-sectional view showing the manufacturing process of the semiconductor device of Embodiment 2, which is subsequent to FIG. 86;

FIG. 90 is a cross-sectional view showing the manufacturing process of the semiconductor device of Embodiment 2, which is subsequent to FIG. 87;

FIG. 91 is a cross-sectional view showing the manufacturing process of the semiconductor device of Embodiment 2, which is subsequent to FIG. 88;

FIG. 92 is a cross-sectional view showing the manufacturing process of the semiconductor device of Embodiment 2, which is subsequent to FIG. 89;

FIG. 93 is a cross-sectional view showing another configuration of the semiconductor device of Embodiment 2;

FIG. 94 is a plan view showing a configuration of a semiconductor device of a first example of Embodiment 3;

FIG. 95 is a schematic cross-sectional view showing the configuration of the semiconductor device of the first example of Embodiment 3;

FIG. 96 is a plan view showing a configuration of a semiconductor device of a second example of Embodiment 3;

FIG. 97 is a schematic cross-sectional view showing the configuration of the semiconductor device of the second example of Embodiment 3;

FIG. 98 is a plan view showing a configuration of a semiconductor device of a third example of Embodiment 3; and

FIG. 99 is a schematic cross-sectional view showing the configuration of the semiconductor device of the third example of Embodiment 3.

### DETAILED DESCRIPTION

In the following embodiments, if necessary for the sake of convenience, the embodiments will be each described by being divided into a plurality of sections or embodiments. However, they are by no means irrelevant to each other unless particularly explicitly described otherwise, and one of the sections or embodiments is modifications, applications, detailed explanation, supplementary explanation, and so forth of part or the whole of the others. Also in the following embodiments, when the number and the like (including the number, numerical value, amount, range, and the like) of elements are referred to, they are not limited to specific numbers unless particularly explicitly described otherwise or unless they are obviously limited to the specific numbers in principle. The number and the like of the elements may be not less than or not more than the specific numbers.

Also in the following embodiments, the components thereof (including also elements, steps, and the like) are not necessarily indispensable unless particularly explicitly described otherwise or unless the components are considered to be obviously indispensable in principle. Likewise, if the shapes, positional relationships, and the like of the components and the like are referred to in the following embodiments, the shapes, positional relationships, and the like are assumed to include those substantially proximate or similar thereto and the like unless particularly explicitly described otherwise or unless it can be considered that they obviously do not in principle. The same shall apply in regard to the foregoing number and the like (including the number, numerical value, amount, range, and the like).

Hereinbelow, the embodiments will be described in detail with reference to the drawings. Note that, throughout all the drawings for illustrating the embodiments, members having the same functions are designated by the same or associated reference numerals, and a repeated description thereof is omitted. When there are a plurality of similar members (portions), marks may be added to general reference numerals to show individual or specific portions. Also, in the following embodiments, a description of the same or like parts will not be repeated in principle unless particularly necessary.

In the drawings used in the embodiments, hatching may be omitted even in a cross-sectional view for improved clarity of illustration, while even a plan view may be hatched for improved clarity of illustration.

In a cross-sectional view and a plan view, the sizes of individual portions do not correspond to those in a real device. For improved clarity of illustration, a specific portion may be shown in a relatively large size. Even when a plan view and a cross-sectional view correspond to each other, for improved clarity of illustration, individual portions may be shown in a relatively large, size.

### Embodiment 1

Referring now to the drawings, a description will be given below of a structure of a semiconductor device (semiconductor storage device) of the present embodiment.

<Description of Structure>

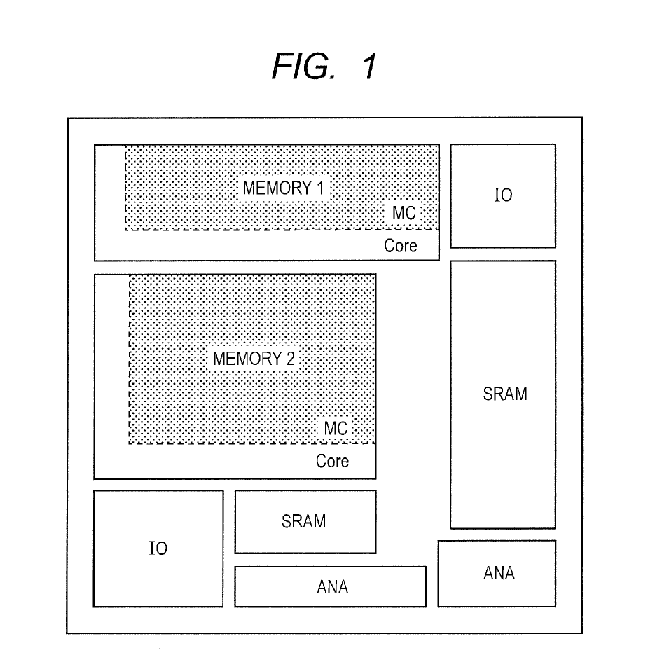

FIG. 1 is a plan view showing an example of a microcomputer chip (SOC for System-on-a-chip) to which the semiconductor device of the present embodiment is applied.

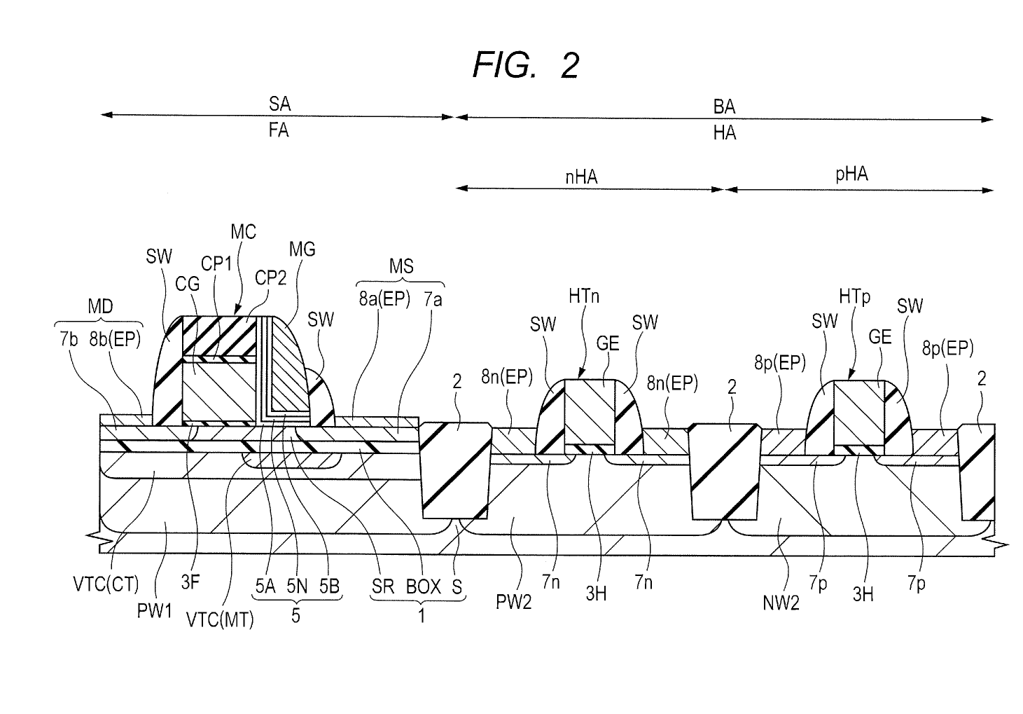

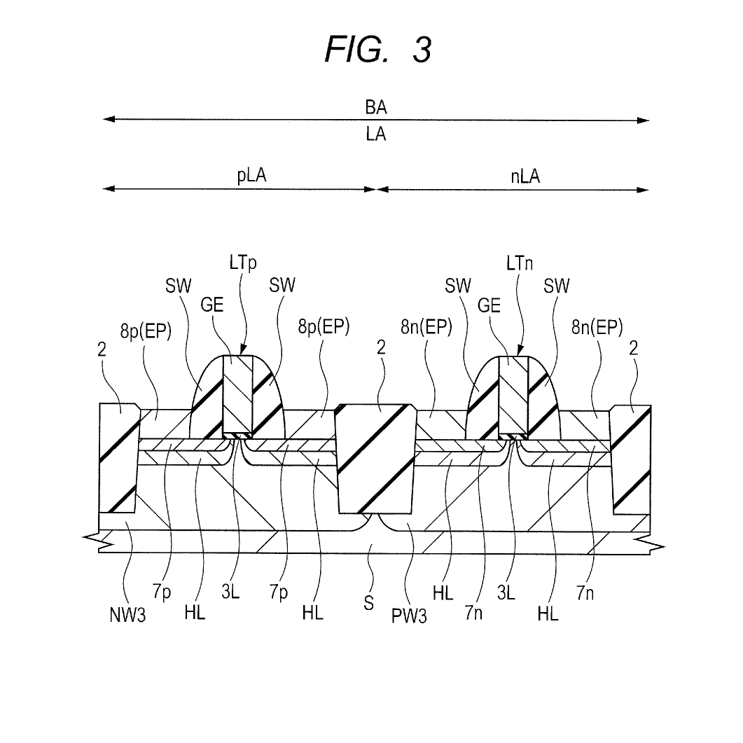

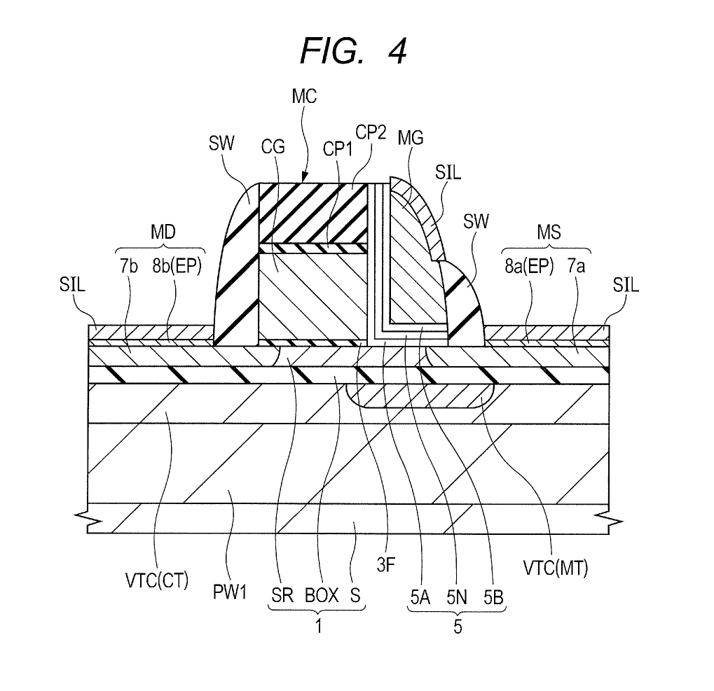

FIGS. 2 and 3 are cross-sectional views each showing a configuration of the semiconductor device of the present embodiment. FIG. 4 is a cross-sectional view showing a configuration of a memory cell in the semiconductor device of the present embodiment.

As shown in FIGS. 1 to 4, the semiconductor device of the present embodiment has memory cells MC formed in a SOI region SA of a SOI substrate 1 and elements other than the memories such as a MISFET formed in a bulk region BA thereof. MISFET is the abbreviation of Metal Insulator Semiconductor Field Effect Transistor and may also be referred to as MOS.

For example, in the microcomputer chip shown in FIG. 1, there are a first memory region (Memory 1) and a second memory region (Memory 2) in each of which the memory cell (referred to also as nonvolatile memory cell, nonvolatile storage element, nonvolatile semiconductor storage device, EEPROM, flash memory, FMONOS, or MONOS) MC is placed. Around the first memory region (Memory 1) and the second memory region (Memory 2), core regions (Core) are provided. In the core regions (Core), low-breakdown-voltage MISFETs (LTn and LTp) described later and the like are placed. Also in the microcomputer chip, IO regions (IO) are provided. In the IO regions (IO), high-breakdown-voltage MISFETs (HTn and HTp) described later or the like are placed. In the microcomputer chip, a SRAM region (SRAM) where a SRAM memory cell is placed, an analog region (ANA) where an analog circuit is placed, and the like are provided.

Here, in the present embodiment, each of the first memory region (Memory 1) and the second memory region (Memory 2) in which the memory cells MC are placed is assumed to be the SOI region (SA) and the other region is assumed to be the bulk region (BA). That is, the memory cells MC are formed in the SOI region (SA), while the other elements (low-breakdown-voltage MISFETs (LTn and LTp), high-breakdown-voltage MISFETs (HTn and HTp), SRAM memory cell, and analog circuit) are formed in the bulk region BA.

Referring to FIGS. 2 and 3, a more detailed description will be given below.

As shown in FIGS. 2 and 3, the semiconductor device of the present embodiment has the memory cells MC formed in the SOI region SA of the SOI substrate 1 and the four MISFETs (HTn, HTp, LTn, and LTp) formed in the bulk region BA thereof.

In the SOI region SA, a silicon layer (referred to also as SOI layer, semiconductor layer, semiconductor film, thin semiconductor film, or thin-film semiconductor region) SR is placed over a supporting substrate S via an insulating layer BOX. In the main surface of the silicon layer SR, the memory cells MC are formed.

In the bulk region BA, the insulating layer BOX and the silicon layer SR are not formed over the supporting substrate S. Accordingly, in the main surface of the supporting substrate S, the four MISFETs (HTn, HTp, LTn, and LTp) are formed.

Of the four MISFETs, the high-breakdown-voltage MISFETs (HTn and HTp) are formed in a high-breakdown-voltage MISFET formation region HA and the low-breakdown-voltage MISFETs (LTn and LTp) are formed in a low-breakdown-voltage MISFET formation region LA. Of the high-breakdown-voltage MISFETs (HTn and HTp), the high-breakdown-voltage n-channel MISFET (HTn) is formed in a region nHA and the high-breakdown-voltage p-channel MISFET (HTp) is formed in a region pHA. Of the low-breakdown-voltage MISFETs (LTn and LTp), the low-breakdown-voltage n-channel MISFET (LTn) is formed in a region nLA and the low-breakdown-voltage p-channel MISFET (LTp) is formed in a region pLA.

The low-breakdown-voltage MISFETs (LTn and LTp) have gate lengths smaller (shorter) than those of the high-breakdown-voltage MISFETs (HTn and HTp). For example, the gate lengths of the low-breakdown-voltage MISFETs (LTn and LTp) are about 50 nm. Such MISFETs having relatively small gate lengths are used for, e.g., a circuit (referred to also as core circuit or peripheral circuit) for driving the memory cells MC or the like.

On the other hand, the high-breakdown-voltage MISFETs (HTn and HTp) have gate lengths longer than those of the low-breakdown-voltage MISFETs (LTn and LTp). For example, the gate lengths of the high-breakdown-voltage MISFETs (HTn and HTp) are about 600 nm. Such MISFETs having relatively large gate lengths are used for, e.g., the input/output circuits (referred to also as I/O circuits) or the like.

The low-breakdown-voltage n-channel MISFET (LTn) has a gate electrode GE located over the supporting substrate S (p-type well PW3) via a gate insulating film 3L and source/drain regions located in the supporting substrate S (p-type well PW3) on both sides of the gate electrode GE. Over the side wall portions of the gate electrode GE, side-wall insulating films SW each made of an insulating film are formed. Each of the source/drain regions has an LDD structure and includes an n⁺-type semiconductor region 8n and an n⁻-type semiconductor region 7n.

The low-breakdown-voltage p-channel MISFET (LTp) has the gate electrode GE located over the supporting substrate S (n-type well NW3) via the gate insulating film 3L and source/drain regions located in the supporting substrate S type well NW3) on both sides of the gate electrode GE. Over the side wall portions of the gate electrode GE, the side-wall insulating films SW each made of an insulating film are formed. Each of the source/drain regions has an LDD structure and includes a p⁺-type semiconductor region 8p and a p⁻-type semiconductor region 7p.

The foregoing higher-concentration semiconductor regions (8n and 8p) have impurity concentrations higher than those of the foregoing lower-concentration semiconductor regions (7n and 7p) and are formed in epitaxial layers EP grown over the supporting substrate S on both sides of the gate electrode GE. Note that, here, halo regions (punch-through stoppers) HL each having a conductivity type opposite to that of each of the lower-concentration semiconductor regions (7n and 7p) are placed so as to surround the lower-concentration semiconductor regions (7n and 7p). That is, under the n⁻-type semiconductor regions 7n, the p-type halo regions HL are formed and, under the p⁻-type semiconductor regions 7p, the n-type halo regions HL are placed.

The high-breakdown-voltage n-channel MISFET (HTn) has the gate electrode GE located over the supporting substrate S (p-type well PW2) via a gate insulating film 3H and source/drain regions located in the supporting substrate (p-type well PW2) on both sides of the gate electrode GE. Over the side wall portions of the gate electrode GE, the side-wall insulating films SW each made of an insulating film are formed. Each of the source/drain regions has an LDD structure and includes the n⁺-type semiconductor region 8n and the n⁻-type semiconductor region 7n.

The high-breakdown-voltage p-channel MISFET (HTp) has the gate electrode GE located over the supporting substrate S (n-type well NW2) via the gate insulating film 3H and source/drain regions located in the supporting substrate (n-type well NW2) on both sides of the gate electrode GE. Over the side wall portions of the gate electrode GE, the side-wall insulating films SW each made of an insulating film are formed. Each of the source/drain regions has an LDD structure and includes the p⁺-type semiconductor region 8p and the p⁻-type semiconductor region 7p.

The foregoing higher-concentration semiconductor regions (8n and 8p) have impurity concentrations higher than those of the foregoing lower-concentration semiconductor regions (7n and 7p) and are formed in the epitaxial layers EP grown over the supporting substrate S on both sides of the gate electrodes GE.

Each of the memory cells MC has a control gate electrode (gate electrode) CG located above the silicon layer SR and a memory gate electrode (gate electrode) MG located above the silicon layer SR to be adjacent to the control gate electrode CG. Over the control gate electrode CG, a silicon oxide film CP1 and a silicon nitride film (cap insulating film) CP2 are placed. The memory cell MC further has a gate insulating film 3F located between the control gate electrode CG and the silicon layer SR and an insulating film 5 located between the memory gate electrode MG and the silicon layer SR and between the memory gate electrode MG and the control gate electrode CG.

The memory cell MC further has a source region MS and a drain region MD formed in the silicon layer SR. Over each of the side wall portions of a composite pattern of the memory gate electrode MG and the control gate electrode CG, the side-wall insulating films SW each made of an insulating film are formed. The source region MS includes an n⁺-type semiconductor region 8a and an n⁻-type semiconductor region 7a. The drain region MD includes an n⁺-type semiconductor region 8b and an n⁻-type semiconductor region 7b.

The foregoing higher-concentration semiconductor regions (8a and 8b) have impurity concentrations higher than those of the foregoing lower-concentration semiconductor regions (7a and 7b) and are formed in the epitaxial layers EP grown over the silicon layer SR on both sides of the foregoing composite pattern.

In the memory cell MC of the present embodiment, in the supporting substrate S located under the control gate electrode CG and under the insulating layer BOX, an impurity region VTC(CT) for adjusting the threshold of the control transistor is formed. In addition, in the supporting substrate S located under the memory gate electrode MG and under the insulating layer BOX, an impurity region VTC(MT) for adjusting the threshold of the memory transistor is formed.

As shown in FIG. 4, the impurity region VTC(MT) for adjusting the threshold of the memory transistor is shallower than the impurity region VTC(CT) for adjusting the threshold of the control transistor. In other words, the bottom surface of the impurity region VTC(MT) for adjusting the threshold of the memory transistor is located at a position shallower than that of the bottom surface of the impurity region VTC(CT) for adjusting the threshold of the control transistor.

The impurity region VTC(MT) for adjusting the threshold of the memory transistor has an impurity concentration lower than that of the impurity region VTC(CT) for adjusting the threshold of the control transistor. In other words, the impurity region VTC(MT) for adjusting the threshold of the memory transistor has an effective carrier concentration lower than that of the impurity region VTC(CT) for adjusting the threshold of the control transistor.

Here, each of the memory gate electrode MG and the control gate electrode CG contains an n-type impurity (such as, e.g., arsenic (As) or phosphorus (P)) and, as the impurity region VTC(MT) for adjusting the threshold of the memory transistor and the impurity region VTC(CT) for adjusting the threshold of the control transistor, p-type impurity regions are used. As a p-type impurity, e.g., boron (B) or the like can be used.

For example, the impurity region VTC(MT) for adjusting the threshold of the memory transistor is a p⁻⁻-type impurity region and the impurity region VTC(CT) for adjusting the threshold of the control transistor is a p⁻-type impurity region. The p⁻⁻-type means having an effective concentration of a p-type impurity which is lower than that of the p⁻-type.

Specifically, the impurity region VTC(CT) for adjusting the threshold of the control transistor is a region in which a p-type impurity (such as, e.g., boron (B)) has been ion-implanted and the impurity region VTC(MT) for adjusting the threshold of the memory transistor is a region in which, in addition to a p-type impurity (such as, e.g., boron (B)), an n-type impurity (such as, e.g., arsenic (As) or phosphorus (P)) of the conductivity type opposite to the p-type has been implanted.

Thus, in the present embodiment, the memory cells MC are placed in the SOI region SA and the impurity region VTC(CT) for adjusting the threshold of the control transistor and the impurity region VTC(MT) for adjusting the threshold of the memory transistor are provided therein. This can improve the performance of each of the memory cells MC. Specifically, variations in the thresholds of the control transistor and the memory transistor can be reduced. In addition, a GiDL (Gate Induced Drain Leakage) can be reduced.

That is, by providing the impurity regions for threshold adjustment, an increase in the concentration of the impurity in the silicon layer SR can be avoided. This can reduce random variations determined by the impurity concentration in the substrate (which is the silicon layer SR herein) and reduce threshold variations. Since an increase in the concentration of the impurity in the silicon layer SR can be avoided by providing the impurity regions for threshold adjustment, the GiDL can also be reduced. The GiDL is a leakage current in a transistor resulting from the formation of a thin depletion layer due to an electric field concentrated on an overlapping portion between a gate electrode and a drain and from the tunneling of electrons from the valence band to the conduction band. In addition, since the leakage current resulting from the GiDL can be reduced, it is possible to improve disturb in each of the memory cells MC. The disturb is a phenomenon in which stored charges fluctuate due to the voltage applied to each of nodes during a write/read operation to the memory cell MC.

On the other hand, in the present embodiment, the low-breakdown-voltage MISFETs (LTn and LTp) provided in the core regions (Core) around the memory regions and the high-breakdown-voltage MISFETs (HTn and HTp) provided in the IO regions (IO) are formed in the bulk region (BA). This eliminates the need for design for newly forming such MISFETs in the SOI region SA. As a result, it is possible to provide a semiconductor device having a lower margin-related failure rate in a shorter period by re-designing only the memory cell portions.

<Description of Manufacturing Method>

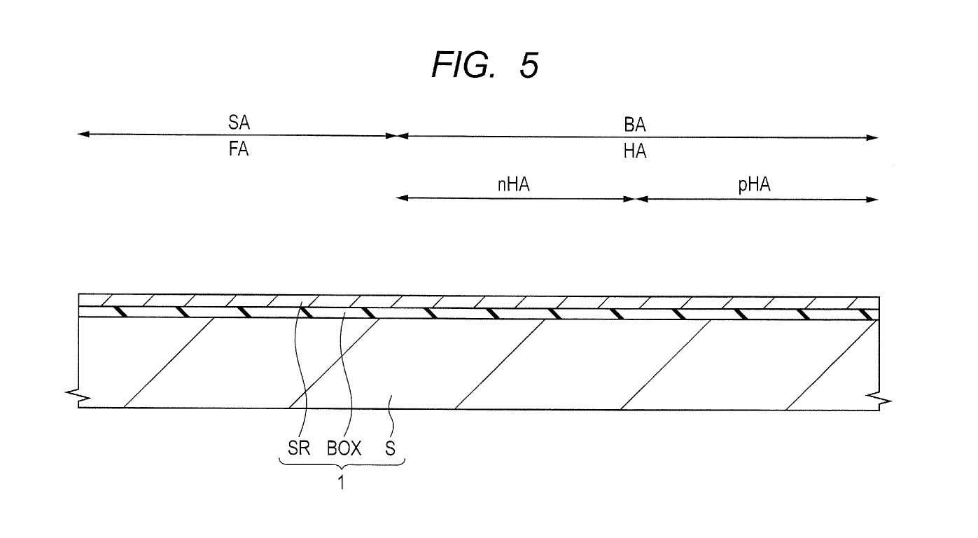

Next, referring to the drawings, a description will be given of a manufacturing method of the semiconductor device of the present embodiment, while defining the configuration of the semiconductor device. FIGS. 5 to 60 are cross-sectional views each showing a manufacturing process of the semiconductor device of the present embodiment.

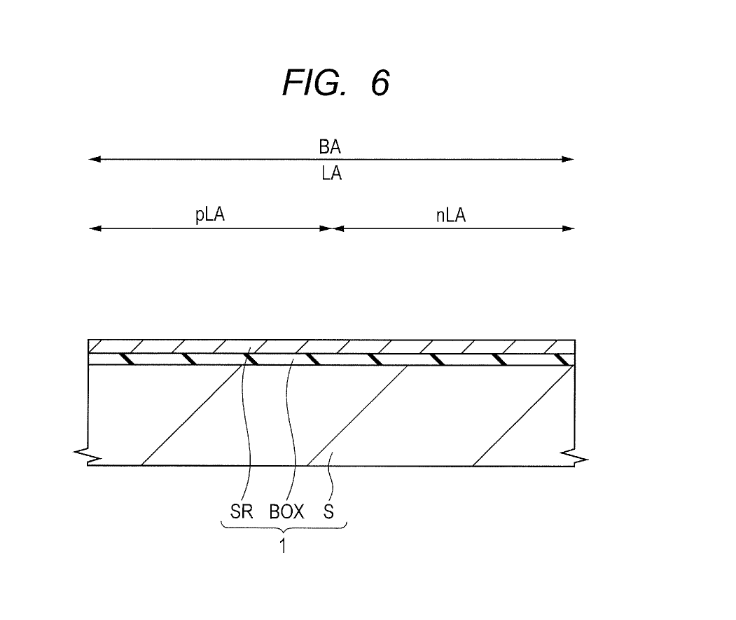

As shown in FIGS. 5 and 6, as a substrate, e.g., the SOI substrate 1 is provided. The SOI substrate 1 includes the supporting substrate (referred to also as semiconductor substrate) S, the insulating film (referred to also as embedded insulating layer) BOX formed over the supporting substrate S, and the silicon layer SR formed over the insulating layer BOX. The supporting substrate S is, e.g., a p-type single-crystal silicon substrate. The insulating layer BOX is, e.g., a silicon oxide film having a thickness of about 50 to 100 nm. The silicon layer SR is formed of, e.g., single-crystal silicon having a thickness of about 50 to 100 nm.

A method of forming the SOI substrate 1 is not limited. For example, the SOI substrate 1 can be formed by a SIMOX (Silicon Implanted Oxide) method. Into the main surface of a semiconductor substrate formed of Si, O₂ (oxygen) is ion-implanted with high energy, and Si (silicon) and the oxygen are bonded together by the subsequent heat treatment to form the insulating layer BOX at a position slightly deeper than the surface of the semiconductor substrate. In this case, a thin film of Si remaining over the insulating layer BOX serves as the silicon layer SR, and the semiconductor substrate under the insulating layer BOX serves as the supporting substrate S. The SOI substrate 1 may also be formed by a lamination method. For example, the surface of a first semiconductor substrate formed of Si is oxidized to form the insulating layer BOX, and then a second semiconductor substrate formed of Si is compressed thereagainst at a high temperature to be laminated thereon. Thereafter, the second semiconductor substrate is thinned. In this case, the thin film of the second semiconductor substrate remaining over the insulating layer BOX serves as the silicon layer SR, and the first semiconductor substrate under the insulating layer BOX serves as the supporting substrate S.

The SOI substrate 1 has the SOI region SA and the bulk region BA. Note that the SOI region SA is also a FMONOS formation region FA where the memory cells MC are formed. On the other hand, the bulk region BA has the low-breakdown-voltage MISFET formation region LA and the high-breakdown-voltage MISFET formation region HA. The low-breakdown-voltage MISFET formation region LA has the region nLA where the low-breakdown-voltage n-channel MISFET (LTn) is formed and the region pLA where the low-breakdown-voltage p-channel MISFET (LTp) is formed. The high-breakdown-voltage MISFET formation region HA has the region nHA where the high-breakdown-voltage n-channel MISFET (HTn) is formed and the region pHA where the high-breakdown-voltage p-channel MISFET (HTp) is formed. Note that the bulk region BA means a region from which the silicon layer SR and the insulating layer BOX are removed by a step described later.

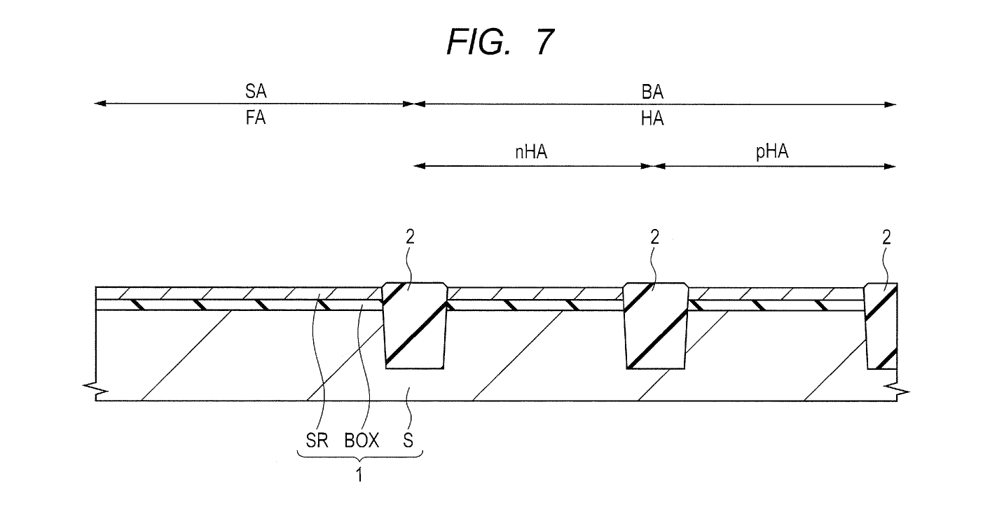

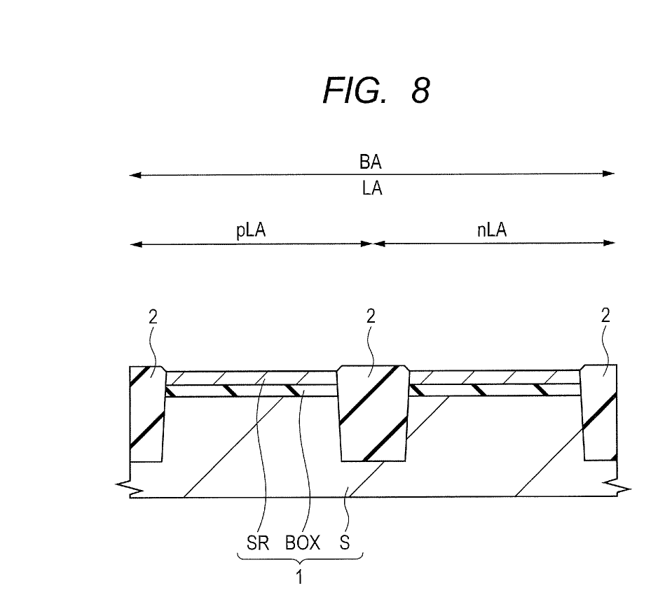

Next, as shown in FIGS. 7 and 8, an isolation region 2 is formed in the SOI substrate 1. The isolation region 2 can be formed using, e.g., a STI (shallow trench isolation) method.

First, using a mask film (such as, e.g., a silicon nitride film) having an opening corresponding to the isolation region as a mask, the silicon layer SR, the insulating layer BOX, and the supporting substrate S are partially etched to form an isolation trench. The isolation trench extends through the silicon layer SR and the insulating layer BOX to reach a middle point in the supporting substrate S.

Next, over the SOI substrate 1 including the foregoing mask, e.g., a silicon oxide film is deposited as an insulating film to such a thickness that allows the isolation trench to be filled therewith using a CVD (Chemical Vapor Deposition) method or the like. Then, the silicon oxide film except for the portion thereof located in the isolation trench is removed using a CMP (Chemical Mechanical Polishing) method, an etch-back method, or the like. In this manner, the isolation region 2 where the isolation trench is filled with the silicon oxide film can be formed. The isolation region 2 is formed in the boundary portion between the individual regions so as to prevent the interference between the individual elements formed in the SOI region SA and in the bulk region BA.

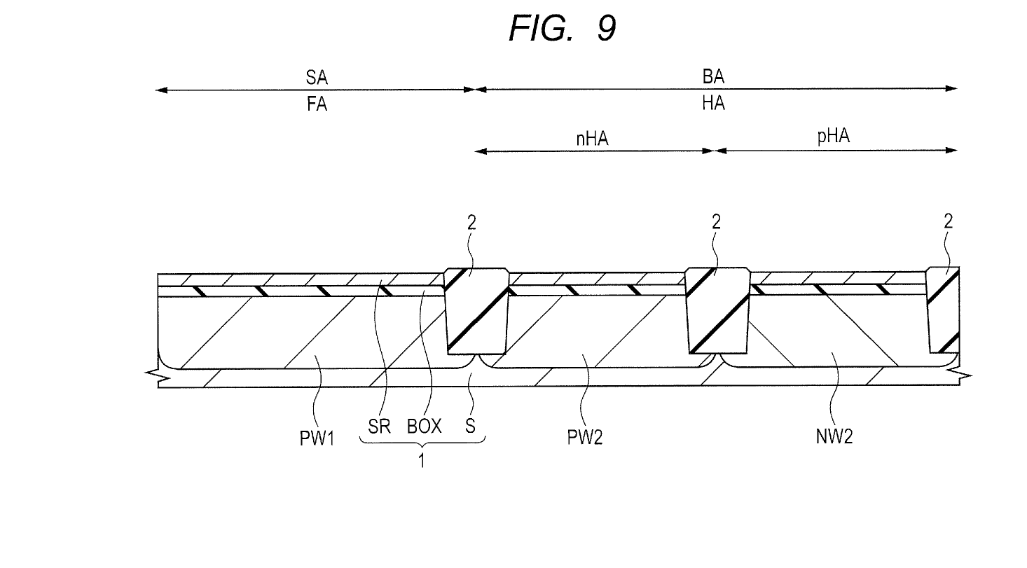

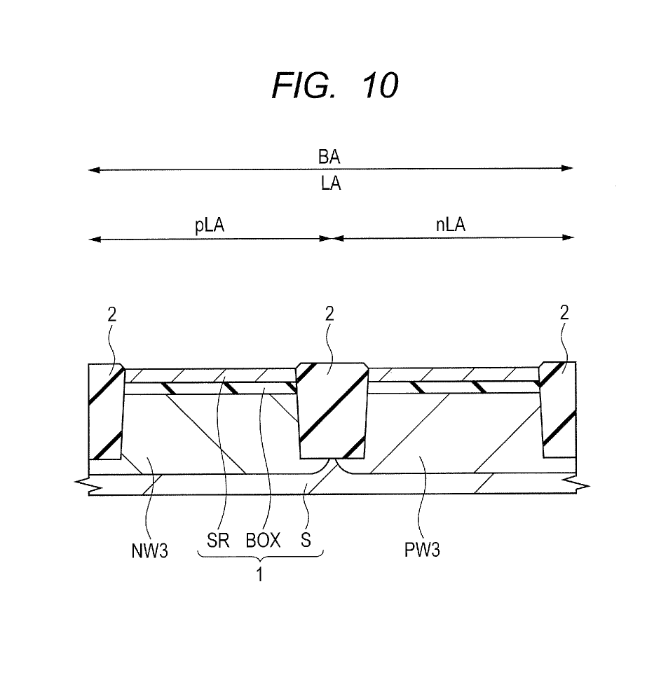

Next, as shown in FIGS. 9 and 10, the p-type wells (PW1, PW2, and PW3) or the n-type wells (NW2 and NW3) are formed in the supporting substrate S in the individual regions.

For example, over the SOI substrate 1, a photoresist film (not shown) having openings corresponding to the SOI region SA and the regions nHA and nLA is formed and a p-type impurity (such as, e.g., boron (B)) is ion-implanted to form the p-type wells (PW1, PW2, and PW3). Thereafter, the foregoing photoresist film (not shown) is removed by ashing treatment or the like. Then, over the SOI substrate 1, a photoresist film (not shown) having openings corresponding to the regions pLA and pHA is formed and an n-type impurity (such as, e.g., arsenic (As) or phosphorus (P)) is ion-implanted to form the n-type wells (NW2 and NW3). Thereafter, the foregoing photoresist film (not shown) is removed by ashing treatment or the like. Then, as well annealing treatment, heat treatment is performed in a nitrogen atmosphere at 1000° C. for about 30 seconds. By the heat treatment, the impurities implanted in the individual regions are activated to allow recovery from a crystal defect caused by the ion implantation. The well annealing treatment may be performed not only in the nitrogen atmosphere, but also in an inert gas atmosphere of argon or the like. The temperature range can also be adjusted appropriately from 750° C. to 1000° C. Instead of the foregoing momentary thermal annealing (e.g., at 1000° C. for about 30 seconds), spike annealing (e.g., at 1000° C. for about 1 or less seconds) may also be used.

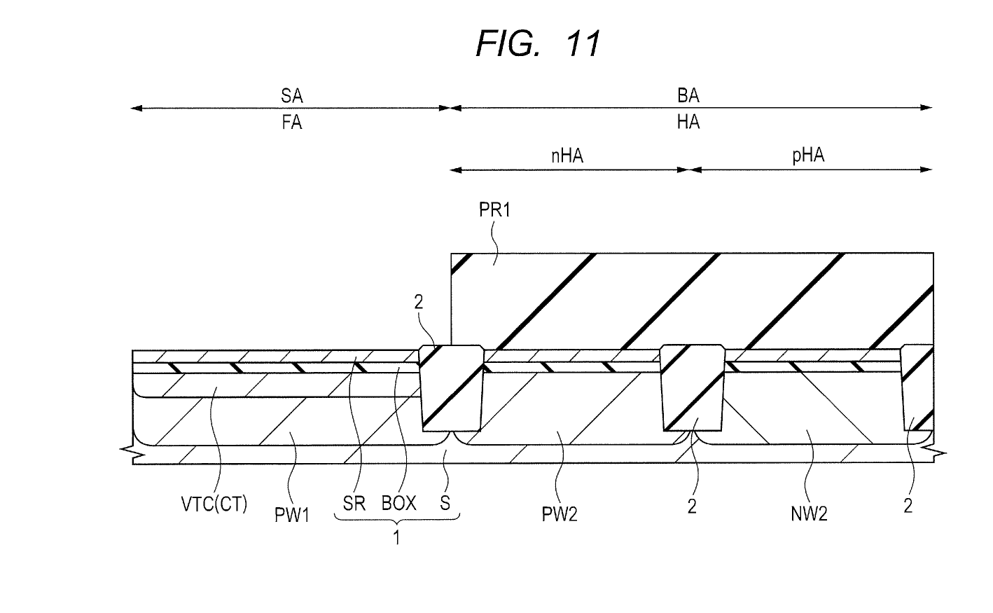

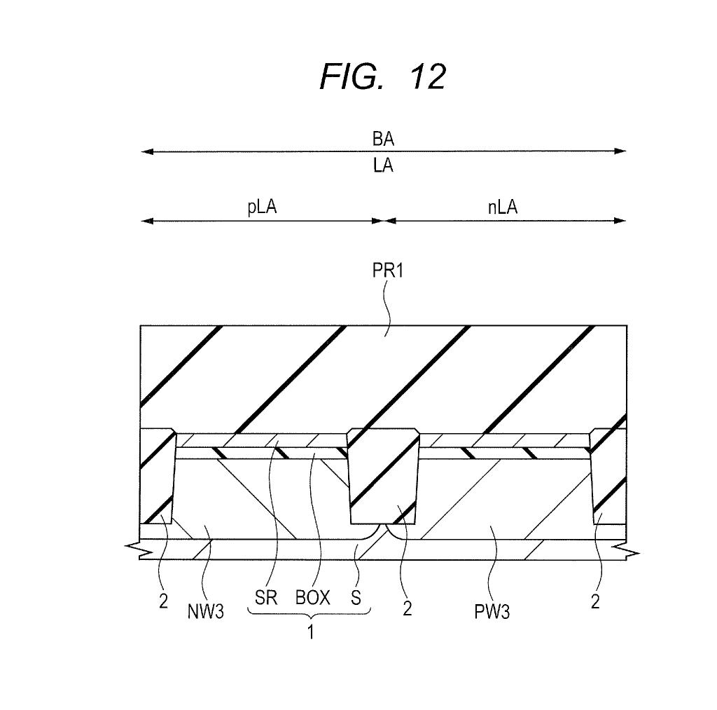

Next, as shown in FIGS. 11 and 12, the impurity region VTC(CT) for adjusting the threshold of the control transistor is formed.

First, over the SOI substrate 1, a photoresist film PR1 having an opening corresponding to the SOI region SA is formed and, into the supporting substrate S under the insulating layer BOX in the SOI region SA, an impurity for threshold adjustment is ion-implanted. At this time, into the silicon layer SR in the SOI region SA, ion implantation is preferably performed with such an implantation energy that minimizes the implantation of the impurity. For example, when the film thickness of each of the silicon layer SR and the insulating layer BOX is about 50 nm and boron (B) is ion-implanted as the impurity for threshold adjustment, ion implantation is performed with an implantation energy of 40 keV and a dosage of 2e13 (2×10¹³) cm⁻². As a result, in the supporting substrate S under the insulating layer BOX in the SOI region SA, a p-type impurity region (referred to also as semiconductor region) is formed as the impurity region VTC(CT) for adjusting the threshold of the control transistor. Note that the implantation conditions need to be adjusted appropriately in accordance with the film thickness of the silicon layer SR, the film thickness of the insulating layer BOX, and a target threshold value. Then, the photoresist film PR1 is removed by ashing treatment or the like.

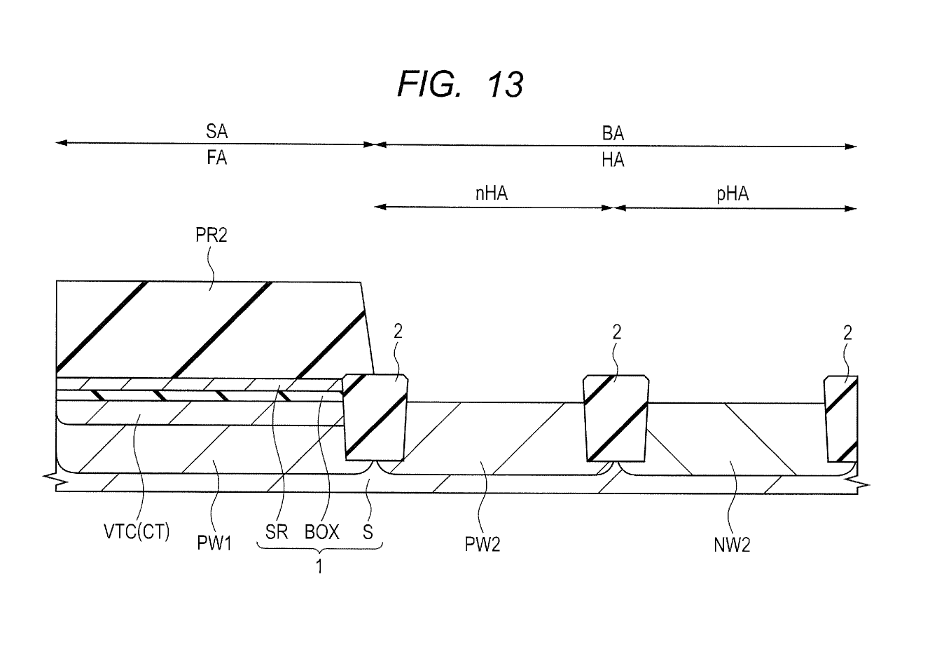

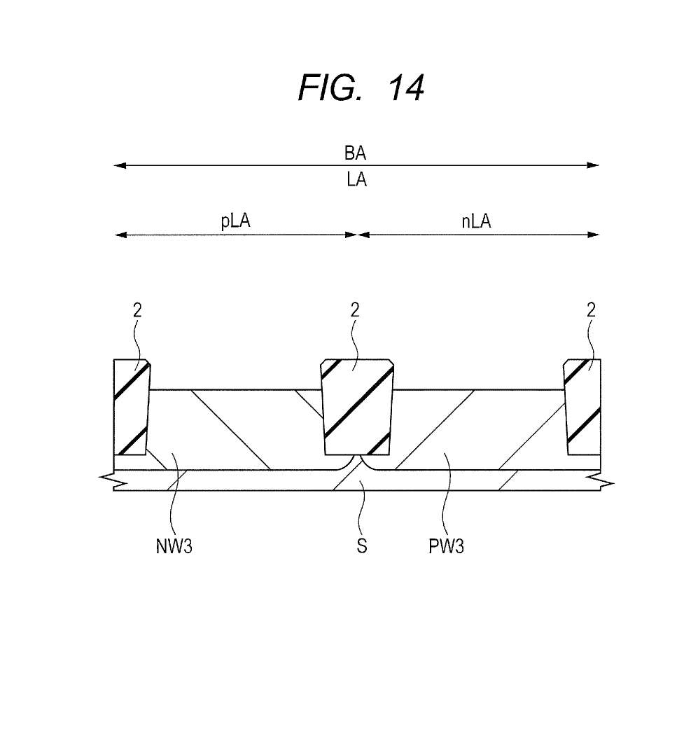

Then, as shown in FIGS. 13 and 14, the silicon layer SR and the insulating layer BOX in the bulk region BA (regions nLA, pLA, nHA, and pHA) are removed to expose the surface of the supporting substrate S.

For example, over the SOI substrate 1, a photoresist film PR2 having an opening corresponding to the bulk region BA (regions nLA, pLA, nHA, and pHA) is formed, and the silicon layer SR and the insulating layer BOX in the bulk region BA are successively removed by dry etching. As a result, the surface of the supporting substrate S in the bulk region BA is exposed. Here, using the photoresist film PR2 as a mask, the silicon layer SR and the insulating layer BOX in the bulk region BA are etched. However, the silicon layer SR and the insulating layer BOX may also be etched using a hard mask formed of a silicon oxide film or a silicon nitride film. Then, the photoresist film PR2 is removed by ashing treatment or the like.

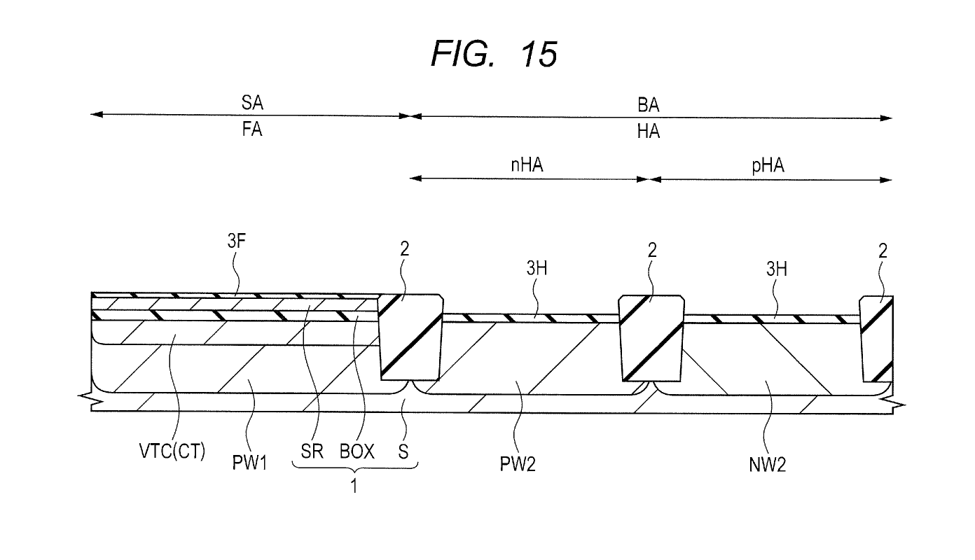

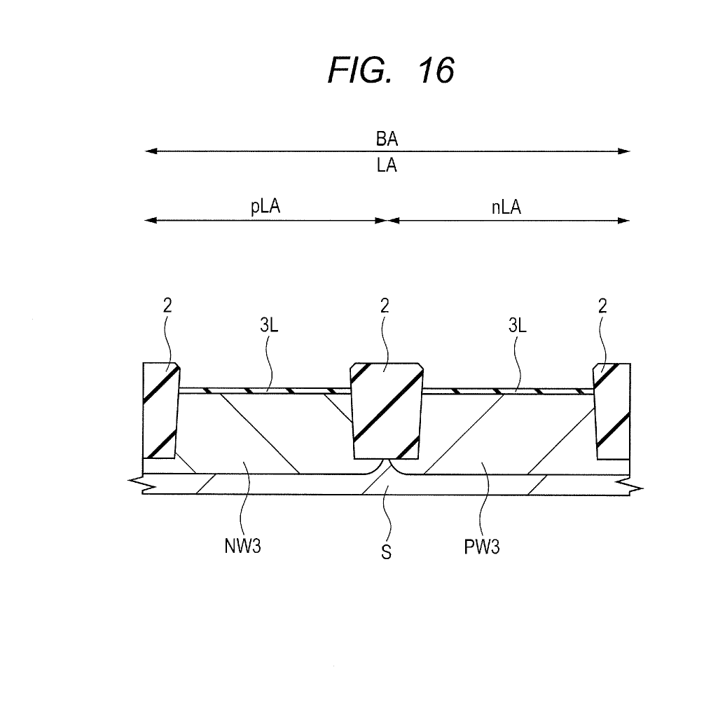

Next, by diluted hydrofluoric acid cleaning or the like, the surface of each of the SOI region SA and the bulk region BA is cleaned. Then, as shown in FIGS. 15 and 16, over the main surface of the silicon layer SR in the SOI region SA and the main surface of the supporting substrate S (p-type wells PW2 and PW3 and n-type wells NW2 and NW3) in the bulk region BA, the gate insulating films 3F, 3L, and 3H are formed. Here, over the main surface of the silicon layer SR in the SOI region SA, the relatively thin gate insulating film 3F is formed. On the other hand, over the high-breakdown-voltage MISFET formation region HA (regions nHA and pHA) of the bulk region BA, the relatively thick gate insulating film 3H is formed while, over the low-breakdown-voltage MISFET formation region LA (regions nLA and pLA) of the bulk region BA, the relatively thin gate insulating film 3L is formed. For example, over the main surface of the silicon layer SR in the SOI region SA and the main surface of the supporting substrate S in the low-breakdown-voltage MISFET formation region LA (regions nLA and pLA) of the bulk region BA, a silicon oxide film having a first thickness (e.g., about 3 nm) is formed by a thermal oxidation method. Then, for example, over the main surface of the supporting substrate S in the high-breakdown-voltage MISFET formation region HA (regions nHA and pHA) of the bulk region BA, a silicon oxide film having a second thickness (e.g., about 16 nm) larger than the first thickness is formed by a thermal oxidation method.

As the gate insulating films 3F, 3L, and 3H, not only the silicon oxide films, but also other insulating films such as a silicon oxynitride film may also be used. Alternatively, a metal oxide film having a high dielectric constant higher than that of a silicon nitride film, such as a hafnium oxide film, an aluminum oxide film (alumina), or a tantalum oxide film or a laminate film of an oxide film or the like and a metal oxide film may also be formed. The gate insulating films 3F, 3L, and 3H may also be formed using not only the thermal oxidation method, but also a CVD method. The gate insulating films 3F, 3L, and 3H may also be formed of different types of films to have different thicknesses.

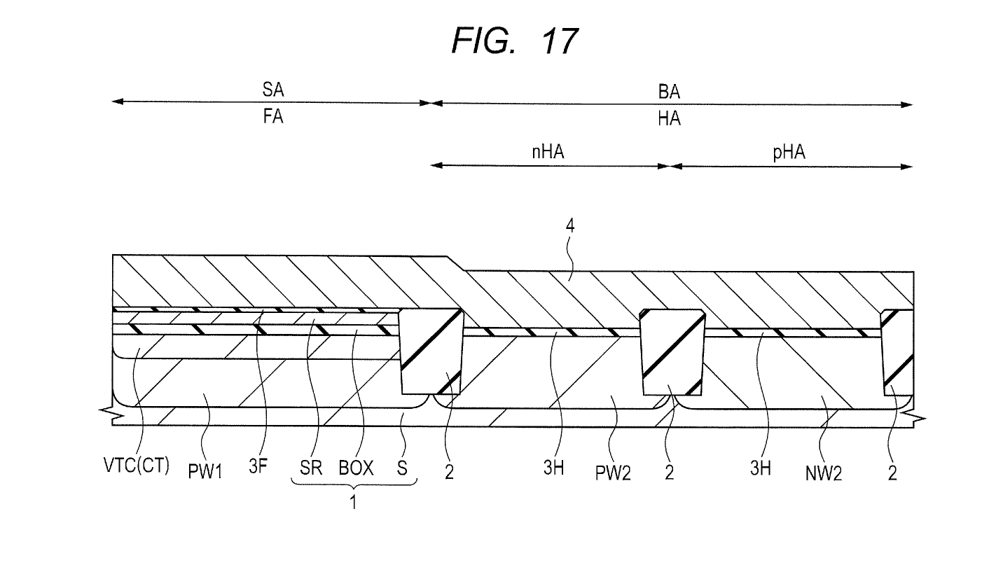

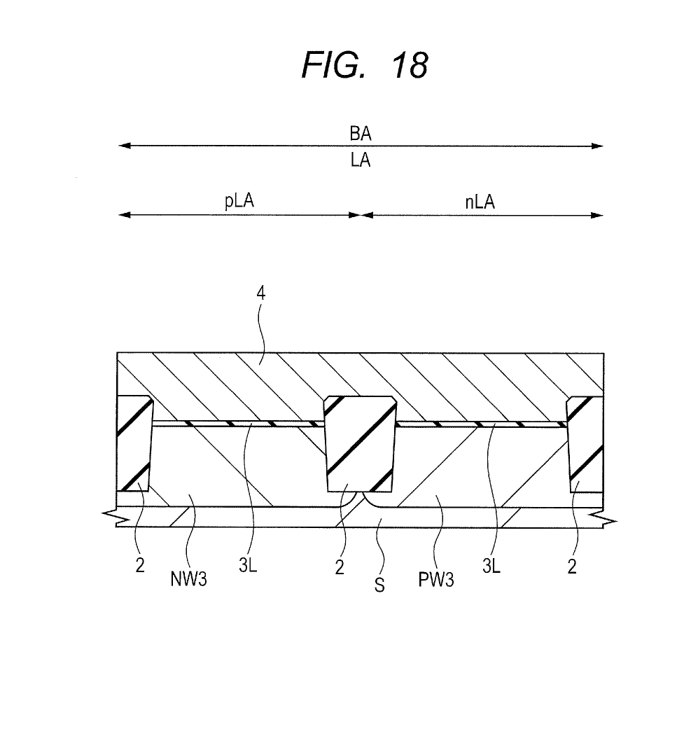

Next, as shown in FIGS. 17 and 18, over the gate insulating films 3F, 3L, and 3H, a silicon film 4 is formed as a conductive (conductor) film. As the silicon film 4, e.g., polysilicon film is formed using a CVD method or the like to a thickness of about 80 nm. As the silicon film 4, an amorphous silicon film may also be deposited and crystallized by being subjected to heat treatment. The silicon film 4 serves as the control gate electrode CG of each of the memory cells MC in the SOI region SA and also serves as the gate electrode GE of each of the high-breakdown-voltage n-channel MISFET (HTn) and the high-breakdown-voltage p-channel MISFET (HTp) in the high-breakdown-voltage MISFET formation region HA (regions nHA and pHA) of the bulk region BA. On the other hand, in the low-breakdown-voltage MISFET formation region LA (regions nLA and pLA) of the bulk region BA, the silicon film 4 serves as the gate electrode GE of each of the low-breakdown-voltage n-channel MISFET (LTn) and the low-breakdown-voltage p-channel MISFET (LTp).

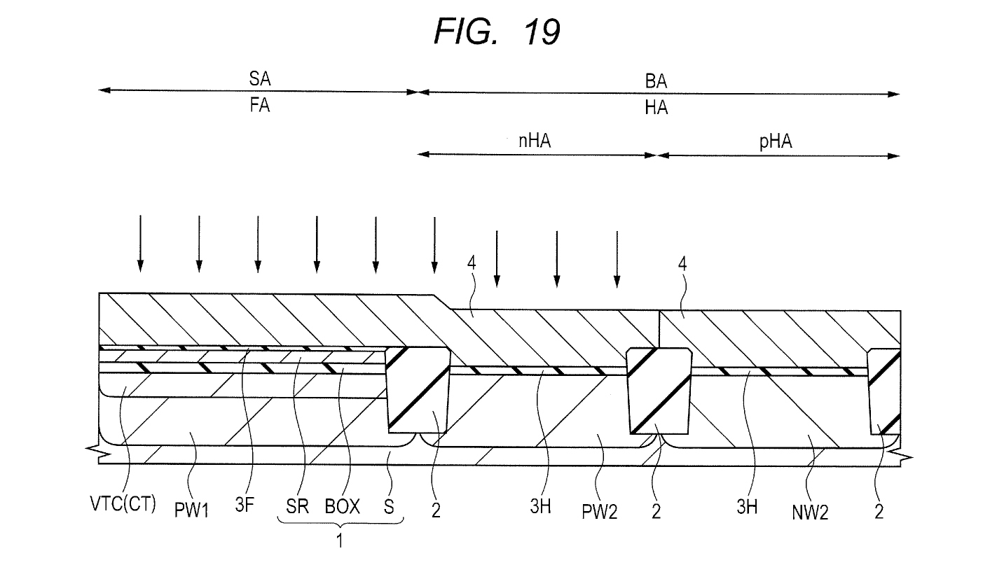

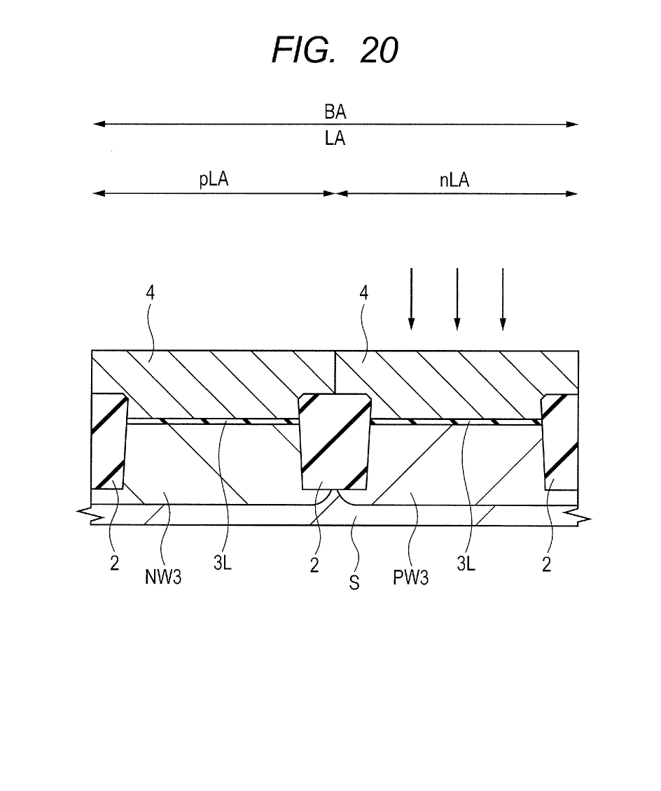

Next, as shown in FIGS. 19 and 20, into the silicon film 4 in each of the SOI region SA, the region nLA of the bulk region BA where the low-breakdown-voltage n-channel MISFET (LTn) is formed, and the region nHA of the bulk region BA where the high-breakdown-voltage n-channel MISFET (HTn) is formed, an n-type impurity (such as, e.g., arsenic (As) or phosphorus (P)) is implanted using a photoresist film (not shown) as a mask. For example, phosphorus (P) is ion-implanted under the conditions of 5 keV and 2e15 cm⁻².

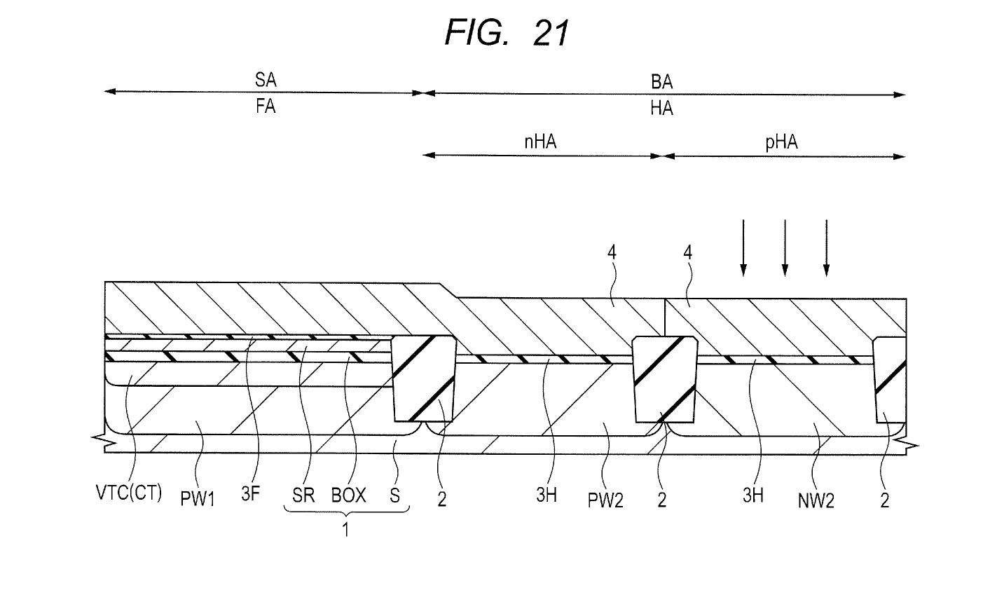

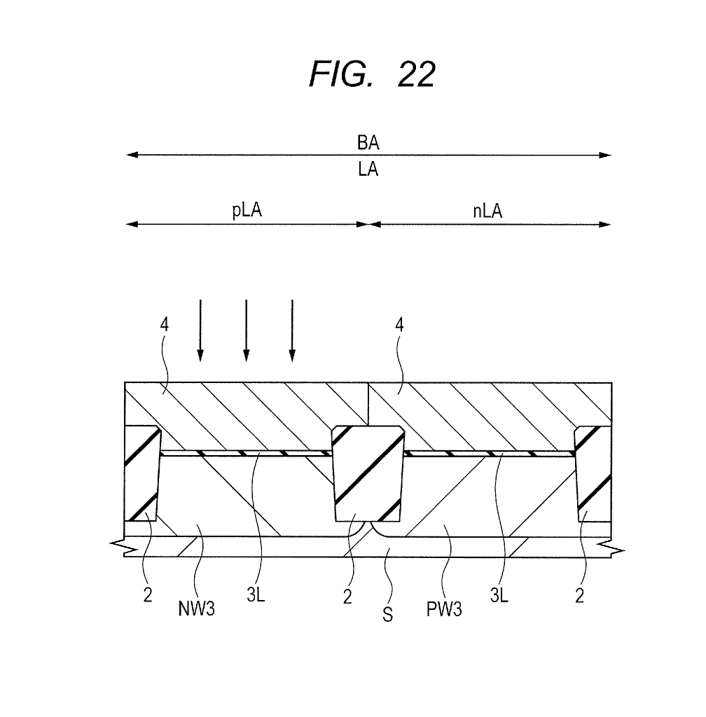

Next, as shown in FIGS. 21 and 22, into the silicon film 4 in each of the region pLA of the bulk region BA where the low-breakdown-voltage p-channel MISFET (LTp) is formed and the region pHA of the bulk region BA where the high-breakdown-voltage p-channel MISFET (HTp) is formed, a p-type impurity (such as, e.g., boron (B)) is implanted using a photoresist film (not shown) as a mask. For example, boron (B) is ion-implanted under the conditions of 2 keV and 2e15 cm⁻². Instead of boron, boron fluoride may also be used.

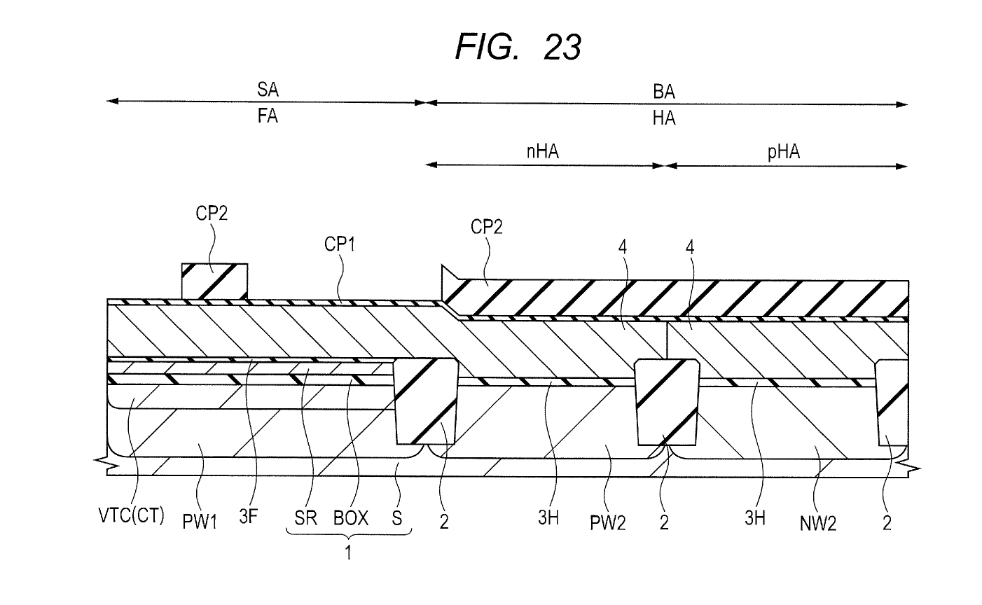

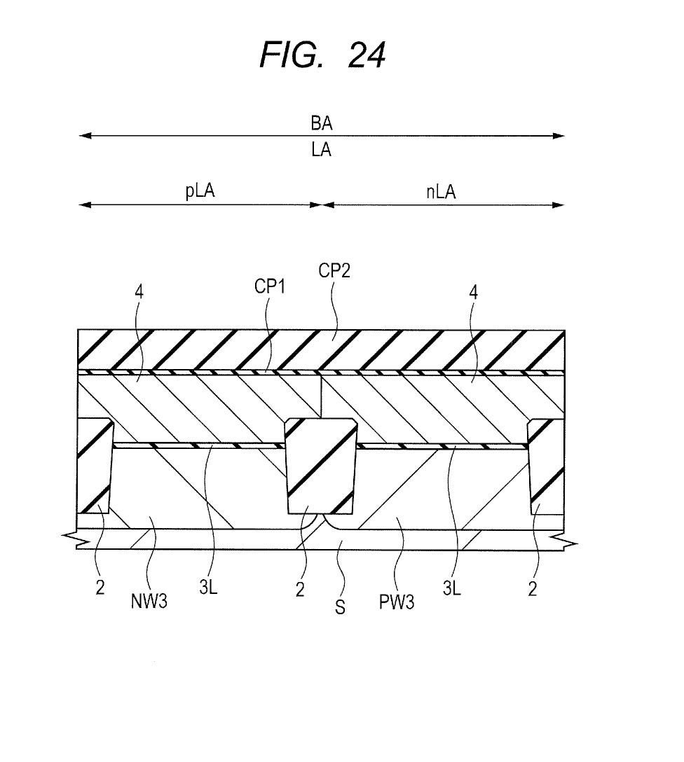

Next, as shown in FIGS. 23 and 24, the surface of the silicon film 4 corresponding to a thickness of about 3 to 10 nm is thermally oxidized to form the thin silicon oxide film CP1. Note that the silicon oxide film CP1 may also be formed using a CVD method. Then, over the silicon oxide film CP1, using a CVD method or the like, the silicon nitride film (cap insulating film) CP2 having a thickness of about 50 to 150 nm is formed.

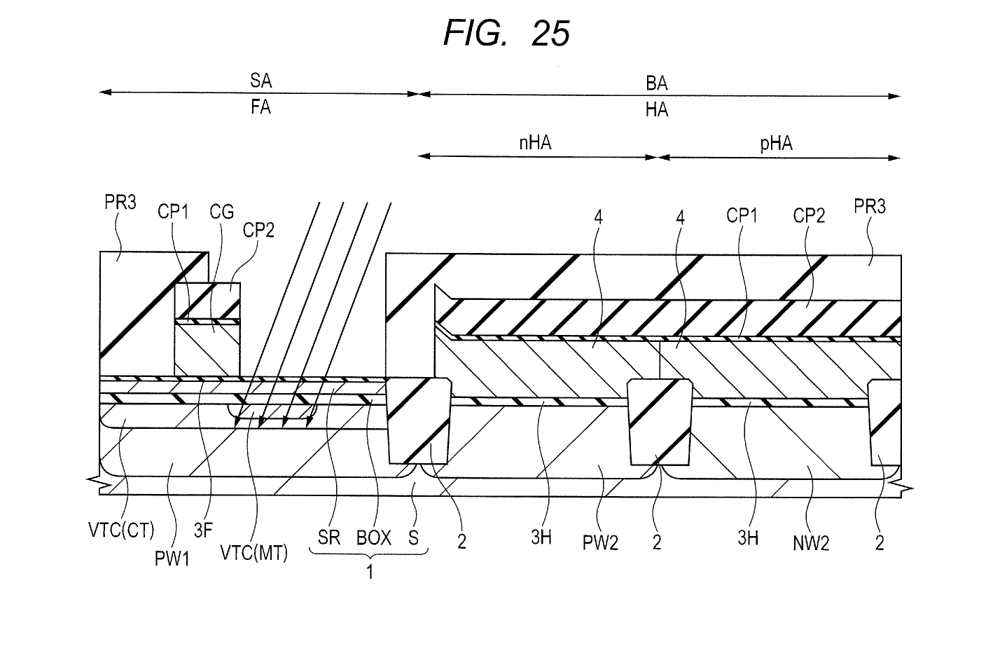

Next, over the region where the control gate electrode CG is to be formed and the bulk region BA, a photoresist film (not shown) is formed using a photolithographic method and, using the photoresist film as a mask, the silicon nitride film CP2 is etched. Then, by removing the photoresist film by ashing or the like, the silicon nitride film CP2 and the silicon oxide film CP1 are left in the region where the control gate electrode CG is to be formed and the bulk region BA. Thereafter, using the silicon nitride film CP2 as a mask, the silicon film 4 and the like are etched. In this manner, the control gate electrode CG (having a gate length of, e.g., about 80 nm) is formed (see FIG. 25). Here, over the control gate electrode CG, the silicon nitride film CP2 and the silicon oxide film CP1 are formed. However, these films may also be omitted.

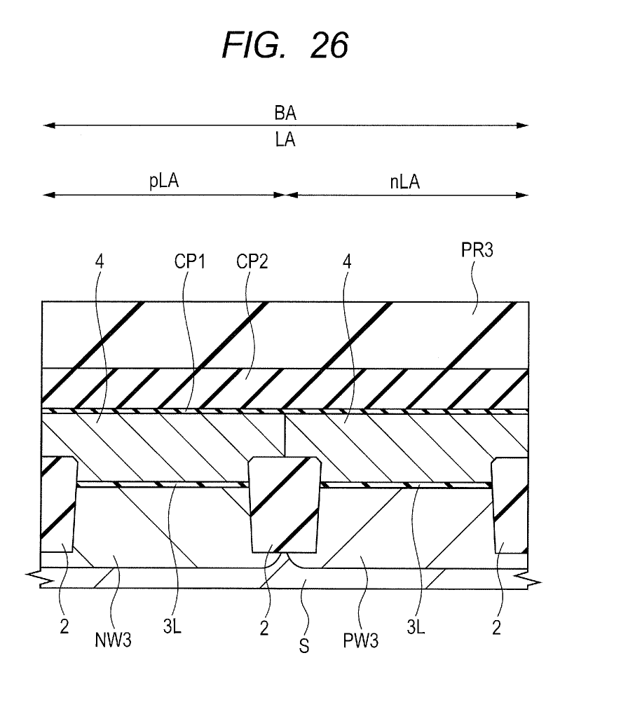

Here, in the SOI region SA, the gate insulating film 3F remaining under the control gate electrode CG serves as the gate insulating film 3F of the control transistor. Note that the gate insulating film 3F except for the portion thereof covered with the control gate electrode CG can be removed by the subsequent patterning step or the like. In the bulk region BA, the silicon nitride film CP2, the silicon oxide film CP1, and the silicon film 4 are left (see FIGS. 25 and 26).

Next, as shown in FIGS. 25 and 26, using a photoresist film PR3 having an opening on one side of the control gate electrode CG (in the region where the memory gate electrode MG is formed) as a mask, an n-type impurity (such as, e.g., arsenic (As) or phosphorus (P)) of the conductivity type opposite to the p-type or the like is implanted. As a result, in the supporting substrate S in the region where the memory gate electrode is formed, a p-type impurity region (referred to also as semiconductor region) is formed as the impurity region VTC(MT) for adjusting the threshold of the memory transistor. At this time, the n-type impurity is obliquely implanted to allow the impurity region VTC(MT) for threshold adjustment to be formed so as to extend to the end portion (boundary portion between the memory gate electrode MG and the control gate electrode CG) of the memory gate electrode MG. In the ion implantation also, the implantation conditions need to be adjusted appropriately in accordance with the film thickness of the silicon layer SR, the film thickness of the insulating layer BOX, and a target threshold value. For example, it is important for the implanted impurity to be distributed on the supporting substrate S side and it is desirable to minimize the distribution of the implanted impurity in the overlaying silicon layer SR. Accordingly, it is desirable to appropriately adjust the implantation conditions such that the projected range is sufficiently distributed on the supporting substrate S side. Here, arsenic (As) is ion-implanted at a slant in the range of 20° to 30° on the drain side with 70 KeV at 2e13 cm⁻². These conditions allow the impurity region VTC(MT) to be formed at substantially the same position as that of the channel. Then, the photoresist film PR3 is removed by ashing treatment or the like.

Thus, by implanting an n-type impurity (such as, e.g., arsenic (As) or phosphorus (P)) of the conductivity type opposite to the p-type, the impurity region VTC(MT) for adjusting the threshold of the memory transistor can be formed which has a concentration lower than that of the impurity region VTC(CT) for adjusting the threshold of the control transistor. The “concentration lower” used herein means that the effective concentration of the impurity (carrier concentration) is lower. Also, by implanting an impurity (such as, e.g., arsenic (As) or phosphorus (P)) having an atomic weight larger than that of the impurity (which is boron (B) herein) in the impurity region VTC(CT), the impurity region VTC(MT) for adjusting the threshold of the memory transistor can be formed to be shallower than the impurity region VTC(CT) for adjusting the threshold of the control transistor.

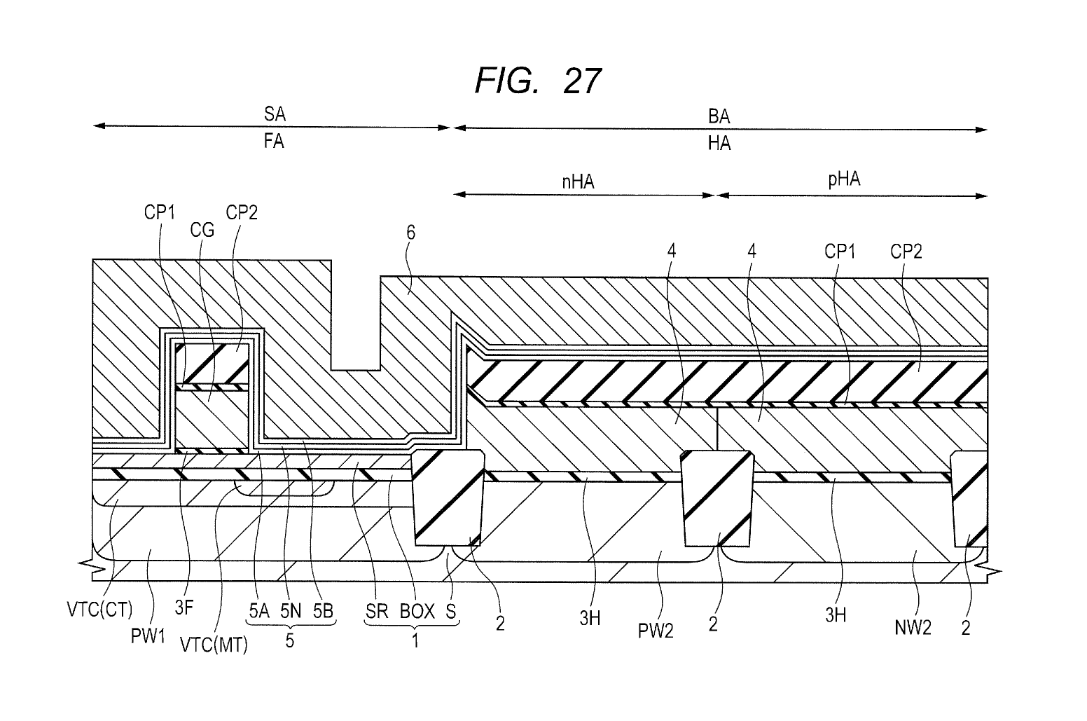

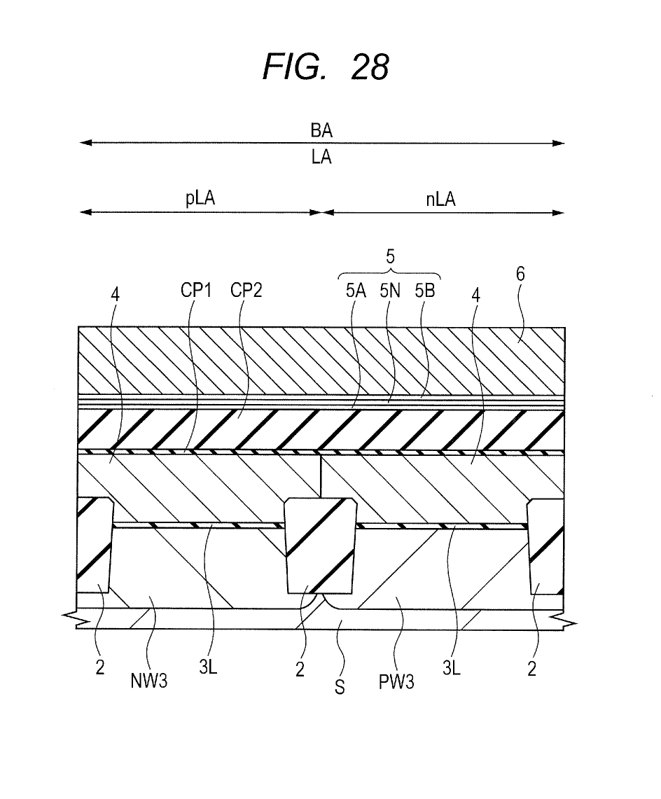

Next, as shown in FIGS. 27 and 28, over the silicon layer SR and the silicon nitride film CP2 in the SOI region SA and the silicon nitride film CP2 in the bulk region BA, the insulating film 5 (5A, 5N, and 5B) is formed.

First, the main surface of the silicon layer SR in the SOI region SA is subjected to cleaning treatment, and then the silicon oxide film 5A is formed in the SOI region SA and the bulk region BA. The silicon oxide film 5A is formed by, e.g., a thermal oxidation method to a thickness of, e.g., about 4 nm. Note that the silicon oxide film 5A may also be formed using a CVD method. In the drawing, the shape of the silicon oxide film 5A when formed by the CVD method is shown. Then, over the silicon oxide film 5A, a silicon nitride film 5N is deposited by a CVD method to a thickness of, e.g., about 10 nm. The silicon nitride film 5N serves as the charge storage portion of the memory cell and serves as a middle layer forming the insulating film (ONO film) 5. Then, over the silicon nitride film 5N, the silicon oxide film 5B is deposited by a CVD method to a thickness of, e.g., about 5 nm.

By the foregoing steps, the insulating film (ONO film) 5 including the silicon oxide film 5A, the silicon nitride film 5N, and the silicon oxide film 5B can be formed. Note that, in the bulk region BA, the insulating film (ONO film) 5 may also remain over the silicon nitride film (cap insulating film) CP2 (FIGS. 27 and 28).

Also in the present embodiment, the silicon nitride film 5N is formed as the charge storage portion (charge storage layer or insulating film having a trap level) in the insulating film 5. However, it may also be possible to use another insulating film such as, e.g., an aluminum oxide film, a hafnium oxide film, or a tantalum oxide film. These films are high-dielectric-constant films each having a dielectric constant higher than that of a silicon nitride film. Alternatively, it may also be possible to form the charge storage layer using an insulating film having a silicon nanodot.

The insulating film 5 formed in the SOI region. SA functions as the gate insulating film of the memory gate electrode MF and has a charge retaining (charge storing) function. Accordingly, the insulating film 5 is configured to have a laminate structure including at least three layers such that the potential barrier height of the inner layer (silicon nitride film 5N) is lower than the potential height of each of the outer layers (silicon oxide films 5A and 5B). The film thicknesses of the individual layers of the insulating film (ONO film) 5 are set to appropriate values in accordance with the operating method of the memory cell thereof. Note that the thickness of the insulating film (ONO film) 5 (sum of the film thicknesses of the individual layers thereof) is larger than the thickness of the gate insulating film 3F remaining under the control gate electrode CG.

Next, as a conductive film (conductor film), a silicon film 6 is formed. Over the insulating film 5, as the silicon film 6, e.g., a polysilicon film is formed to a thickness of about 50 to 200 nm using a CVD method or the like. As the silicon film 6, an amorphous silicon film may also be deposited and subjected to heat treatment to be crystallized. Note that, into the silicon film 6, an n-type impurity may also be introduced. As will be described later, the silicon film 6 serves as the memory gate electrode MG (having a gate length of, e.g., about 50 nm) in the SOI region SA.

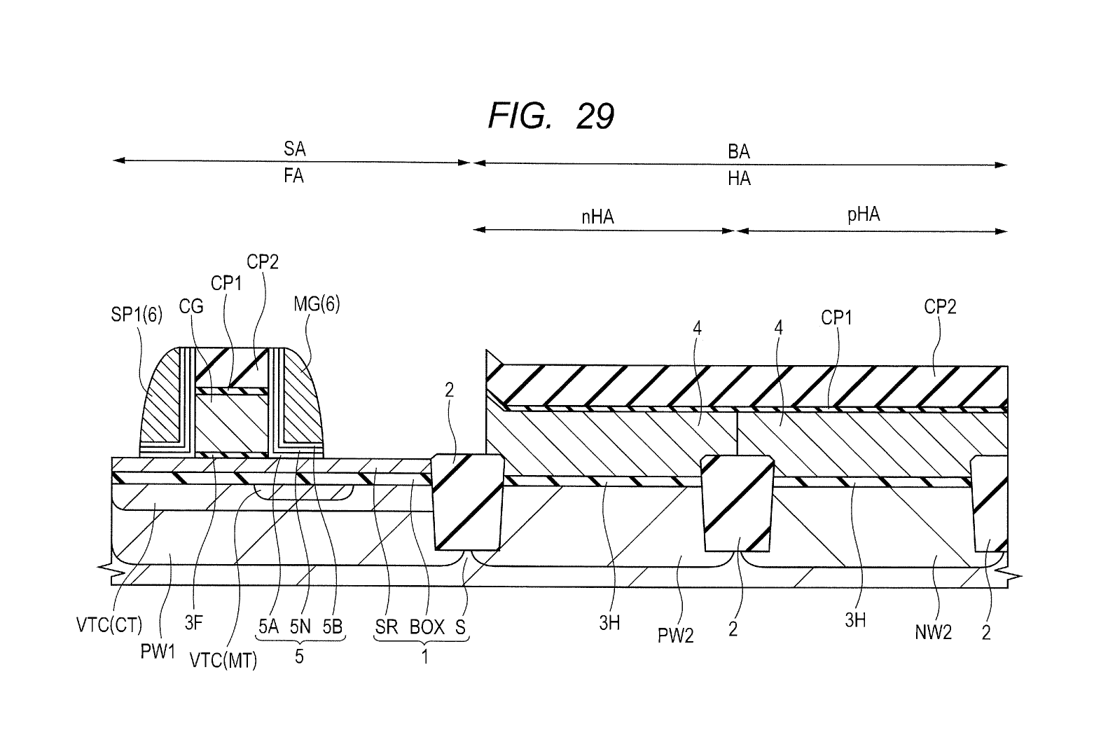

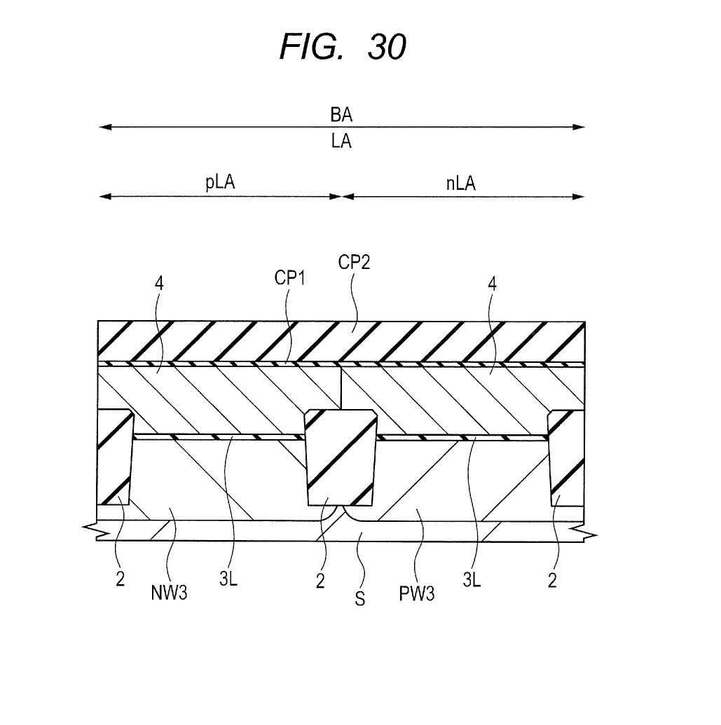

Next, as shown in FIGS. 29 and 30, the silicon film 6 is etched back. In the etch-back step, only the portion of the silicon film 6 corresponding to a predetermined thickness is removed from the surface thereof by anisotropic dry etching. The step allows the silicon film 6 to remain in sidewall shapes (side-wall-film shapes) over the both side wall portions of the control gate electrode CG each via the insulating film 5. The silicon film 6 remaining over one of the both side wall portions of the foregoing control gate electrode CG forms the memory gate electrode MG. On the other hand, the silicon film 6 remaining over the other side wall portion forms a silicon spacer SP1. The insulating film 5 under the foregoing memory gate electrode MG serves as the gate insulating film of the memory transistor. The memory gate length (gate length of the memory gate electrode MG) is determined in correspondence to the thickness of the deposited silicon film 6.

At this time, in the bulk region BA, the silicon film 6 is etched to expose the insulating film 5. Then, the insulating film 5 is removed by etching. As a result, in the SOI region SA, the silicon nitride film CP2 over the control gate electrode CG is exposed to expose the silicon layer SR. On the other hand, in the bulk region BA, the silicon nitride film CP2 is exposed.

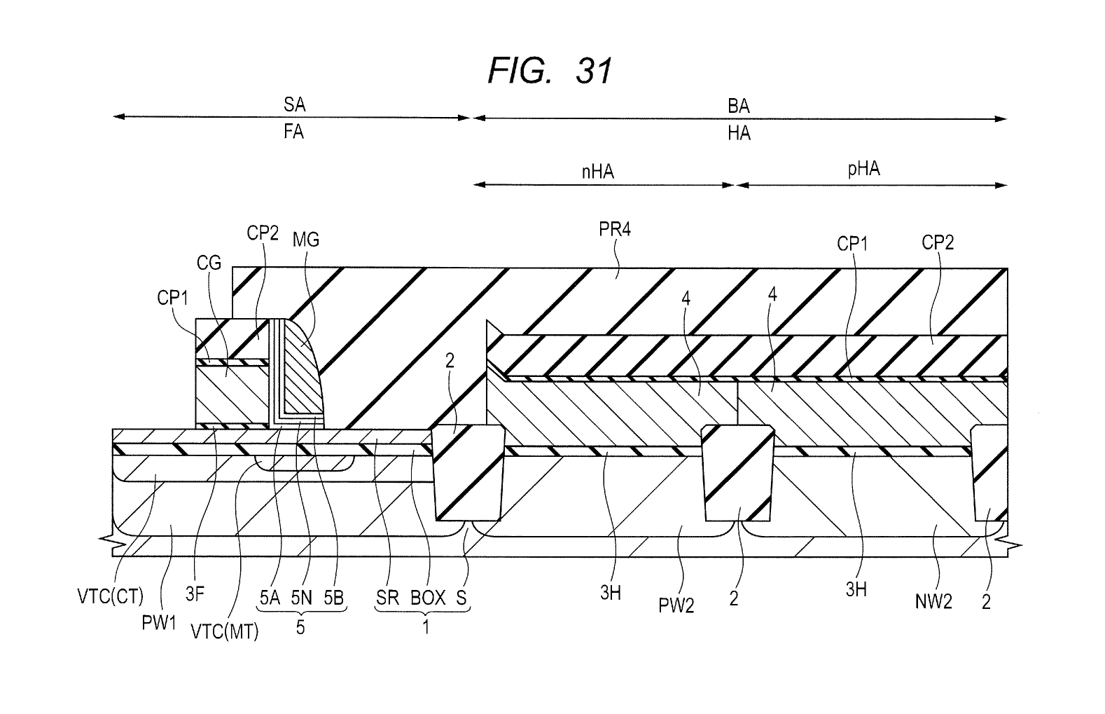

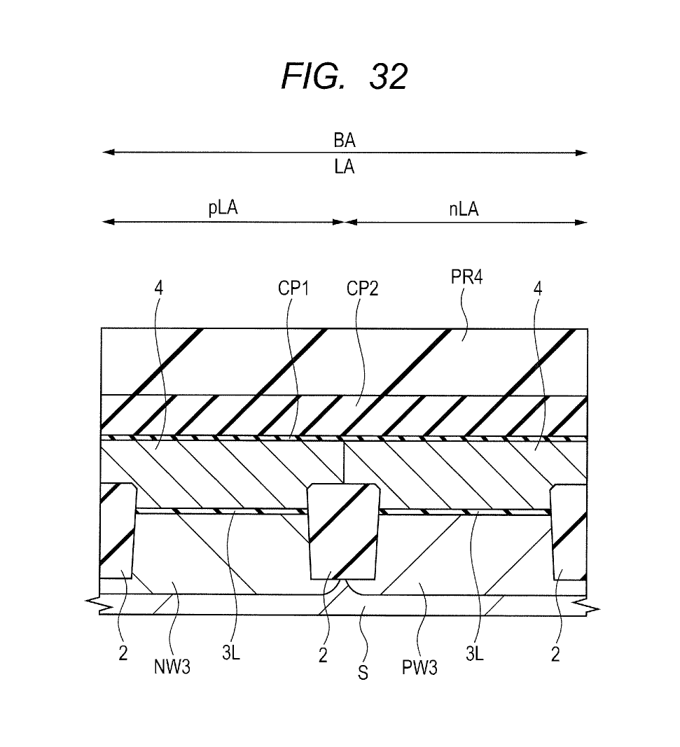

Next, as shown in FIGS. 31 and 32, a photoresist film PR4 is formed to cover the memory gate electrode MG from above and expose the silicon spacer SP1. Using the photoresist film PS4 as a mask, the unneeded silicon spacer SP1 is etched. Then, the photoresist film PF4 is removed by asking treatment or the like.

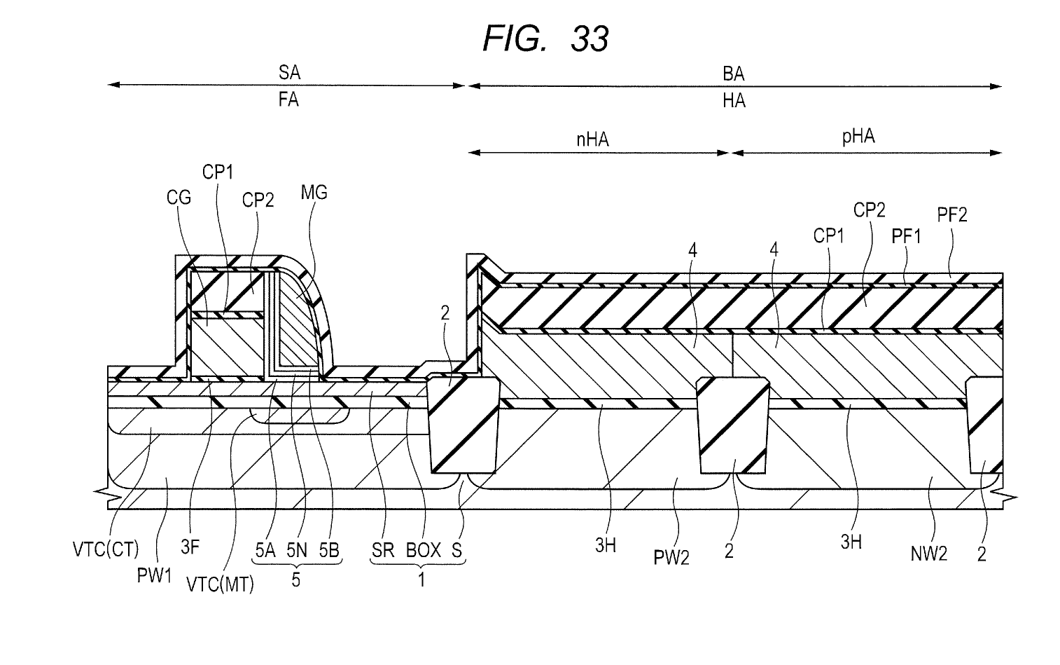

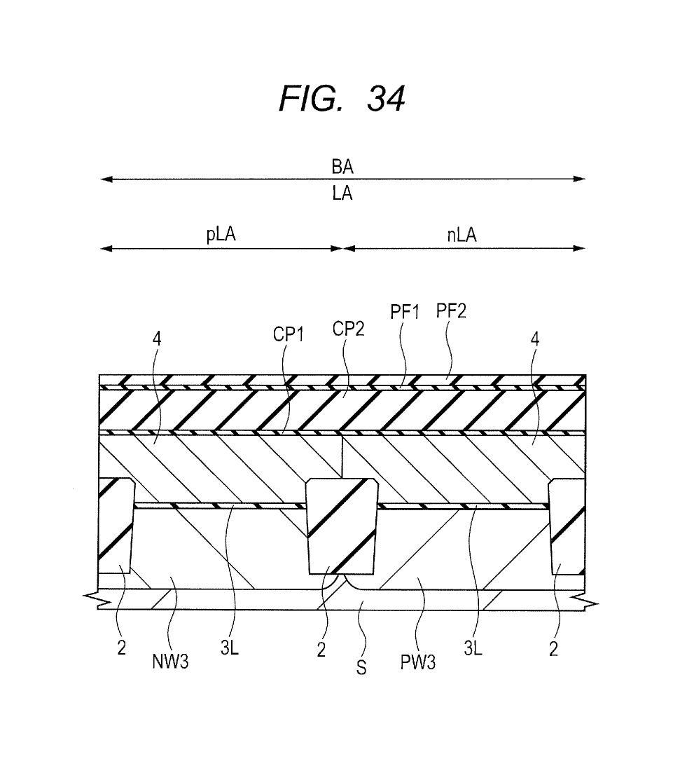

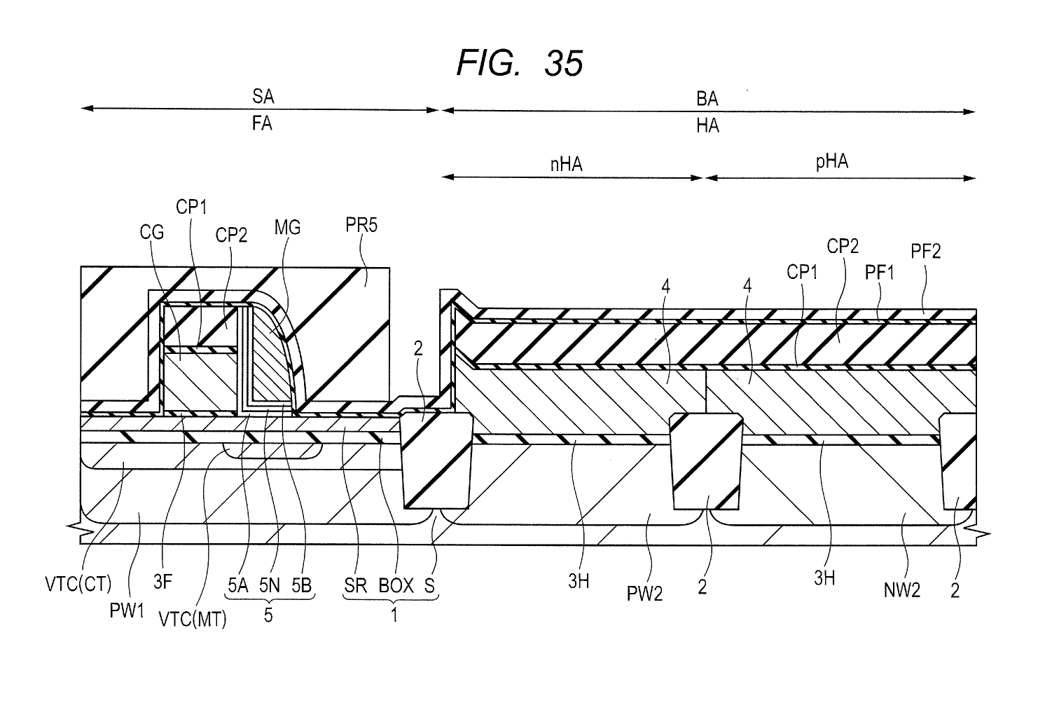

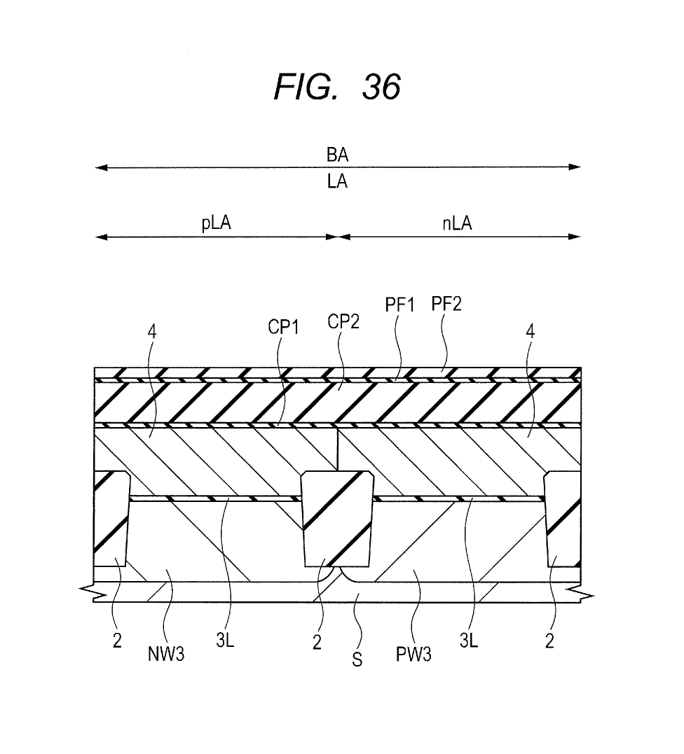

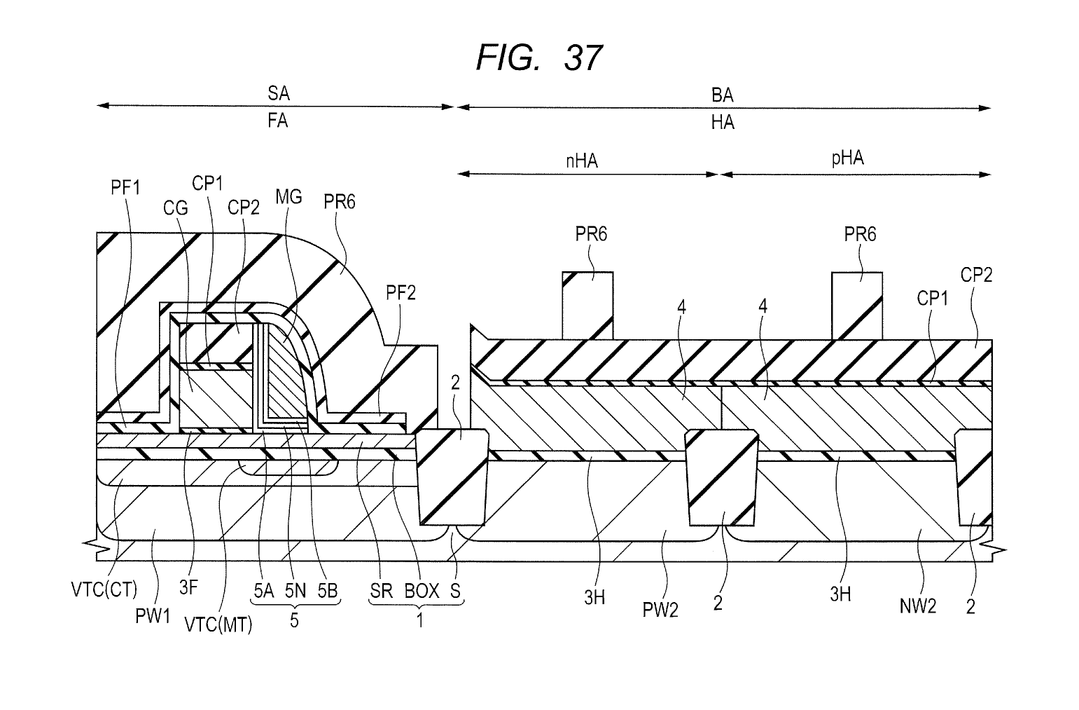

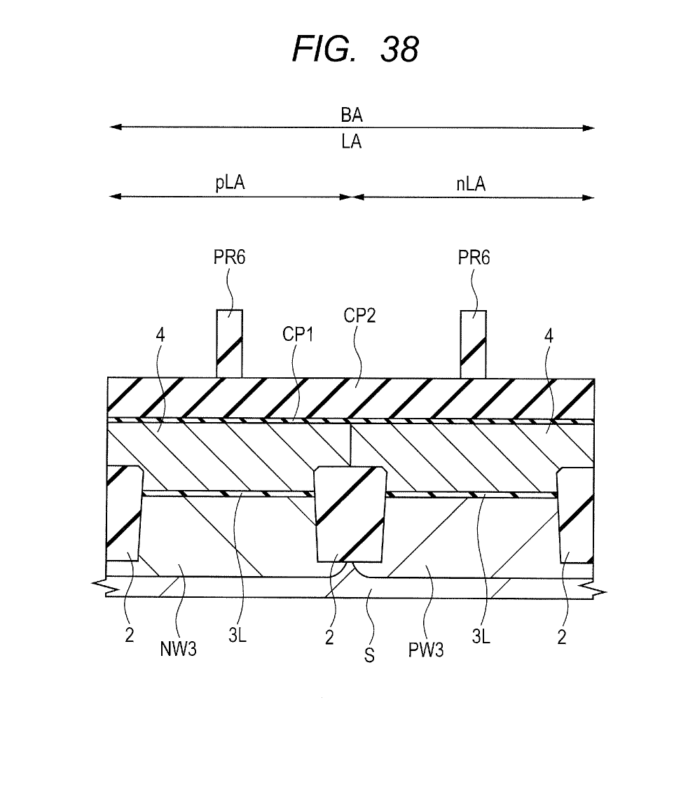

Next, as shown in FIGS. 33 and 34, in the SOI region SA and the bulk region BA, as a protective film, a laminate film of a silicon oxide film PF1 and a silicon nitride film PF2 is formed. For example, the silicon oxide film PF1 is formed by a CVD method and, over the silicon oxide film PF1, the silicon nitride film PF2 is formed by a CVD method. Then, as shown in FIGS. 35 and 36, a photoresist film PR5 is formed to cover the SOI region SA. Using the photoresist film PR5 as a mask, the silicon oxide film PF1 and the silicon nitride film PF2 in the bulk region BA are etched (see FIGS. 37 and 38). Then, the photoresist film PR5 is removed by ashing treatment or the like.

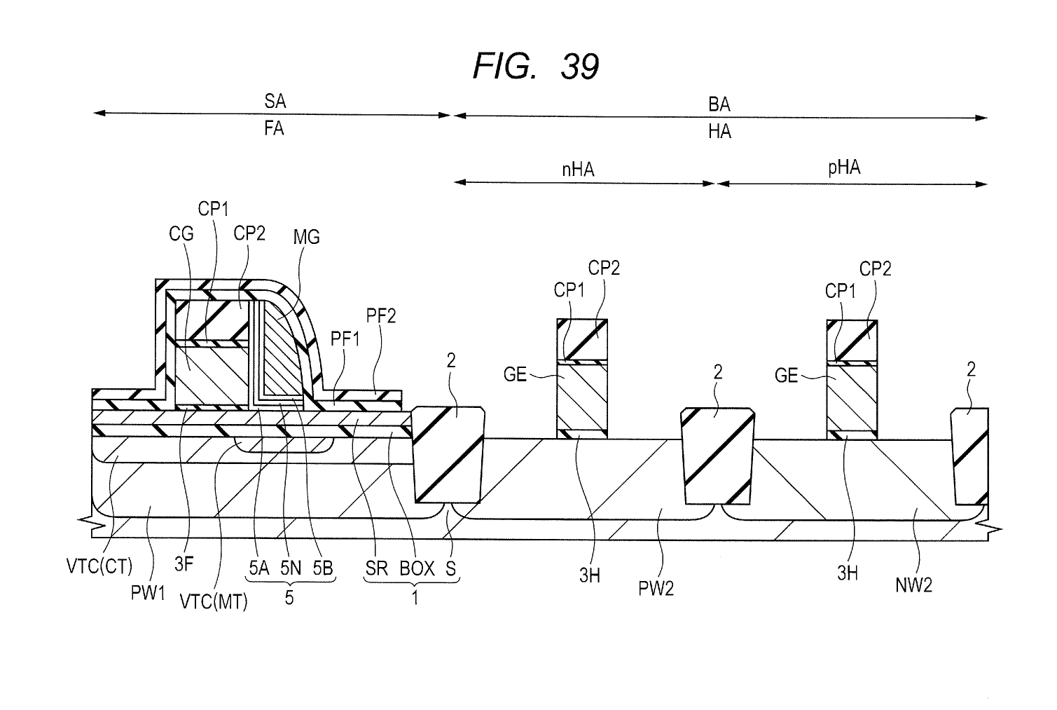

Next, as shown in FIGS. 37 and 38, a photoresist film PR6 is formed to cover the SOI region SA and remain in the region of the bulk region BA where the gate electrode GE is to be formed. Then, using the photoresist film PR6 as a mask, the silicon nitride film CP2, the silicon oxide film CP1, and the silicon film 4 are etched. By subsequently removing the photoresist film PR6 by ashing or the like, as shown in FIGS. 39 and 40, the respective gate electrodes GE of the high-breakdown-voltage n-channel MISFET (HTn) and the high-breakdown-voltage p-channel MISFET (HTp) are formed in the high-breakdown-voltage MISFET formation region HA (regions nHA and pHA) of the bulk region BA. On the other hand, the respective gate electrodes GE of the low-breakdown-voltage n-channel MISFET (LTn) and the low-breakdown voltage p-channel MISFET (LTp) are formed in the low-breakdown-voltage MISFET formation region LA (regions nLA and pLA) of the bulk region BA. The gate length (e.g., about 0.1 to 0.6 μm) of the gate electrode GE of each of the high-breakdown-voltage n-channel MISFET (HTn) and the high-breakdown-voltage p-channel MISFET (HTp) is larger than the gate length (e.g., about 0.05 to 0.06 μm) of the gate electrode GE of each of the low-breakdown-voltage n-channel MISFET (LTn) and the low-breakdown-voltage p-channel MISFET (Lp).

The gate insulating films 3H remaining under the gate electrodes GE serve as the gate insulating films 3H of the MISFETs (HTn and HTp). On the other hand, the gate insulating films 3L remaining under the gate electrodes GE serve as the gate insulating films 3L of the MISFETs (LTn and LTp). Note that the gate insulating films 3H and 3L except for the portions thereof covered by the gate electrodes GE may be removed during the formation of the foregoing gate electrodes GE or may be removed by the subsequent patterning step or the like.

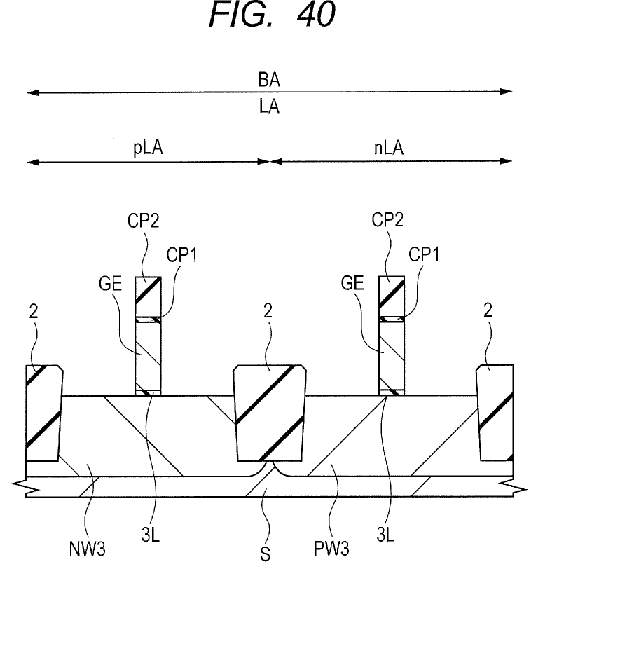

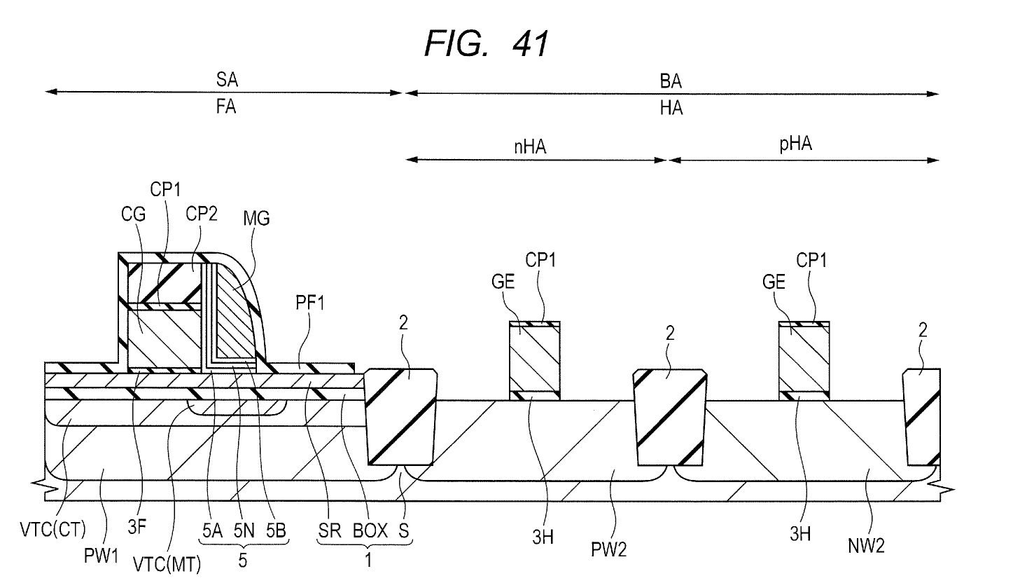

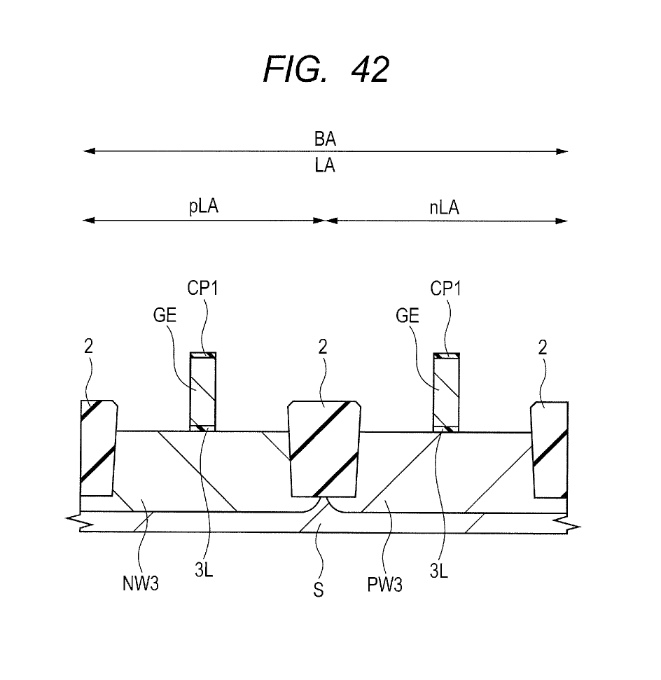

Next, as shown in FIGS. 41 and 42, the silicon nitride film PF2 forming the protective film and the silicon nitride film CP2 over each of the gate electrodes GE are removed by etching.

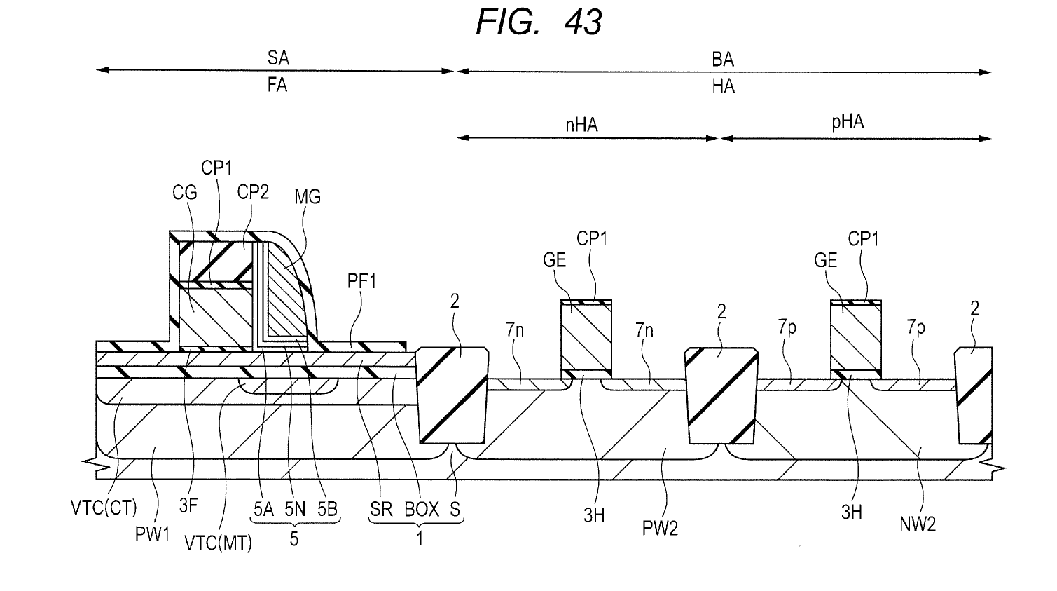

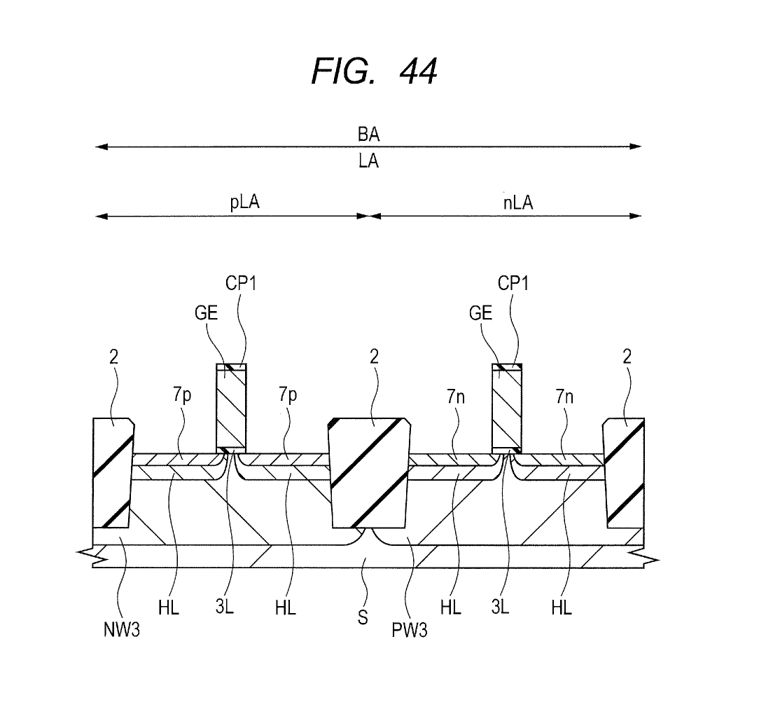

Next, as shown in FIGS. 43 and 44, in the supporting substrate S (p-type wells PW2 and PW3 and n-type wells NW2 and NW3) on both sides of the gate electrodes GE in the bulk region BA, the halo regions (impurity regions) HL, the n⁻-type semiconductor regions 7n, and the p⁻-type semiconductor regions 7p are formed. For example, using a photoresist film (not shown) having an opening corresponding to the region nLA of the bulk region BA where the low-breakdown-voltage n-channel MISFET (LTn) is formed as a mask, a p-type impurity is obliquely implanted. In this manner, in the p-type well PW3 on both sides of the gate electrode GE of the low-breakdown-voltage n-channel MISFET (LTn), the p-type halo regions (p-type impurity regions) HL are formed. On the other hand, using a photoresist film (not shown) having an opening corresponding to the region pLA of the bulk region BA where the low-breakdown-voltage p-channel MISFET (LTp) is formed as a mask, an n-type impurity is obliquely implanted. In this manner, in the n-type well NW3 on both sides of the gate electrode GE of the low-breakdown-voltage p-channel MISFET (LTp), the n-type halo regions (n-type impurity regions) HL are formed (FIGS. 43 and 44).

Next, using a photoresist film (not shown) having respective openings corresponding to the region nLA of the bulk region where the low-breakdown-voltage n-channel MISFET (LTn) is formed and to the region nHA of the bulk region BA where the high-breakdown-voltage n-channel MISFET (HTn) is formed as well as the gate electrodes GE as a mask, in the supporting substrate S (p-type wells PW2 and PW3) on both sides of the gate electrodes GE, an n-type impurity such as arsenic (As) or phosphorus (P) is implanted. In this manner, the n⁻-type semiconductor regions 7n are formed. At this time, the n⁻-type semiconductor regions 7n are formed by self-alignment with the side walls of the gate electrodes GE. On the other hand, using a photoresist film (not shown) having respective openings corresponding to the region pLA of the bulk region BA where the low-breakdown voltage p-channel MISFET (LTp) is formed and to the region pHA of the bulk region BA where the high-breakdown-voltage p-channel MISFET (HTp) is formed as well as the gate electrodes as a mask, in the supporting substrate S (n-type wells NW2 and NW3) on both sides of the gate electrodes GE, a p-type impurity such as boron (B) is implanted. In this manner, the p⁻-type semiconductor regions 7p are formed. At this time, the p⁻-type semiconductor regions 7p are formed by self-alignment with the side walls of the gate electrodes GE. Here, the n⁻-type semiconductor regions 7n in the region nLA where the low-breakdown-voltage n-channel MISFET (LTn) is formed and the n⁻-type semiconductor regions 7n in the region nHA where the high-breakdown-voltage n-channel MISFET (HTn) is formed are formed in the same ion implantation step. However, the n⁻-type semiconductor regions 7n in the regions nLA and nHA may also be formed in different ion implantation steps. Also, the p⁻-type semiconductor regions 7p in the region pLA where the low-breakdown-voltage p-channel MISFET (LTp) is formed and the p⁻-type semiconductor regions 7p in the region pHA where the high-breakdown-voltage p-channel MISFET (HTp) is formed are formed in the same ion implantation step. However, the p⁻-type semiconductor regions 7p in the regions pLA and pHA may also be formed in different ion implantation steps. By thus forming the semiconductor regions 7n and 7p in different ion implantation steps, each of the semiconductor regions 7n and each of the semiconductor regions 7p can be formed to have desired impurity concentrations and desired junction depths.

For example, in the present embodiment, in the region nHA where the high-breakdown-voltage n-channel MISFET (HTn) is formed, phosphorus (P) is implanted under the conditions of 50 KeV and 3e13 cm⁻² while, in the region pHA where the high-breakdown-voltage p-channel MISFET (HTp) is formed, boron (B) is implanted under the conditions of 20 KeV and 3e13 cm⁻². On the other hand, in the region nLA where the low-breakdown-voltage n-channel MISFET (LTn) is formed, arsenic (As) is implanted under the conditions of 2 KeV and 1.5e15 cm⁻² and boron difluoride is implanted to form the halo regions HL under the conditions of 30 KeV and 4e13 cm⁻² while, in the region pLA where the low-breakdown-voltage p-channel MISFET (LTp) is formed, boron fluoride is implanted under the conditions of 2 KeV and 1e15 cm⁻² and phosphorus (P) is implanted to form the halo regions HL under the conditions of 25 KeV and 2e13 cm⁻².

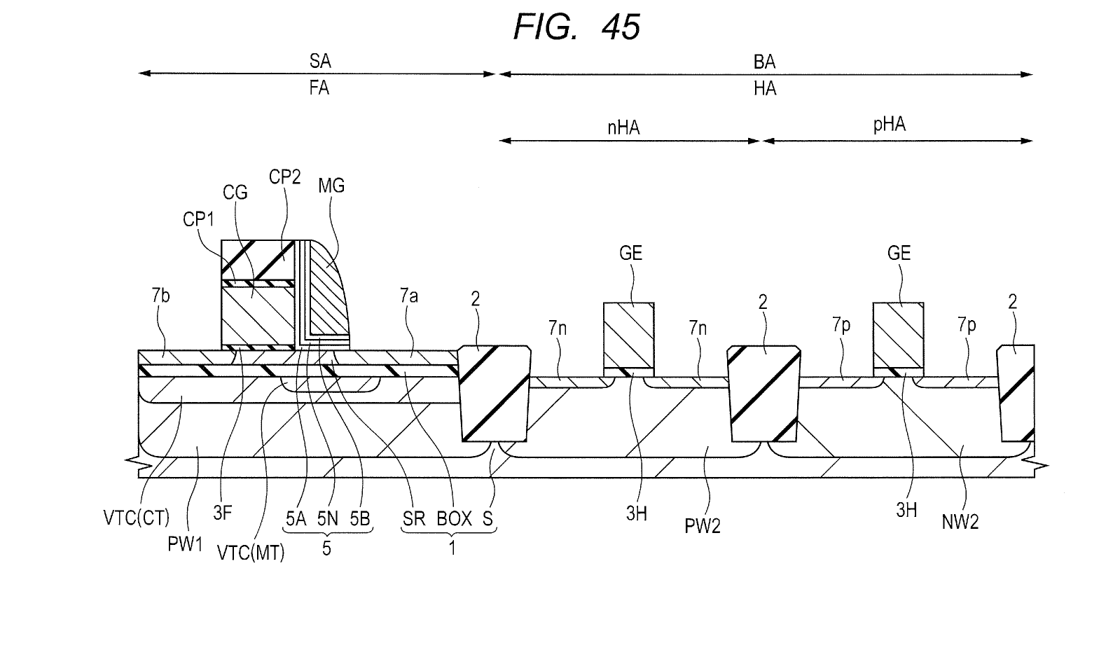

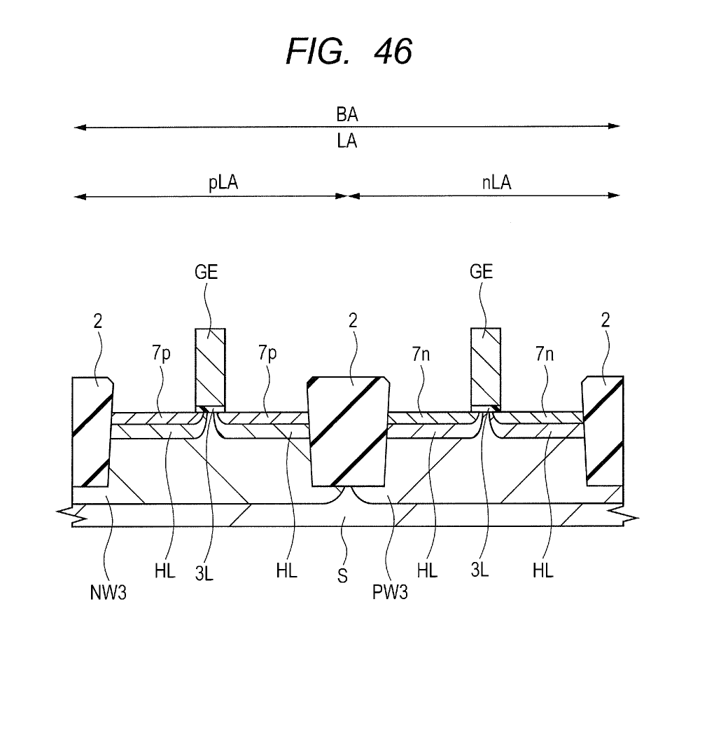

Next, as shown in FIGS. 45 and 46, the silicon oxide film PF1 forming the protective film and the silicon oxide films CP1 over the gate electrodes GE are removed by etching. Then, in the silicon layer SR in the SOI region SA, an n-type impurity such as arsenic (As) or phosphorus (P) is implanted to form the n⁻-type semiconductor region 7a and the n⁻-type semiconductor region 7b. At this time, the n⁻-type semiconductor region 7a is formed by self-alignment with the side wall (side wall opposite to the side wall adjacent to the control gate electrode CG via the insulating film 5) of the memory gate electrode MG. On the other hand, the n⁻-type semiconductor region 7b is formed by self-alignment with the side wall (side wall opposite to the side wall adjacent to the memory gate electrode MG via the insulating film 5) of the control gate electrode CG.

The n⁻-type semiconductor regions 7a, 7b, and 7n may be formed in the same ion implantation step, but are formed herein in different ion implantation steps. By thus forming the n⁻-type semiconductor regions 7a, 7b, and 7n in the different ion implantation steps, each of the n⁻-type semiconductor regions 7a, 7b, and 7n can be formed to have a desired impurity concentration and a desired junction depth.

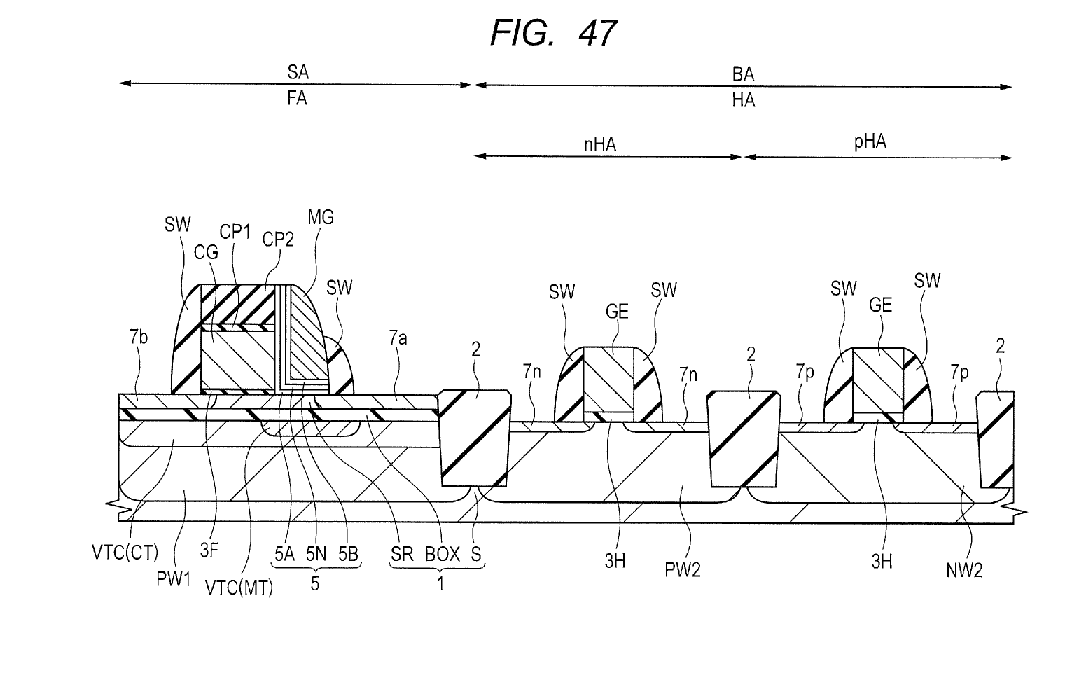

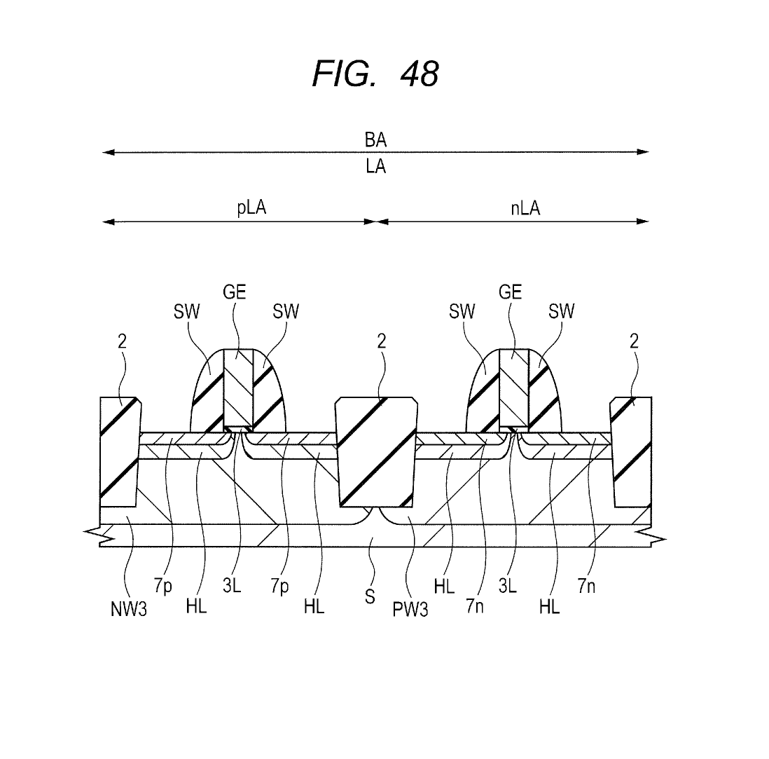

Next, as shown in FIGS. 47 and 48, in the SOI region SA, the side-wall insulating films SW are formed over the side wall portions of the composite pattern of the control gate electrode CG and the memory gate electrode MG. On the other hand, in the bulk region BA, the side-wall insulating films SW are formed over the side wall portions of the gate electrodes GE. For example, all over the SOI region SA and the bulk region BA, an insulating film formed of a silicon oxide film or the like is formed. By etching back the insulating film, over the side wall portions of the foregoing composite pattern (CG and MG) and the side wall portions of the gate electrodes GE, the side-wall insulating films SW are formed. As each of the side-wall insulating films SW, not only the silicon oxide film, but also a silicon nitride film, a laminate film of a silicon oxide film and a silicon nitride film, or the like may also be used.

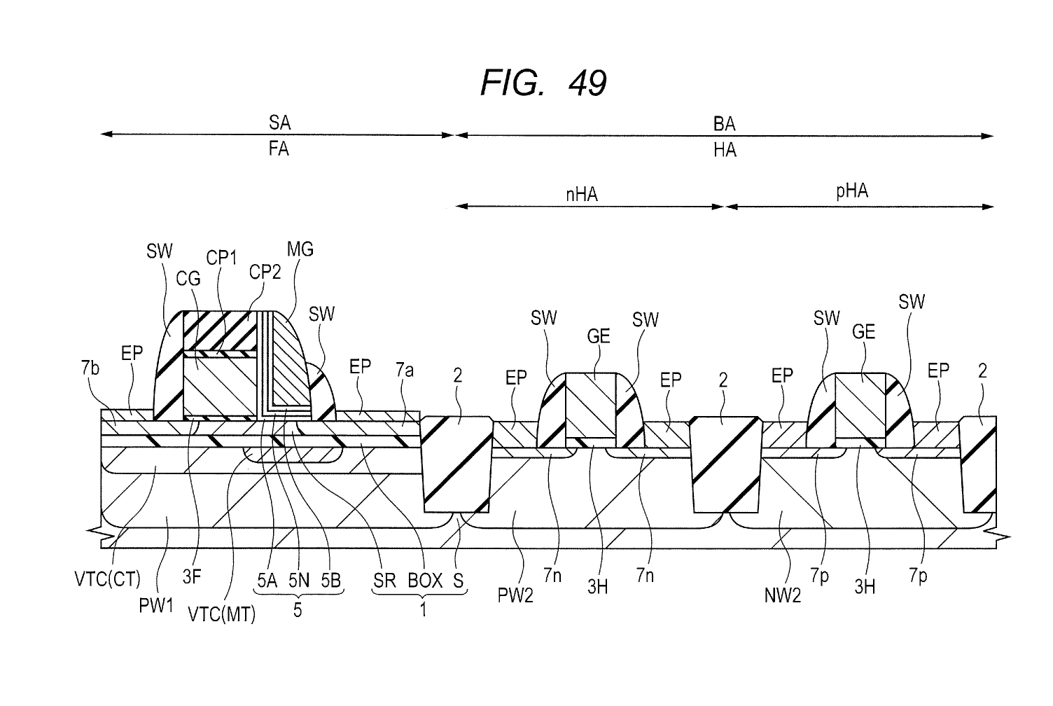

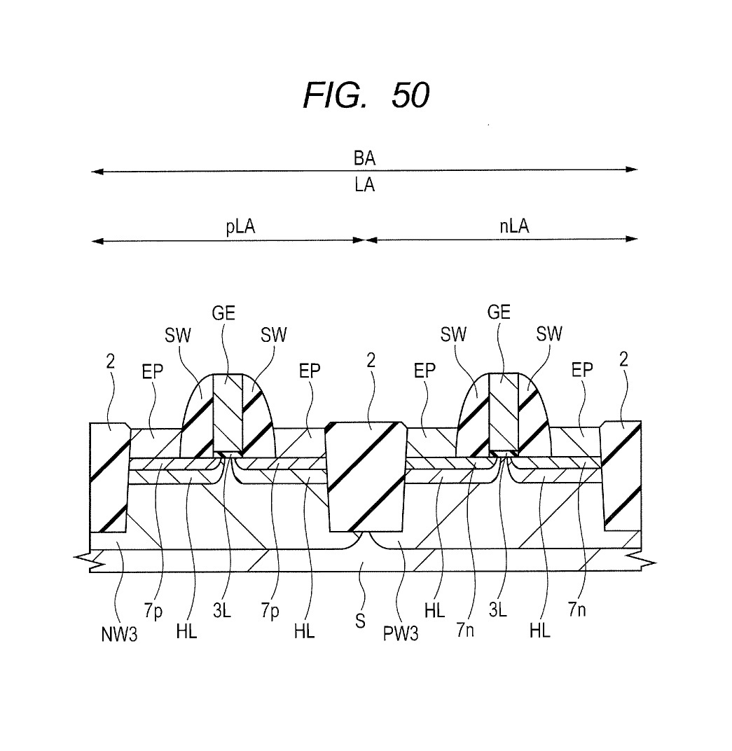

Next, as shown in FIGS. 49 and 50, over the supporting substrate S (n⁻-type semiconductor regions 7n and 7p) exposed in the bulk region BA and over the silicon layer SR (n⁻-type semiconductor regions 7a and 7b) exposed in the SOI region SA, the epitaxial layers EP each having a film thickness of about 50 nm are formed using an epitaxial growth method (referred to also as a crystal growth method).

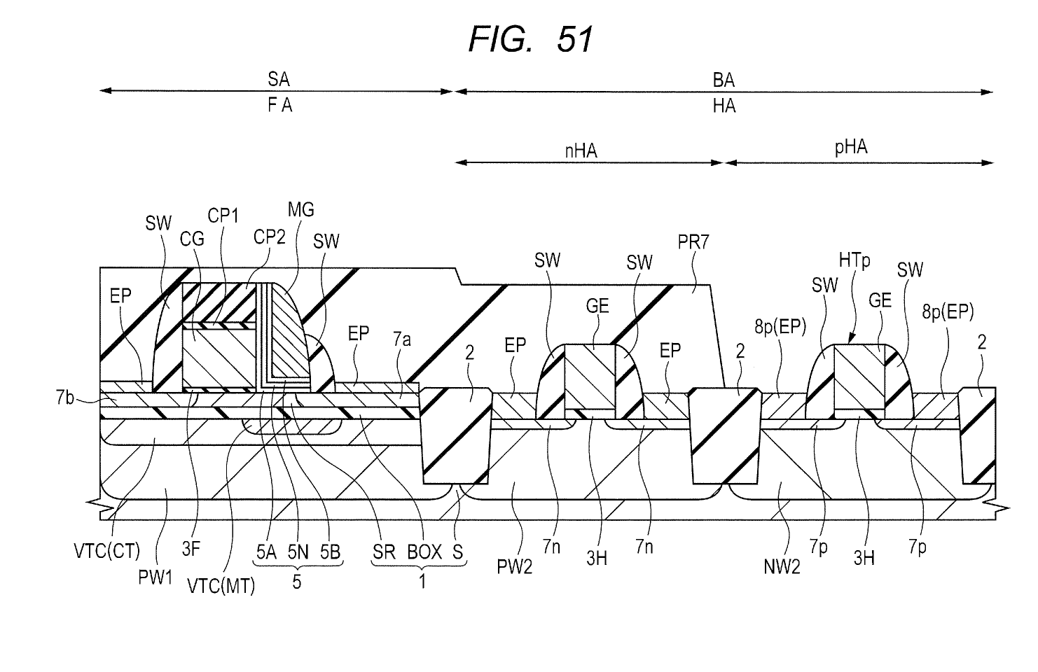

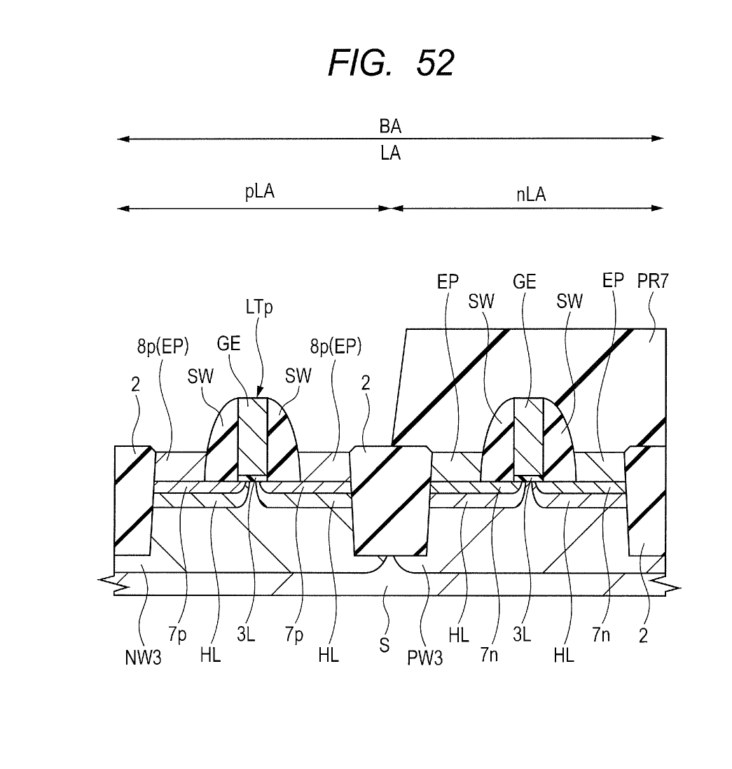

Next, as shown in FIGS. 51 and 52, a photoresist film PR7 is formed to cover the SOI region SA, the region nLA of the bulk region BA where the low-breakdown-voltage n-channel MISFET (LTn) is formed, and the region nHA of the bulk region BA where the high-breakdown-voltage n-channel MISFET (HTn) is formed. Using the photoresist film PR7 and the gate electrodes GE as a mask, a p-type impurity such as boron (B) is implanted into the epitaxial layers EP on both sides of the gate electrodes GE to form the p⁺-type semiconductor regions 8p. At this time, the p⁺-type semiconductor regions 8p are formed by self-alignment with the side walls of the gate electrodes GE. The p⁺-type semiconductor regions 8p are formed to have impurity concentrations higher than those of the p⁻-type semiconductor regions 7p.

Here, the p⁺-type semiconductor regions 8p in the region pLA where the low-breakdown-voltage p-channel MISFET (LTp) is formed and the p⁺-type semiconductor regions 8p in the region pHA where the high-breakdown-voltage p-channel MISFET (HTp) is formed are formed in the same ion implantation step. However, these p⁺-type semiconductor regions 8p may also be formed in different ion implantation steps. By thus forming these p⁺-type semiconductor regions 8p in different ion implantation steps, each of the semiconductor regions 8p can be formed to have a desired impurity concentration. Then, the photoresist film PR7 is removed by ashing treatment or the like.

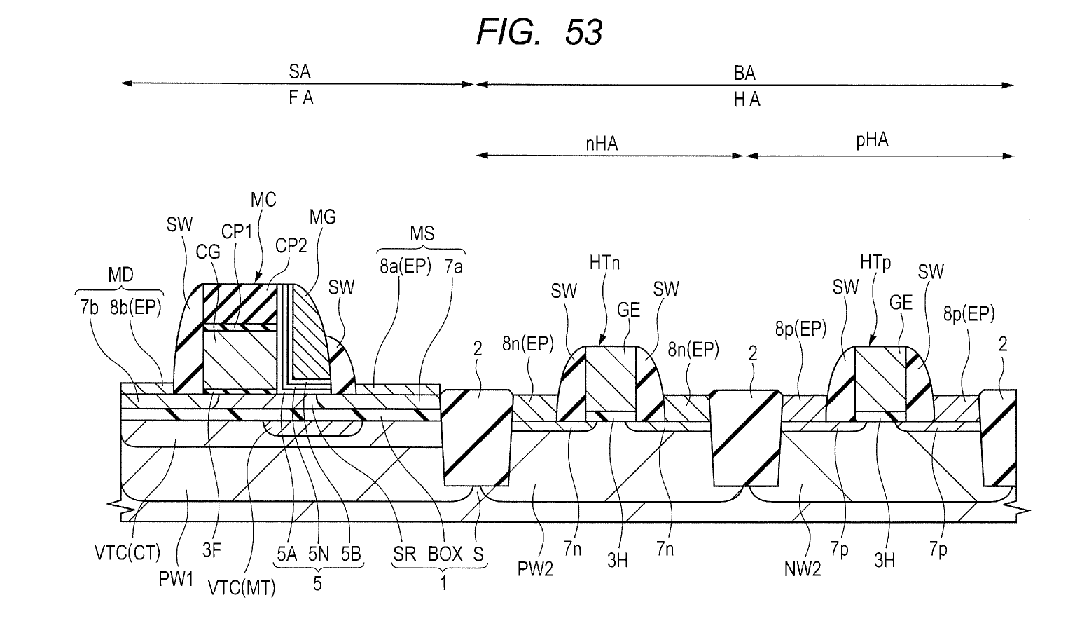

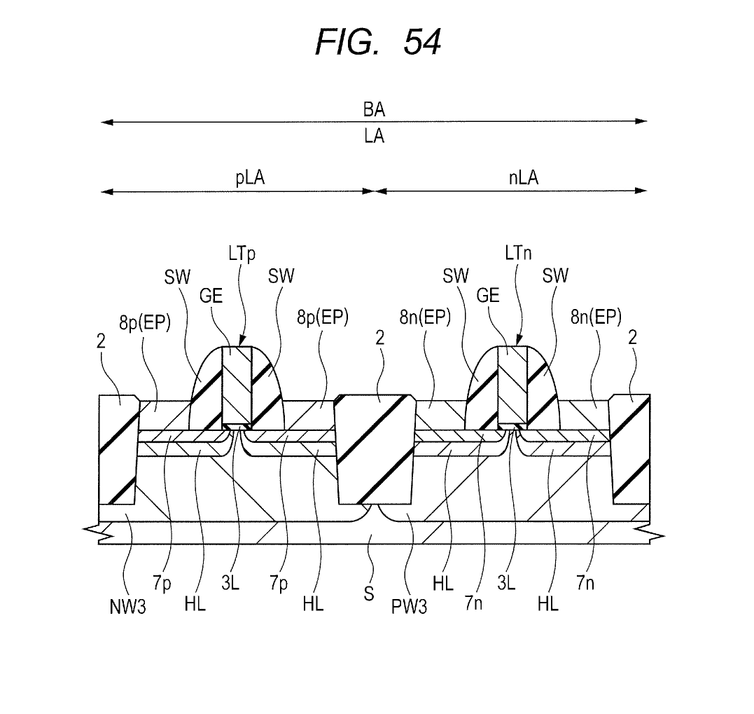

Next, as shown in FIGS. 53 and 54, a photoresist film (not shown) is formed to cover the region pLA of the bulk region BA where the low-breakdown-voltage p-channel MISFET (LTp) is formed and the region pHA of the bulk region BA where the high-breakdown-voltage p-channel MISFET (HTp) is formed. Using the photoresist film (not shown) and the gate electrodes GE as a mask, in the epitaxial layers EP on both sides of the gate electrodes GE, an n-type impurity such as arsenic (As) or phosphorus (P) is implanted to form the n⁺-type semiconductor regions 8a, 8b, and 8n. At this time, the n⁺-type semiconductor regions 8n are formed by self-alignment with the side walls of the gate electrodes GE. The n⁺-type semiconductor regions 8n are formed to have impurity concentrations higher than those of the n⁻-type semiconductor regions 7n. The n⁺-type semiconductor region 8a is formed by self-alignment with the side-wall insulating film SW on the memory gate electrode MG side. The n⁺-type semiconductor region 8b is formed by self-alignment with the side-wall insulating film SW on the control gate electrode CG side. These n⁺-type semiconductor regions 8a and 8b are formed to have impurity concentrations higher than those of the n⁻-type semiconductor regions 7a and 7b.

Here, the n⁺-type semiconductor regions 8n in the region nLA where the low-breakdown-voltage n-channel MISFET (LTn) is formed, the n⁺-type semiconductor regions 8n in the region nHA where the high-breakdown-voltage n-channel MISFET (HTn) is formed, and the n⁺-type semiconductor regions 8a and 8b in the SOI region SA are formed in the same ion implantation step. However, these n⁺-type semiconductor regions 8n, 8a, and 8b may also be formed in different ion implantation steps. By thus forming the n⁺-type semiconductor regions 8n, 8a, and 8b in different ion implantation steps, each of the semiconductor regions can be formed to have a desired impurity concentration.

For example, in the present embodiment, the n⁺-type semiconductor regions 8n are formed by implanting arsenic (As) under the conditions of 20 KeV and 2e15 cm⁻² and implanting phosphorus (P) under the conditions of 10 KeV and 2e15 cm⁻². Note that the n⁺-type semiconductor regions 8a and 8b may also be formed under similar conditions. On the other hand, to form the p⁺-type semiconductor regions 8p, boron (B) is implanted under the conditions of 2 KeV and 4e15 cm⁻². At the time of such ion implantation, to reduce an electric field at the junction, additional field reducing implantation may also be performed.

By the foregoing steps, in the SOI region SA, the n-type drain region MD including the n⁻-type semiconductor region 7b and the n⁺-type semiconductor region 8b and functioning as the drain region of the memory transistor is formed and the n-type source region MS including the n⁻-type semiconductor region 7a and the n⁺-type semiconductor region 8a and functioning as the source region of the memory transistor is formed. On the other hand, in the bulk region BA, the source/drain regions (7n, 7p, 8n, and 8p) each having an LDD structure including a lower-concentration impurity region and a higher-concentration impurity region are formed.

Next, heat treatment (activation treatment) for activating the impurities introduced in the source region MS (n⁻-type semiconductor region 7a and n⁺-type semiconductor region 8a), the drain region MD (n⁻-type semiconductor region 7b and n⁺-type semiconductor region 8b), and the source/drain regions (7n, 7p, 8n, and 8p) is performed. For example, in the present embodiment, spike annealing at about 1000° C. and laser annealing are used in combination. By thus performing the high-temperature heat treatment for a short time, it is possible to suppress redistribution of the impurities, particularly boron having a large diffusion coefficient in silicon, and suppress the degradation of a short-channel property. By also depositing a stress application film such as a silicon nitride film in the SOI region SA and the bulk region BA prior to the heat treatment step and subjecting the stress application film to the foregoing heat treatment, stress can be applied to each of the gate electrodes (GE, MG, and CG). This allows the mobility of each of the transistors to be varied and allows an improvement in the current driving ability of the transistor.

By the foregoing steps, the memory cells MC are formed in the SOI region SA and the MISFETs (LTn, LTp, HTn, and HTp) are formed in the bulk region BA (see FIGS. 53 and 54).

Note that the steps of forming the memory cells MC and the steps of forming each of the MISFETs are not limited to the foregoing steps.

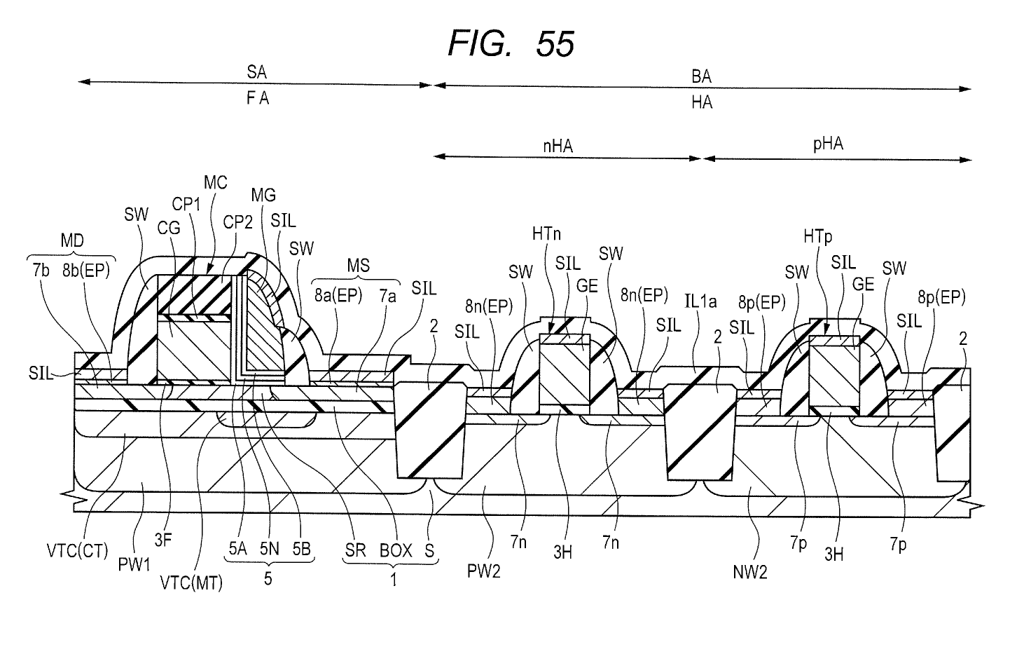

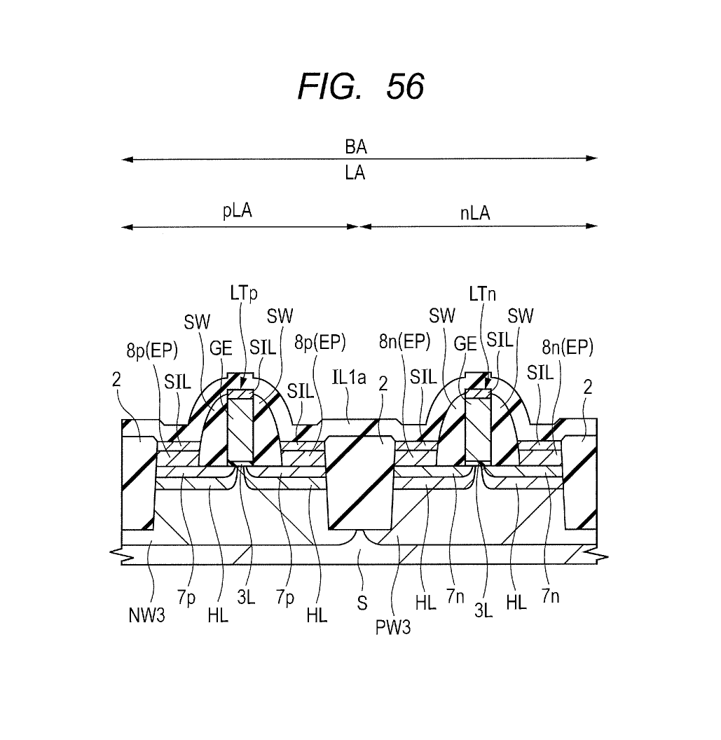

Next, as shown in FIGS. 55 and 56, using a salicide technique, a metal silicide layer (metal silicide film) SIL is formed over each of the memory gate electrode MG, the n⁺-type semiconductor region 8a, and the n⁺-type semiconductor region 8b in the SOI region SA. On the other hand, in the bulk region BA, the metal silicide layer SIL is formed over each of the gate electrodes GE, the n⁺-type semiconductor regions 8n, and the p⁺-type semiconductor regions 8p.

The metal silicide layers SIL can reduce resistances such as diffusion resistance and contact resistance. The metal silicide layers SIL can be formed as follows.

For example, all over the SOI region SA and the bulk region BA, a metal film (not shown) is formed and, by subjecting the SOI substrate 1 to heat treatment, the upper portions of the memory gate electrode MG, the n⁺-type semiconductor region 8a, the n⁺-type semiconductor region 8b, the gate electrodes GE, the n⁺-type semiconductor regions 8n, and the p⁺-type semiconductor regions 8p are caused to react with the foregoing metal film. Thus, over each of the memory gate electrode MG, the n⁺-type semiconductor region 8a, the n⁺-type semiconductor region 8b, the gate electrodes GE, the n⁺-type semiconductor regions 8n, and the p⁺-type semiconductor regions 8p, the metal silicide layer SIL is formed. The foregoing metal film is formed of, e.g., a cobalt (Co) film, a nickel (Ni) film, or the like and can be formed using a sputtering method or the like. Then, the unreacted metal film is removed.

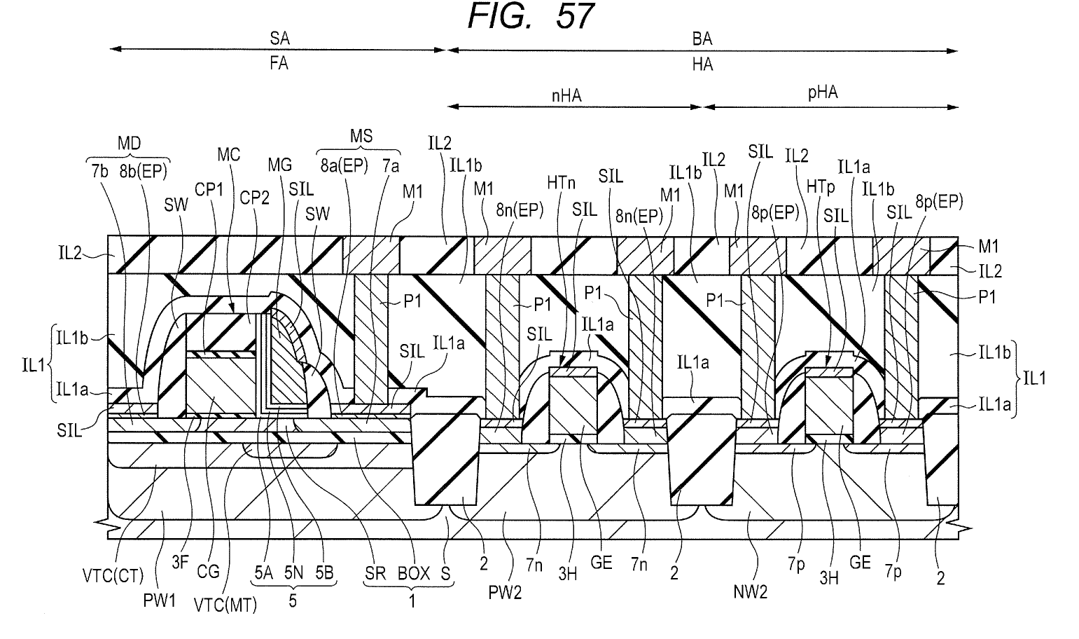

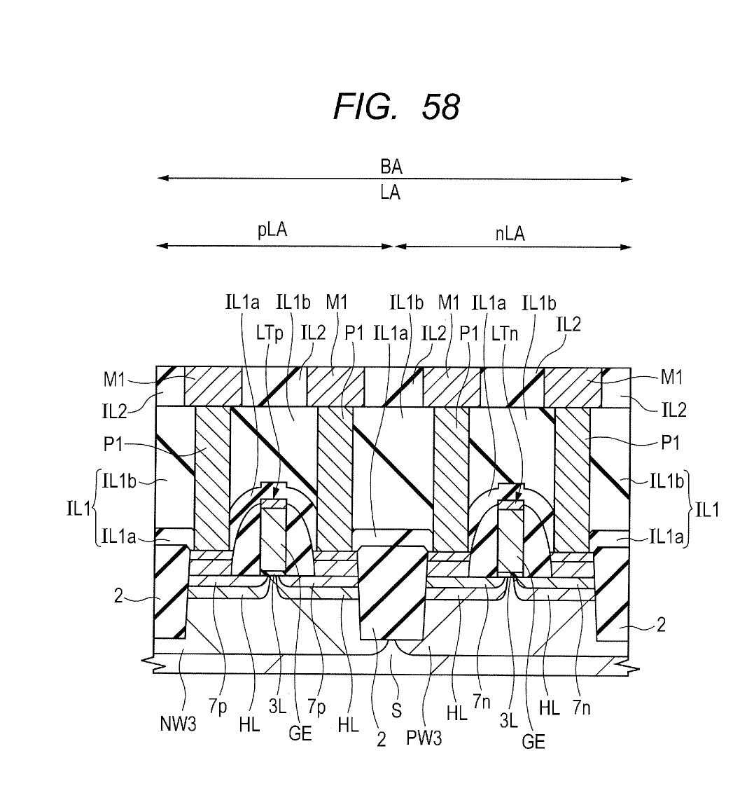

Then, all over the SOI region SA and the bulk region BA, an insulating film (interlayer insulating film) IL1 is formed. For example, as shown in FIGS. 55 and 56, all over the SOI region SA and the bulk region BA, a silicon nitride film IL1a is formed to a thickness of about 50 to 100 nm using a CVD method or the like. Then, over the silicon nitride film, a silicon oxide film IL1b formed to be thicker than the silicon nitride film is formed using a CVD method or the like. In this manner, the insulating film (interlayer insulating film) IL1 formed of a laminate film of the silicon nitride film IL1a and the silicon oxide film IL1b can be formed. After the formation of the insulating film IL1, the upper surface of the insulating film IL1 is planarized as necessary using a CMP method or the like (see FIGS. 57 and 58).

Next, as shown in FIGS. 57 and 58, the insulating film IL1 is dry-etched to form contact holes (openings or through holes) in the insulating film IL1. Then, in each of the contact holes, a laminate film of a barrier conductor film and a main conductor film is formed. Then, the unneeded portions of the main conductor film and the barrier conductor film over the insulating film IL1 are removed by a CMP method, an etch-back method, or the like to form plugs P1. The plugs P1 are formed over, e.g., the n⁺-type semiconductor region 8a, the n⁺-type semiconductor regions 8n, and the p⁺-type semiconductor regions 8p via the metal silicide layers SIL. The plugs P1 are also formed over, e.g., the control gate electrode CG, the memory gate electrode MG, and the gate electrodes GE, though not shown in the cross sections shown in FIGS. 57 and 58. Note that, as the barrier conductor film, e.g., a titanium film, a titanium nitride film, or a laminate film thereof can be used. As the main conductor film, a tungsten film or the like can be used.

Next, over the insulating film IL1 in which the plugs P1 are embedded, first-layer interconnects M1 are formed. The interconnects M1 are formed using, e.g., a damascene technique (which is a single-damascene technique herein). First, over the insulating film in which the plugs P1 are embedded, an insulating film IL2 for trenches is formed and, in the insulating film IL2 for trenches, interconnect trenches are formed using a photolithographic technique and a dry etching technique. Then, over the insulating film IL1 including the inside of each of the interconnect trenches, a barrier conductor film (not shown) is formed and, subsequently, copper seed layer (not shown) is formed over the barrier, conductor film by a CVD method, a sputtering method, or the like. Then, using an electrolytic plating method or the like, a copper plating film is formed over the seed layer such that the interconnect trenches are filled with the copper plating film. Thereafter, by removing the copper plating film, the seed layer, and the barrier metal film located in the region other than the inside of each of the interconnect trenches by a CMP method, the first-layer interconnects M1 containing copper as a main conductive material are formed. Note that, as the barrier conductor film, e.g., a titanium nitride film, a tantalum film, a tantalum nitride film, or the like can be used.

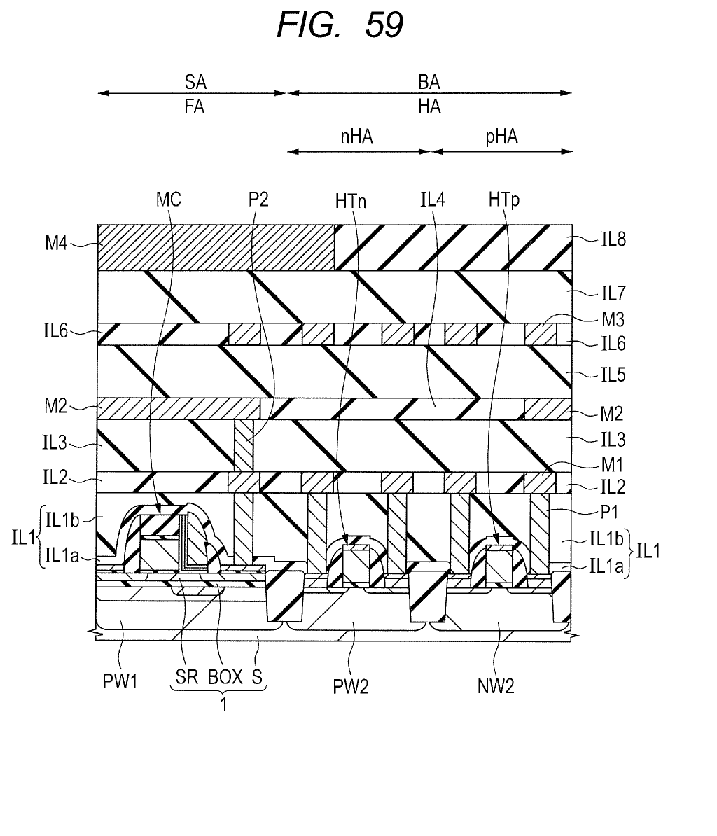

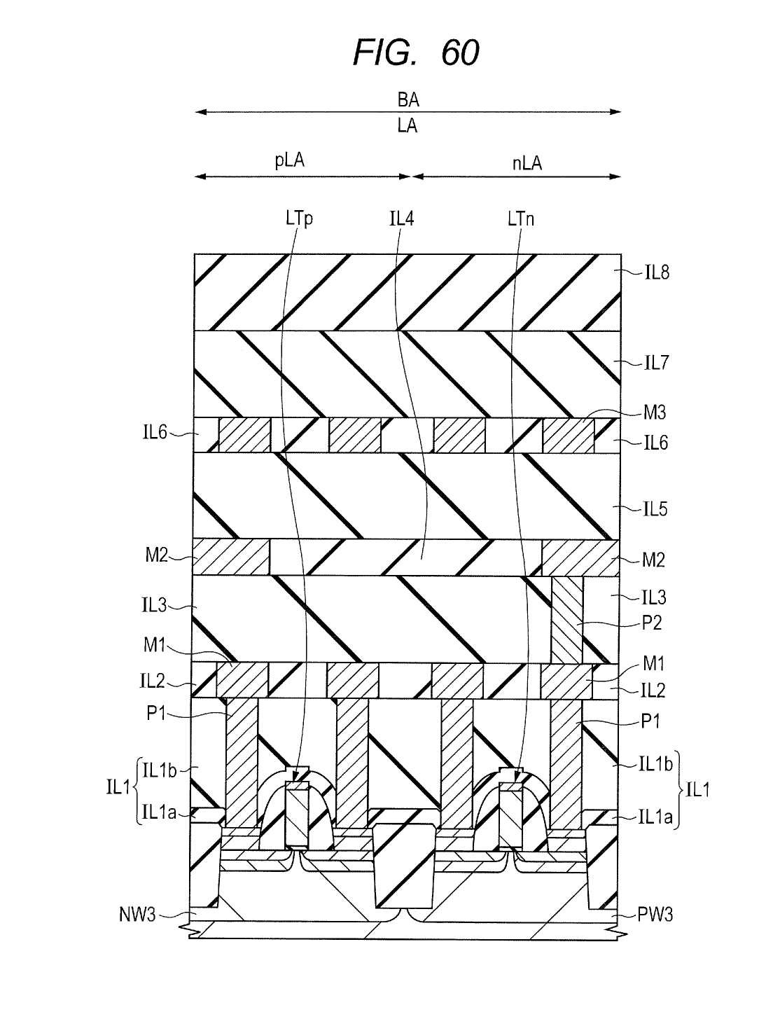

Then, as shown in FIGS. 59 and 60, the second-layer and higher-order-layer interconnects M2, M3, and M4, plugs P2, and the like are formed by a dual damascene method or the like. For example, in a laminate film of an insulating film IL3 and an insulating film IL4, contact holes and interconnect trenches are formed and, in the same manner as in the case where the interconnects M1 are formed, these contact holes and interconnect trenches are filled with a copper plating film using an electrolytic plating method or the like. Thereafter, the copper plating film located in the region other than the inside of each of the interconnect trenches is removed by CMP method or the like to form the plugs P2 and the interconnects M2. Likewise, in insulating films I15 to IL8, the interconnects M3 and M4 and the like can further be formed.

Thus, according to the present embodiment, the memory cells MC are placed in the SOI region SA, and the impurity region VTC(CT) for adjusting the threshold of the control transistor and the impurity region VTC(MT) for adjusting the threshold of the memory transistor are provided. This can improve the performance of each of the memory cells MC. Specifically, variations in the thresholds of the control transistor and the memory transistor can be reduced. In addition, the GiDL can be reduced. Moreover, the disturb in the memory cell MC can be improved.

Also, the impurity region VTC(CT) for adjusting the threshold of the control transistor is formed by ion-implanting a p-type impurity (such as boron (B)), and the impurity region VTC(MT) for adjusting the threshold of the memory transistor is formed by ion-implanting an n-type impurity (such as arsenic or phosphorus (P)) of the conductivity type opposite to the p-type into the region in which the p-type impurity has been ion-implanted. This facilitates the adjustment of the impurity concentrations. Specifically, the impurity region VTC(MT) for adjusting the threshold of the memory transistor can easily be formed as an impurity region having a concentration lower than that of the impurity region VTC(CT) for adjusting the threshold of the control transistor.

### Embodiment 2

In Embodiment 1, the memory cells MC are formed in the SOI region (SA), and the other elements (low-breakdown-voltage MISFETs (LTn and LTp), high-breakdown-voltage MISFETs (HTn and HTp), SRAM memory cell, and analog circuit) are formed in the bulk region BA. However, the memory cells MC and the SRAM memory cell may also be formed in the SOI region (SA).

<Description of Structure>

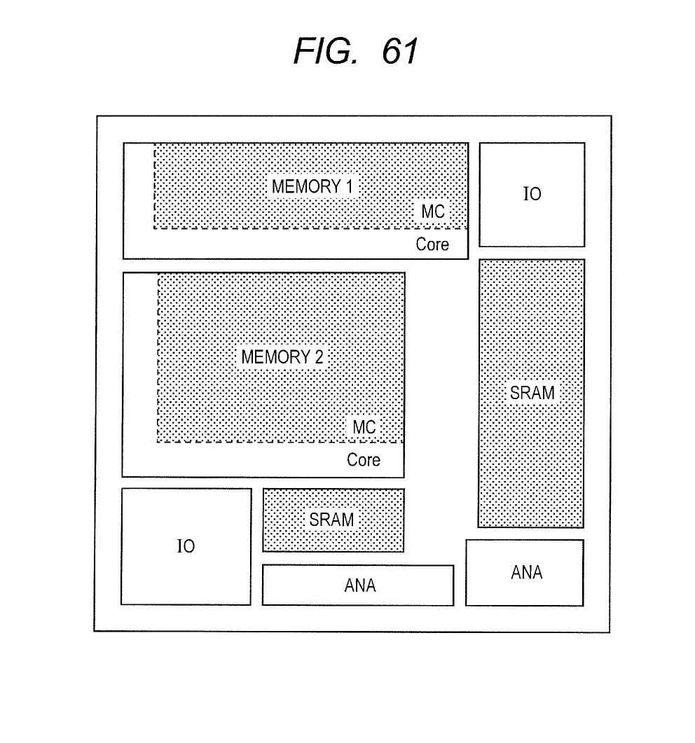

FIG. 61 is a plan view showing an example of a microcomputer chip (SOC) to which a semiconductor device of the present embodiment is applied.

For example, in the microcomputer chip shown in FIG. 61, there are the first memory region (Memory 1) and the second memory region (Memory 2) in each of which the memory cell (referred to also as nonvolatile memory cell, nonvolatile storage element, nonvolatile semiconductor storage device, EEPROM, flash memory, FMONOS, or NMONOS) MC is placed. Around the first memory region (Memory 1) and the second memory region (Memory 2), the core regions (Core) are provided. In the core regions (Core), the low-breakdown-voltage MISFETs (LTn and LTp) described later and the like are placed. Also in the microcomputer chip, the IO regions (IO) are provided. In the IO regions (IO), the high-breakdown-voltage MISFETs (HTn and HTp) described later and the like are placed. In the microcomputer chip, the SRAM region (SRAM) where the SRAM memory cell is placed, the analog region (ANA) where the analog circuit is placed, and the like are provided.

Here, in the present embodiment, in addition to the first memory region (Memory 1) and the second memory region (Memory 2) in each of which the memory cell MC is placed, the SRAM region where the SRAM memory cell is placed is assumed to be the SOI region (SA) and the other region is assumed to be the bulk region (BA). That is, the memory cells MC and the SRAM memory cell are formed in the SOI region (SA), while the other elements (low-breakdown-voltage MISFETs (LTn and LTp), high-breakdown-voltage MISFETs (HTn and HTp), and analog circuit) are formed in the bulk region BA.

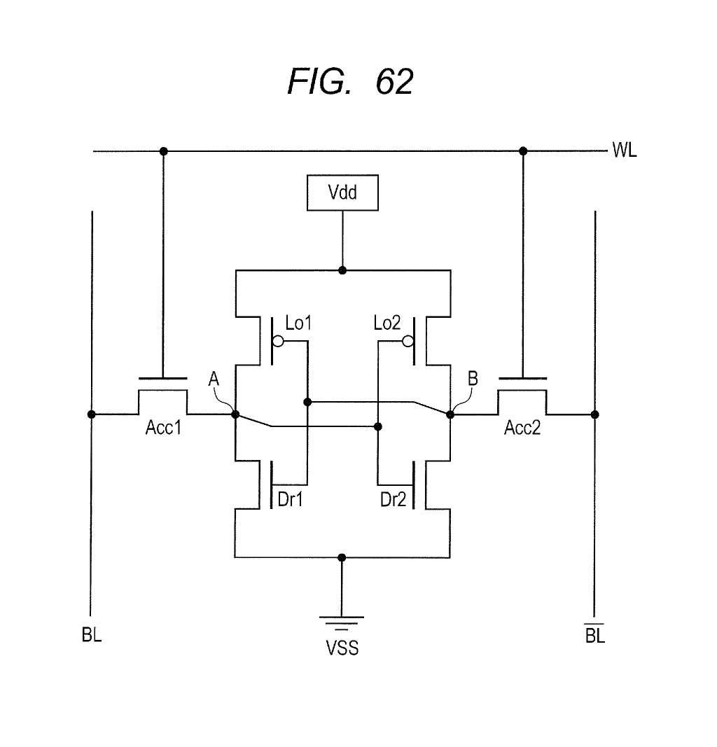

FIG. 62 is an equivalent circuit diagram showing an example of the memory cell in the SRAM. As shown in the drawing, the memory cell is placed at the intersection of a pair of bit lines (bit line BL and bit line/BL) and a word line WL. The memory cell has a pair of load transistors (load MOS transistors, transistors for loads, or MISFETs for load) Lo1 and Lo2, a pair of access transistors (access MOS transistors, transistors for access, access MISFETs, transistors for transfer) Acc1 and Acc2, and a pair of driver transistors (driver MOS transistors, transistors for driving, or MISFETs for driving) Dr1 and Dr2.

Of the foregoing six transistors forming the foregoing memory cell, the load transistors (Lo1 and Lo2) are p-type (p channel) transistors, and the access transistors (Acc1 and Acc2) and the driver transistors (Dr1 and Dr2) are n-type (n-channel) transistors.

Of the foregoing six transistors forming the foregoing memory cell, the load transistor Lo1 and the driver transistor Dr1 form a CMOS inverter and the load transistor Lo2 and the driver transistor Dr2 form another CMOS inverter. The respective input/output terminals (storage nodes A and B) of the pair of CMOS inverters are cross-linked to form a flip-flop circuit as an information storage portion for storing therein 1-bit information.

The following is a detailed description of coupling relations among the six transistors forming the foregoing SRAM memory cell.

Between the power source potential (first potential) Vdd and the storage node A, the load transistor Lo1 is coupled. Between the storage node A and a ground potential (GND, 0 V, reference potential, or second potential lower than the foregoing first potential) VSS, the driver transistor Dr1 is coupled. The respective gate electrodes of the load transistor Lo1 and the driver transistor Dr1 are coupled to the storage node B.

Between the power source potential Vdd and the storage node B, the load transistor Lo2 is coupled. Between the storage node B and the ground potential VSS, the driver transistor Dr2 is coupled. The respective gate electrodes of the load transistor Lo2 and the driver transistor Dr2 are coupled to the storage node A.

Between the bit line BL and the storage node A, the access transistor Acc1 is coupled. Between the bit line /BL and the storage node B, the access transistor Acc2 is coupled. The respective gate electrodes of the access transistors Acc1 and Acc2 are coupled to the word line WL (serve as the word line).

The transistors (MISFETs) forming the memory cell of such a SRAM as described above may also be formed in the SOI region (SA).

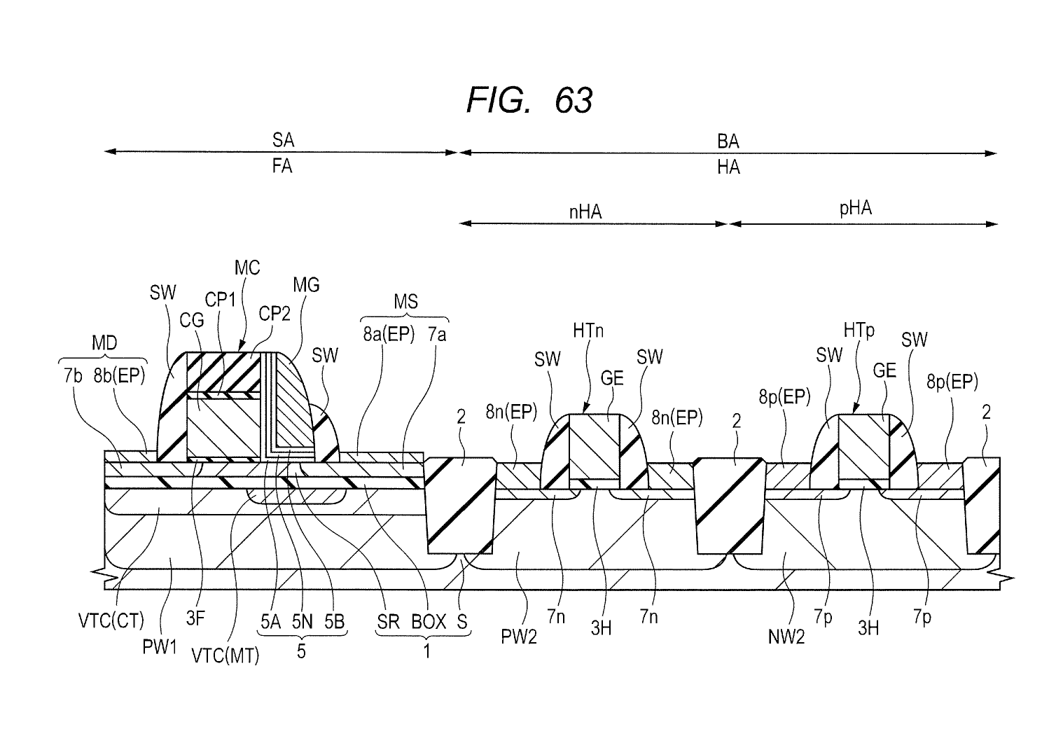

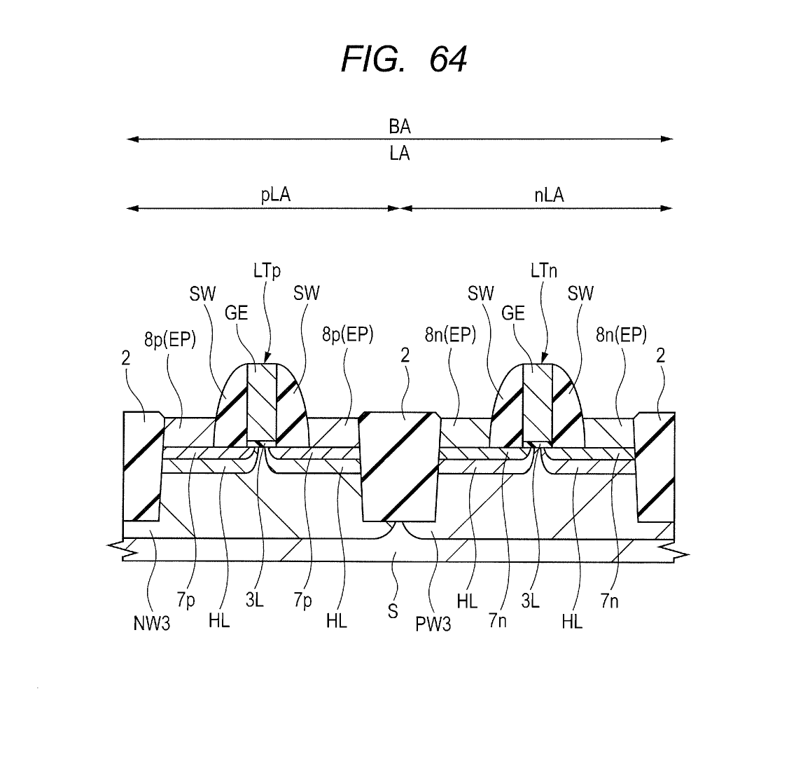

FIGS. 63 to 65 are cross-sectional views each showing a configuration of the semiconductor device of the present embodiment.

As shown in FIGS. 63 to 65, the semiconductor device of the present embodiment has the memory cell MC formed in an FMONOS formation region FA of the SOI region SA of the SOI substrate 1 and transistors (MISFETs) Tn1 and Tn2 forming the memory cell in the SRAM formed in an SRAM formation region SRA of the SOI region SA of the SOI substrate 1. In addition, the semiconductor device of the present embodiment has elements other than the memories such as the four MISFETs (HTn, HTp, LTn, and LTp) formed in the bulk region BA. What is different from the case in Embodiment 1 is only the portion of the memory cell in the SRAM formed in the SRAM formation region SRA of the SOI region SA of the SOI substrate 1. Therefore, a more detailed description will be given of the portion.

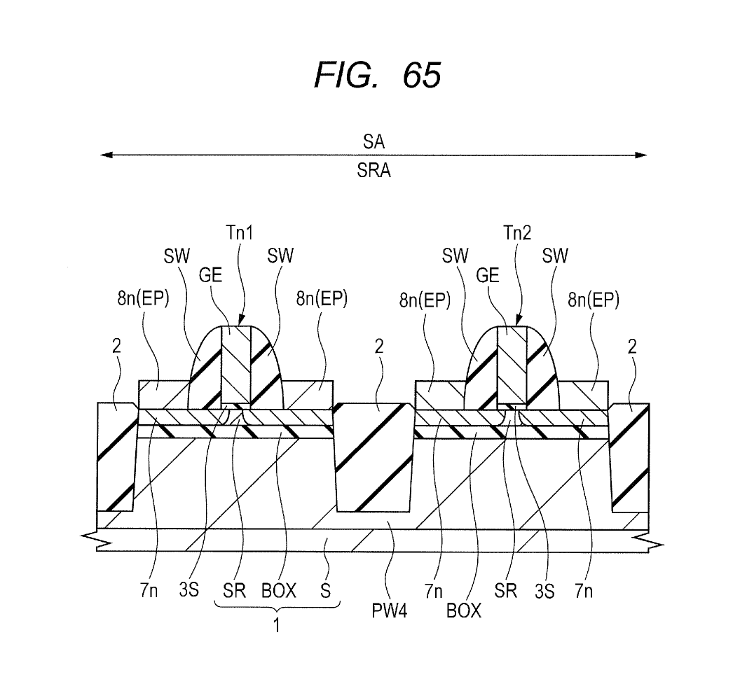

In the SOI region SA, the silicon layer (referred to also as SOI layer, semiconductor layer, semiconductor film, thin semiconductor film, or thin-film semiconductor region) SR is placed over the supporting substrate S via the insulating layer BOX. In the main surface of the silicon layer SR, the memory cell MC and the transistors (MISFETs) Tn1 and Tn2 forming the memory cell in the SRAM are formed (see FIGS. 63, 65, and the like).

Of the two types of memory cells, the memory cell MC is formed in the FMONOS formation region FA of the SOI region SA. The transistors (MISFETs) Tn1 and Tn2 forming the memory cell in the SRAM are formed in the SRAM formation region SRA of the SOI region SA. The transistors (MISFETs) Tn1 and Tn2 correspond to, e.g., any of the six transistors (see FIG. 62) forming the SRAM memory cell.

In the bulk region BA, the insulating layer BOX and the silicon layer SR are not formed over the supporting substrate S. Accordingly, the four MISFETs (HTn, HTp, LTn, and LTp) are formed in the main surface of the supporting substrate S.

Of the four MISFETs, the high-breakdown-voltage MISFETs (HTn and HTp) are formed in the high-breakdown-voltage MISFET formation region HA and the low-breakdown-voltage MISFETs (LTn and LTp) are formed in the low-breakdown-voltage MISFET formation region LA. Of the high-breakdown-voltage MISFETs (HTn and HTp), the high-breakdown-voltage n-channel MISFET (HTn) is formed in the region nHA and the high-breakdown-voltage p-channel MISFET (HTp) is formed in the region pHA. Of the low-breakdown-voltage MISFETs (LTn and LTp), the low-breakdown-voltage n-channel MISFET (LTn) is formed in the region nLA and the low-breakdown-voltage p-channel MISFET (LTp) is formed in the region pLA.

The low-breakdown-voltage MISFETs (LTn and LTp) have gate lengths smaller (shorter) than those of the high-breakdown-voltage MISFETs (HTn and HTp). For example, the gate lengths of the low-breakdown-voltage MISFETs (LTn and LTp) are about 55 nm. Such MISFETs having relatively small gate lengths are used for, e.g., a circuit (referred to also as core circuit or peripheral circuit) for driving the memory cells MC or the like.

On the other hand, the high-breakdown-voltage MISFETs (HTn and HTp) have gate lengths larger than those of the low-breakdown-voltage MISFETs (LTn and LTp). For example, the gate lengths of the high-breakdown-voltage MISFETs (HTn and HTp) are about 600 to 1000 nm. Such MISFETs having relatively large gate lengths are used for, e.g., the input/output circuits (referred to also as I/O circuits) or the like.

The transistors (MISFETs) Tn1 and Tn2 forming the memory cell in the SRAM are MISFETs having gate lengths smaller than those of the high-breakdown-voltage MISFETs (HTn and HTp). For example, the gate lengths of the transistors (MISFETs) Tn1 and Tn2 forming the memory cell in the SRAM are about 60 nm.

The low-breakdown-voltage n-channel MISFET (LTn) has the gate electrode GE located over the supporting substrate S (p-type well PW3) via the gate insulating film 3L and source/drain regions located in the supporting substrate S (p-type well PW3) on both sides of the gate electrode GE. Over the side wall portions of the gate electrode GE, the side-wall insulating films SW each made of an insulating film are formed. Each of the source/drain regions has an LDD structure and includes the n⁺-type semiconductor region 8n and the n⁻-type semiconductor region 7n.

The low-breakdown-voltage p-channel MISFET (LTp) has the gate electrode GE located over the supporting substrate S (n-type well NW3) via the gate insulating film 3L and source/drain regions located in the supporting substrate S (n-type well NW3) on both sides of the gate electrode GE. Over the side wall portions of the gate electrode GE, the side-wall insulating films SW each made of an insulating film are formed. Each of the source/drain regions has an LDD structure and includes the p⁺-type semiconductor region 8p and the p⁻-type semiconductor region 7p.

The foregoing higher-concentration semiconductor regions (8n and 8p) have impurity concentrations higher than those of the foregoing lower-concentration semiconductor regions (7n and 7p) and are formed in the epitaxial layers EP grown over the supporting substrate S on both sides of the gate electrode GE. Note that, here, the halo regions HL each having a conductivity type opposite to that of each of the lower-concentration semiconductor regions (7n and 7p) are placed so as to surround the lower-concentration semiconductor regions (7n and 7p). That is, under the n⁻-type semiconductor regions 7n, the p-type halo regions HL are formed and, under the p⁻-type semiconductor regions 7p, the n-type halo regions HL are placed.

The high-breakdown-voltage n-channel MISFET (HTn) has the gate electrode GE located over the supporting substrate S (p-type well PW2) via the gate insulating film 3H and source/drain regions located in the supporting substrate (p-type well PW2) on both sides of the gate electrode GE. Over the side wall portions of the gate electrode GE, the side-wall insulating films SW each made of an insulating film are formed. Each of the source/drain regions has an LDD structure and includes the n⁺-type semiconductor region 8n and the n⁻-type semiconductor region 7n.

The high-breakdown-voltage p-channel MISFET (HTp) has the gate electrode GE located over the supporting substrate S (n-type well PW2) via the gate insulating film 3H and source/drain regions located in the supporting substrate (n-type well NW2) on both sides of the gate electrode GE. Over the side wall portions of the gate electrode GE, the side-wall insulating films SW each made of an insulating film are formed. Each of the source/drain regions has an LDD structure and includes the p⁺-type semiconductor region 8p and the p⁻-type semiconductor region 7p.

The foregoing higher-concentration semiconductor regions (8n and 8p) have impurity concentrations higher than those of the foregoing lower-concentration semiconductor regions (7n and 7p) and are formed in the epitaxial layers EP grown over the supporting substrate S on both sides of the gate electrodes GE.

Each of the memory cells MC has the control gate electrode (gate electrode) CG located above the silicon layer SR and the memory gate electrode (gate electrode) MG located above the silicon layer SR to be adjacent to the control gate electrode CG. Over the control gate electrode CG, the silicon oxide film CP1 and the silicon nitride film (cap insulating film) CP2 are placed. The memory cell MC further has the gate insulating film 3F located between the control gate electrode CG and the silicon layer SR and the insulating film 5 located between the memory gate electrode MG and the silicon layer SR and between the memory gate electrode MG and the control gate electrode CG.

The memory cell MC further has the source region MS and the drain region MD in the silicon layer SR. Over each of the side wall portions of a composite pattern of the memory gate electrode MG and the control gate electrode CG, the side-wall insulating films SW each made of an insulating film are formed. The source region MS includes the n⁺-type semiconductor region 8a and the n⁻-type semiconductor region 7a. The drain region MD includes the n⁺-type semiconductor region 8b and the n⁻-type semiconductor region 7b.

The foregoing higher-concentration semiconductor regions (8a and 8b) have impurity concentrations higher than those of the foregoing lower-concentration semiconductor regions (7a and 7b) and are formed in the epitaxial layers EP grown over the supporting substrate S on both sides of the foregoing composite pattern.

Each of the transistors (MISFETs) Tn1 and T2 forming the memory cell in the SRAM has the gate electrode GE located over the silicon layer SR via the gate insulating film 3S and the source/drain regions located in the silicon layer SR on both sides of the gate electrode GE. Over the side wall portions of the gate electrode GE, the side-wall insulating films SW each made of an insulating film are formed. Each of the source/drain regions has an LDD structure and includes the n⁺-type semiconductor region 8n and the n⁻-type semiconductor region, 7n.

The foregoing higher-concentration semiconductor regions (8n) have impurity concentrations higher than those of the foregoing lower-concentration semiconductor regions (7n) and are formed in the epitaxial layers EP grown over the silicon layer SR on both sides of the gate electrode GE.

In the memory cell MC of the present embodiment, in the supporting substrate S located under the control gate electrode CG and under the insulating layer BOX, the impurity region VTC(CT) for adjusting the threshold of the control transistor is formed. In addition, in the supporting substrate S located under the memory gate electrode MG and under the insulating layer BOX, the impurity region VTC(MT) for adjusting the threshold of the memory transistor is formed.

As described in Embodiment 1 with reference to FIG. 4, the impurity region VTC(MT) for adjusting the threshold of the memory transistor is shallower than the impurity region VTC(CT) for adjusting the threshold of the control transistor. In other words, the bottom surface of the impurity region VTC(MT) for adjusting the threshold of the memory transistor is located at a position shallower than that of the bottom surface of the impurity region VTC(CT) for adjusting the threshold of the control transistor.

The impurity regions VTC(MT) for adjusting the threshold of the memory transistor has an impurity concentration lower than that of the impurity region VTC(CT) for adjusting the threshold of the control transistor. In other words, the impurity region VTC(MT) for adjusting the threshold of the memory transistor has an effective carrier concentration lower than that of the impurity region VTC(CT) for adjusting the threshold of the control transistor.

Here, each of the memory gate electrode MG and the control gate electrode CG contains an n-type impurity (such as, e.g., arsenic (As) or phosphorus (P)) and, as the impurity region VTC(MC) for adjusting the threshold of the memory transistor and the impurity region VTC(CT) for adjusting the threshold of the control transistor, p-type impurity regions are used. As a p-type impurity, e.g., boron (B) or the like can be used.

For example, the impurity region VTC(MT) for adjusting the threshold of the memory transistor is a p⁻⁻-type impurity region and the impurity region VTC(CT) for adjusting the threshold of the control transistor is a p⁻-type impurity region. The p⁻-type means having an effective concentration of a p-type impurity which is lower than that of the p⁻-type.

Specifically, the impurity region VTC(CT) for adjusting the threshold of the control transistor is a region in which a p-type impurity (such as, e.g., boron (B)) has been ion-implanted and the impurity region VTC(MT) for adjusting the threshold of the memory transistor is a region in which, in addition to a p-type impurity (such as, e.g., boron (B)), an n-type impurity (such as, e.g., arsenic (As) or phosphorus (P)) of the conductivity type opposite to the p-type has been implanted.

Thus, in the present embodiment, the memory cells MC are placed in the SOI regions and the impurity region VTC(CT) for adjusting the threshold of the control transistor and the impurity region VTC(MT) for adjusting the threshold of the memory transistor are provided therein. This can improve the performance of the memory cell MC. Specifically, variations in the thresholds of the control transistor and the memory transistor can be reduced. In addition, the GiDL can be reduced. Also, the disturb in each of the memory cells MC can be improved.

That is, by providing the impurity region for threshold adjustment, an increase in the concentration of the impurity in the silicon layer SR can be avoided. This can reduce threshold variations. Since an increase in the concentration of the impurity in the silicon layer SR can be avoided by providing the impurity regions for threshold adjustment, the GiDL can also be reduced. In addition, the disturb in each of the memory cells MC can be improved.

In the present embodiment, in the SOI region SA, the transistors Tn1 and Tn2 forming the memory cell in the SRAM are formed. This can reduce a parasitic capacitance resulting from a diffusion region formed in the silicon layer and leakage current to the substrate. As a result, it is possible to achieve an improvement in the operating speed of a circuit formed using the memory cell in the SRAM and a reduction in the power consumed thereby. It is also possible to reduce the concentration of the impurity in the silicon layer SR. This allows reductions in random variations in the transistors Tn1 and Tn2 forming the SRAM memory cell forming the SRAM. In particular, as has been described with reference to FIG. 62, when one memory cell is formed using six transistors, the random variations may significantly affect the characteristics of the SRAM. By thus reducing the “random variations” in the transistors Tn1 and Tn2 forming the memory cell in the SRAM and further uniformizing the characteristics of the individual transistors, the characteristics of the SRAM can be improved.

On the other hand, in the present embodiment, the low-breakdown-voltage MISFETs (LTn and LTp) provided in the core regions (Core) around the memory regions and the high-breakdown-voltage MISFETs (HTn and HTp) provided in the IO regions (IO) are formed in the bulk region (BA). This eliminates the need for design for newly forming such MISFETs in the SOI region SA. As a result, it is possible to provide a semiconductor device having a lower margin-related failure rate in a shorter period by re-designing only the memory cell portions.

<Description of Manufacturing Method>

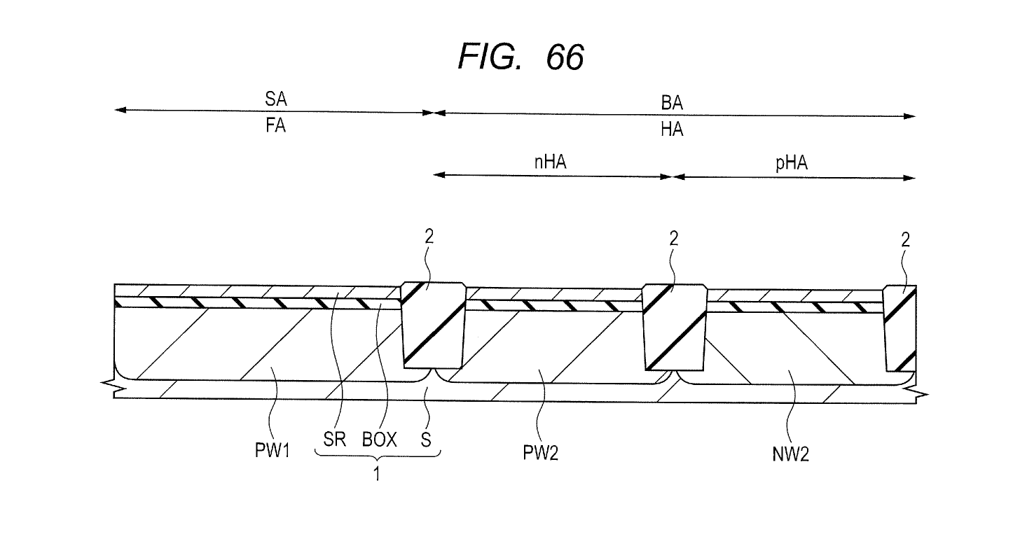

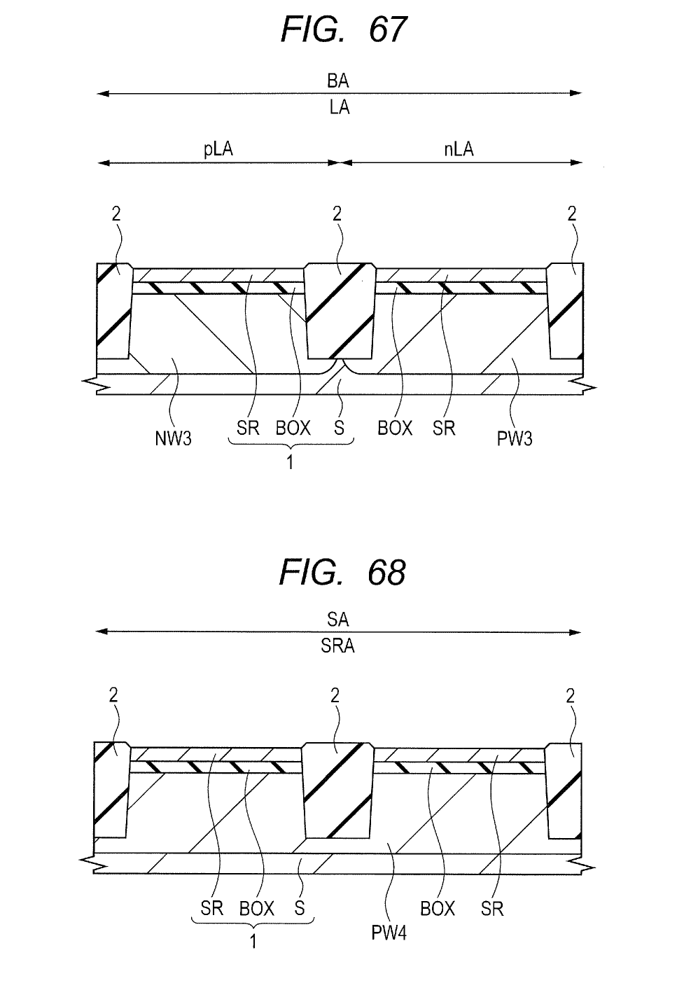

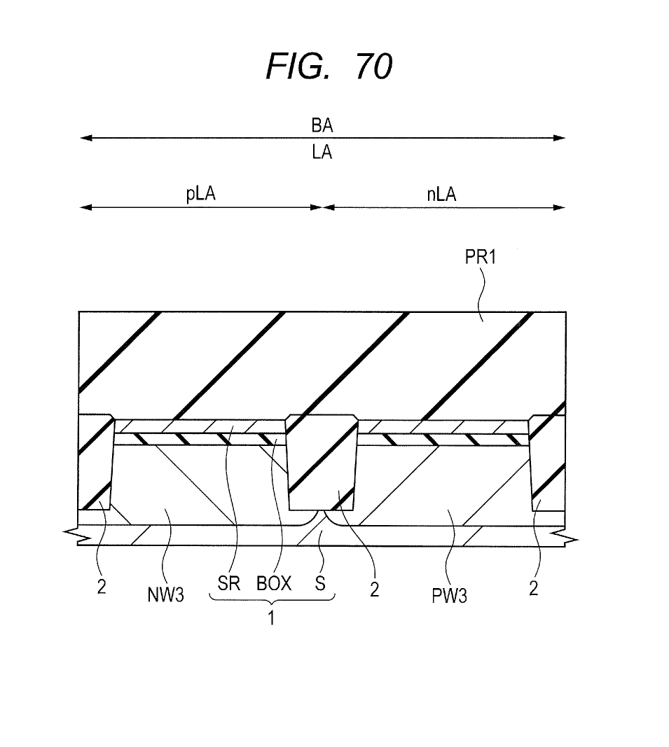

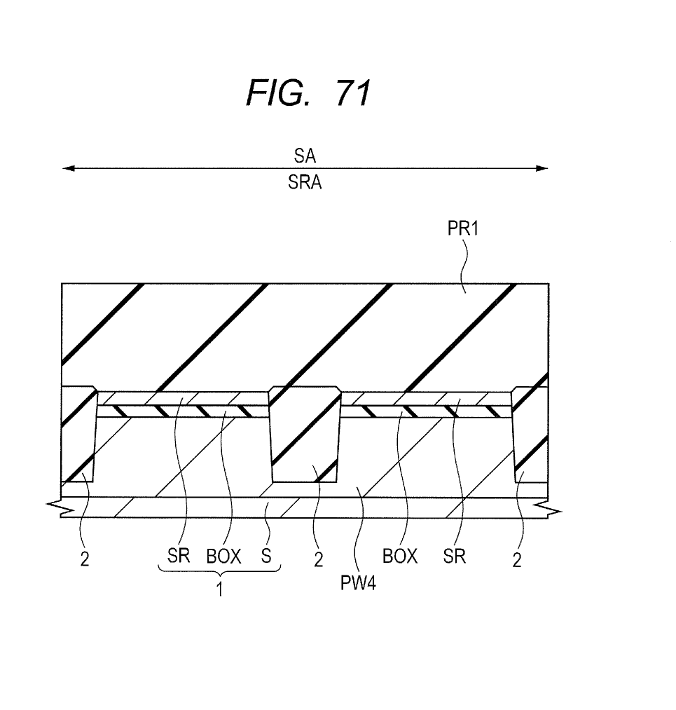

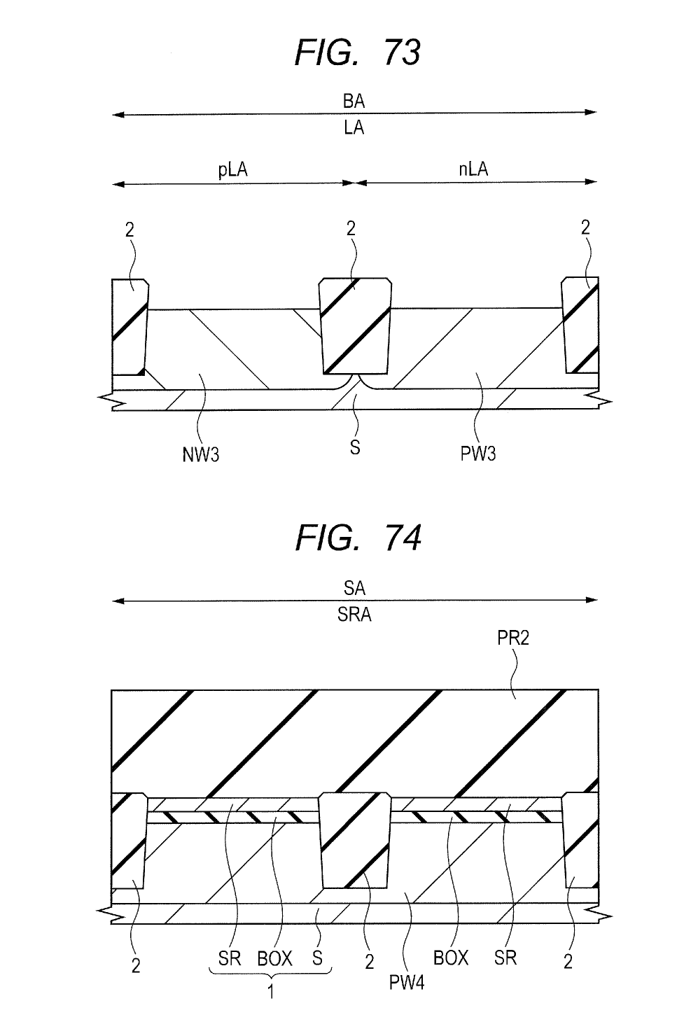

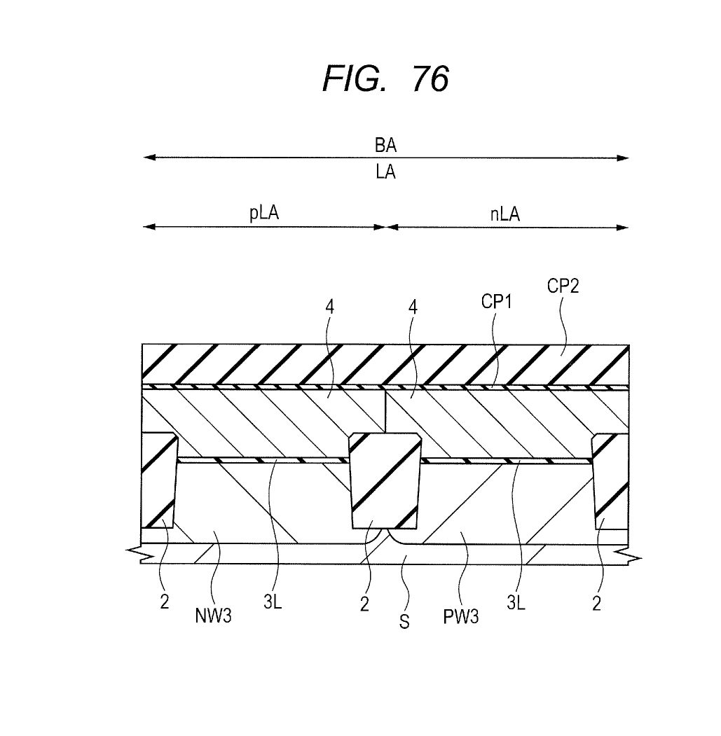

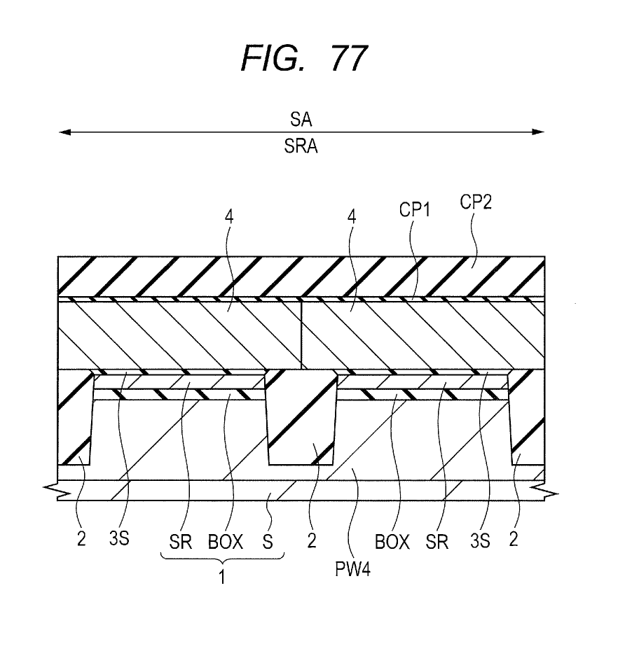

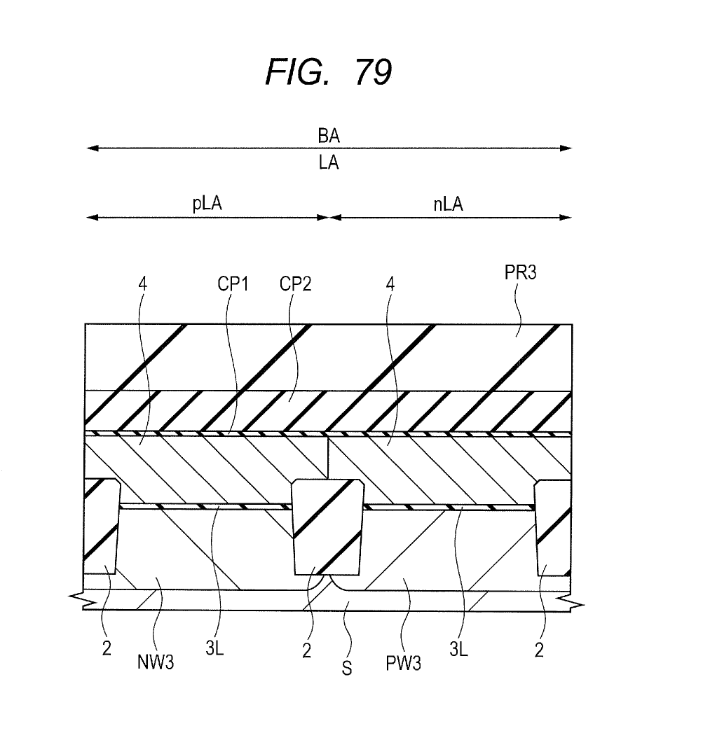

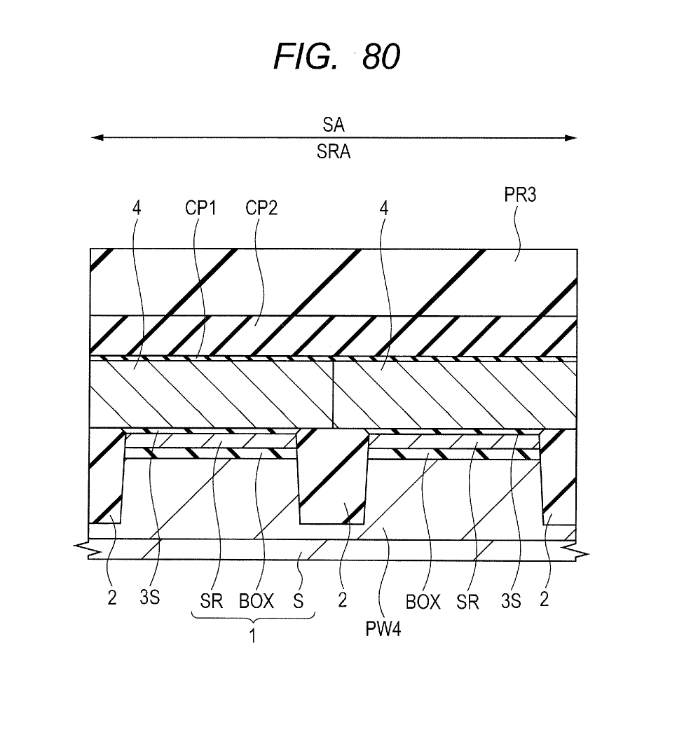

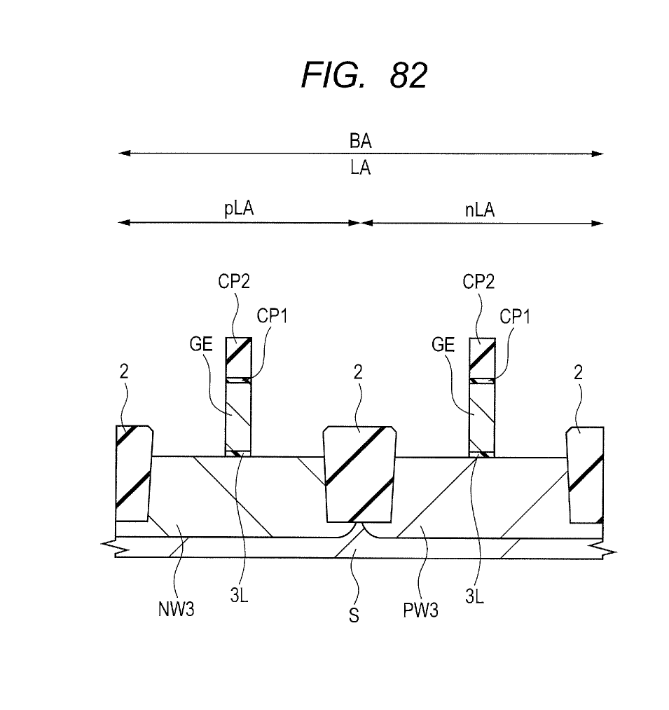

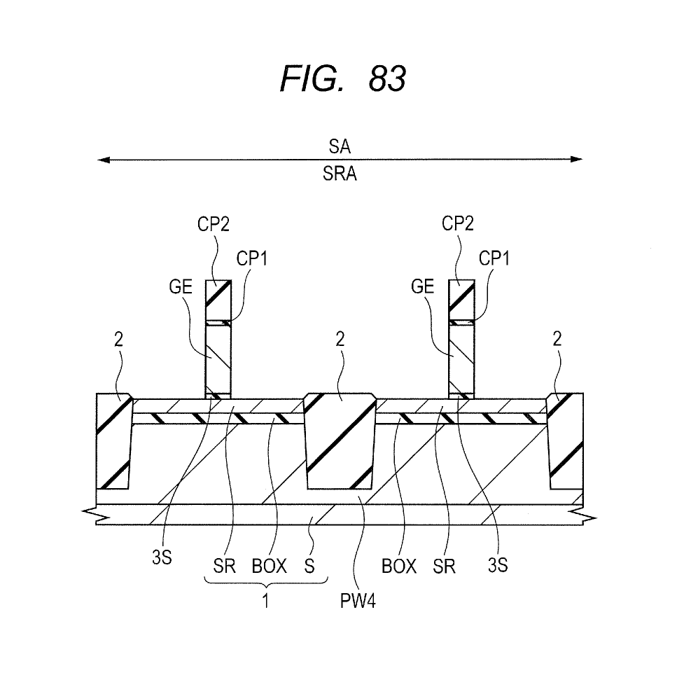

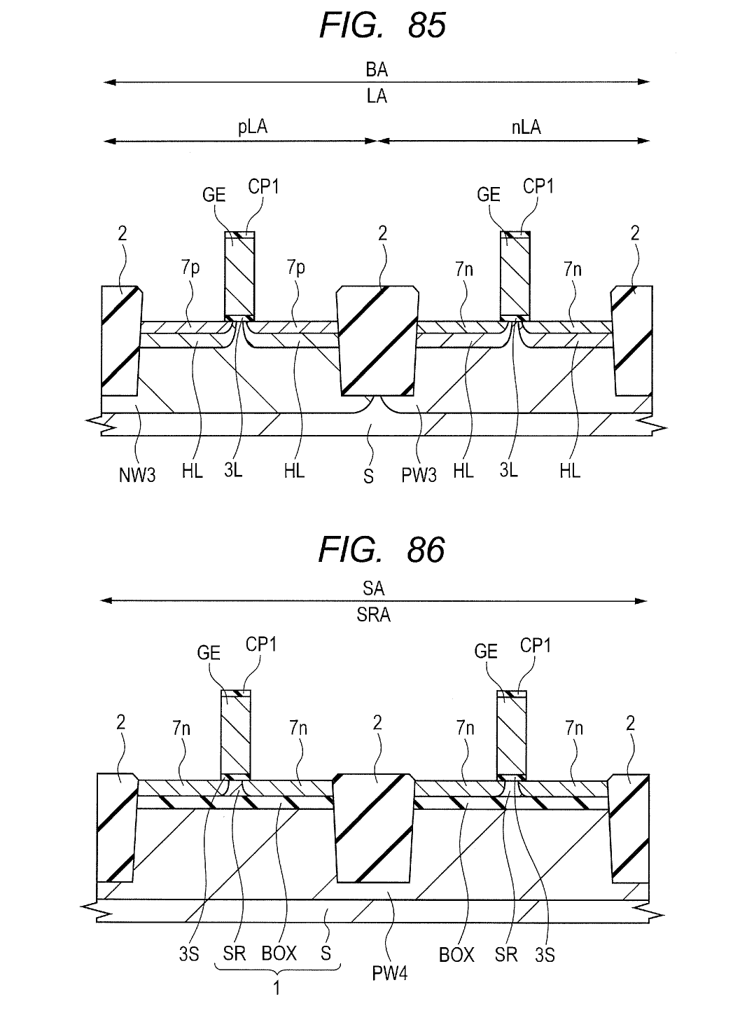

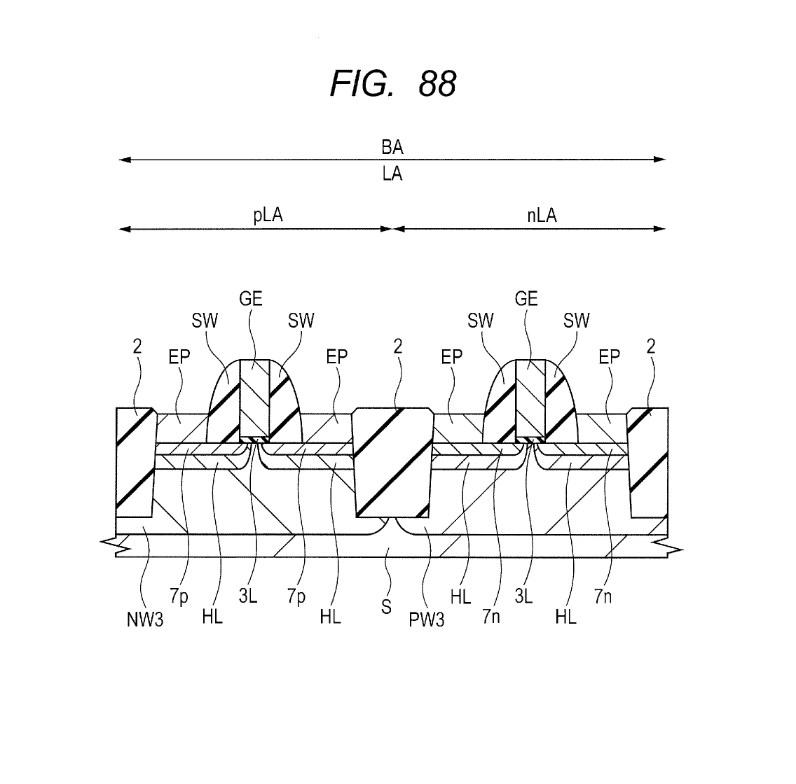

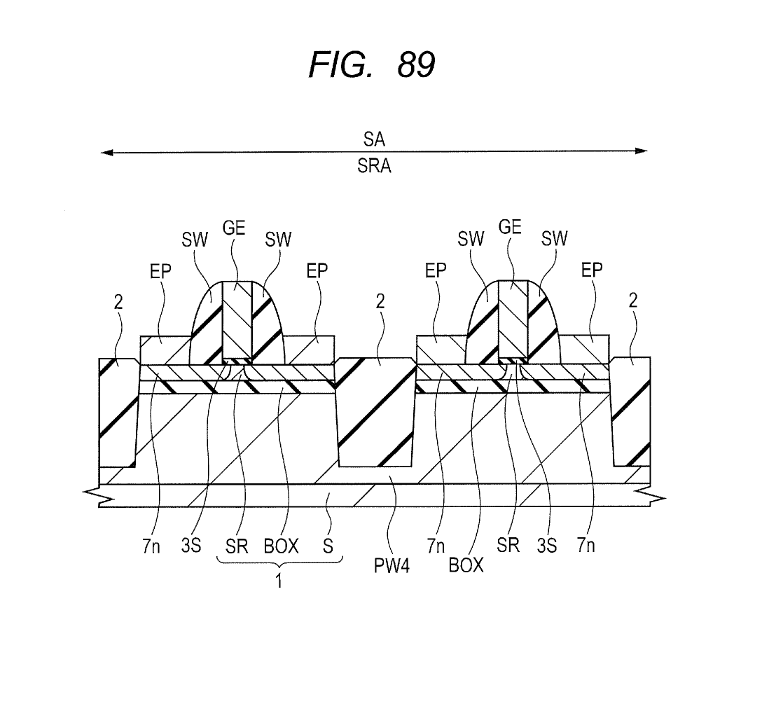

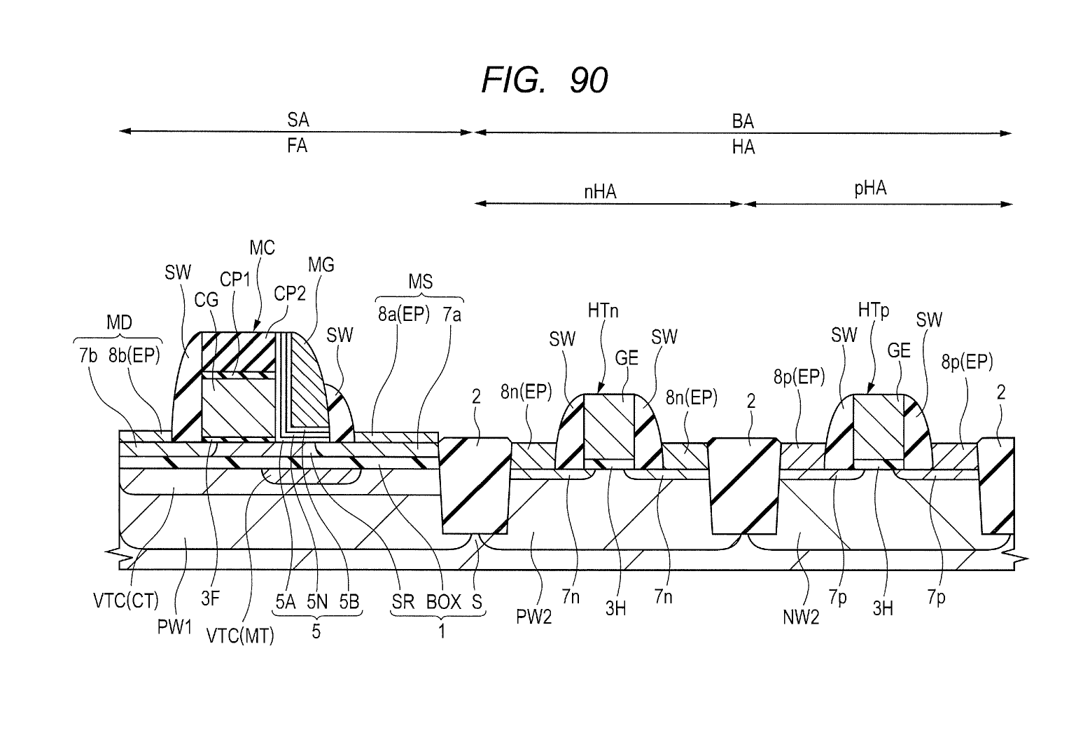

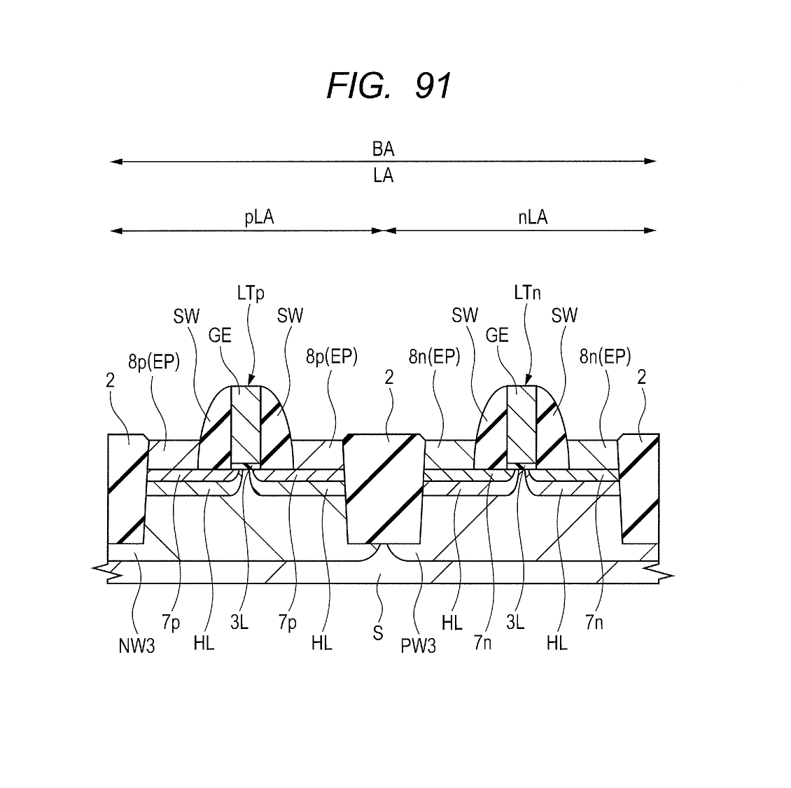

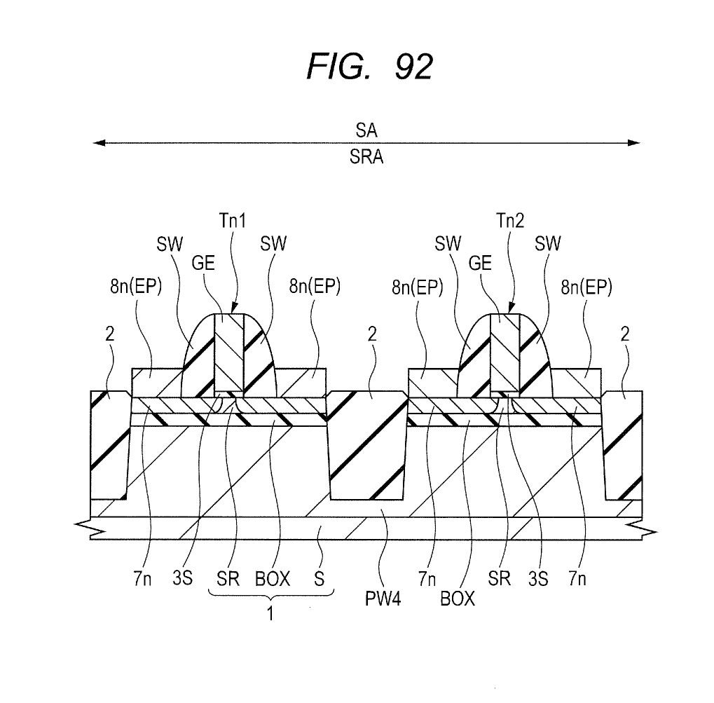

Next, referring to the drawings, a description will be given of a manufacturing method of the semiconductor device of the present embodiment, while defining the configuration of the semiconductor device. FIGS. 66 to 92 are cross-sectional views each showing a manufacturing process of the semiconductor device of the present embodiment.

As shown in FIGS. 66 to 68, as a substrate, e.g., the SOI substrate 1 is provided. The SOI substrate 1 includes the supporting substrate (referred to also as semiconductor substrate) S, the insulating film (referred to also as embedded insulating layer) BOX formed over the supporting substrate S, and the silicon layer SR formed over the insulating layer BOX.

The SOI substrate 1 has the SOI region SA and the bulk region BA. The SOI region SA has the FMONOS formation region FA and the SRAM formation region SRA. On the other hand, the bulk region BA has a low-breakdown-voltage MISFET formation region LA and a high-breakdown-voltage MISFET formation region HA. The low-breakdown-voltage MISFET formation region LA has the region nLA where the low-breakdown-voltage n-channel MISFET (LTn) is formed and the region pLA where the low-breakdown-voltage p-channel MISFET (LTp) is formed. The high-breakdown-voltage MISFET formation region HA has the region nHA where the high-breakdown-voltage n-channel, MISFET (HTn) is formed and the region pHA where the high-breakdown-voltage p-channel MISFET (HTp) is formed. Note that the bulk region BA means a region from which the silicon layer SR and the insulating layer BOX are removed by a step described later.

Next, in the same manner as in Embodiment 1, the isolation region 2 is formed in the SOI substrate 1. In the same manner as in Embodiment 1, the isolation region 2 can be formed using, e.g., a STI method.

Next, in the same manner as in Embodiment 1, the p-type wells (PW1, PW2, PW3, and PW4) or the n-type wells (NW2 and NW3) are formed in the supporting substrate S in the individual regions.

For example, over the SOI substrate 1, a photoresist film (not shown) having openings corresponding to the SOI region SA and the regions nHA and nLA is formed and a p-type impurity (such as, e.g., boron (B)) is ion-implanted to form the p-type wells (PW1, PW2, PW3, and PW4). Thereafter, the foregoing photoresist film (not shown) is removed by ashing treatment or the like. Then, over the SOI substrate 1, a photoresist film (not shown) having openings corresponding to the regions pLA and pHA is formed and an n-type impurity (such as, e.g., arsenic (As) or phosphorus (P)) is ion-implanted to form the n-type wells (NW2 and NW3). Thereafter, the foregoing photoresist film (not shown) is removed by ashing treatment or the like. Then, as well annealing treatment, heat treatment is performed in a nitrogen atmosphere at 1000° C. for about 30 seconds. By the heat treatment, the impurities implanted in the individual regions are activated to allow recovery from a crystal defect caused by the ion implantation. The well annealing treatment may be performed not only in the nitrogen atmosphere, but also in an inert gas atmosphere of argon or the like. The temperature range can also be adjusted appropriately from 750° C. to 1000° C. Instead, rapid thermal annealing (referred to also as spike annealing) may also be used.

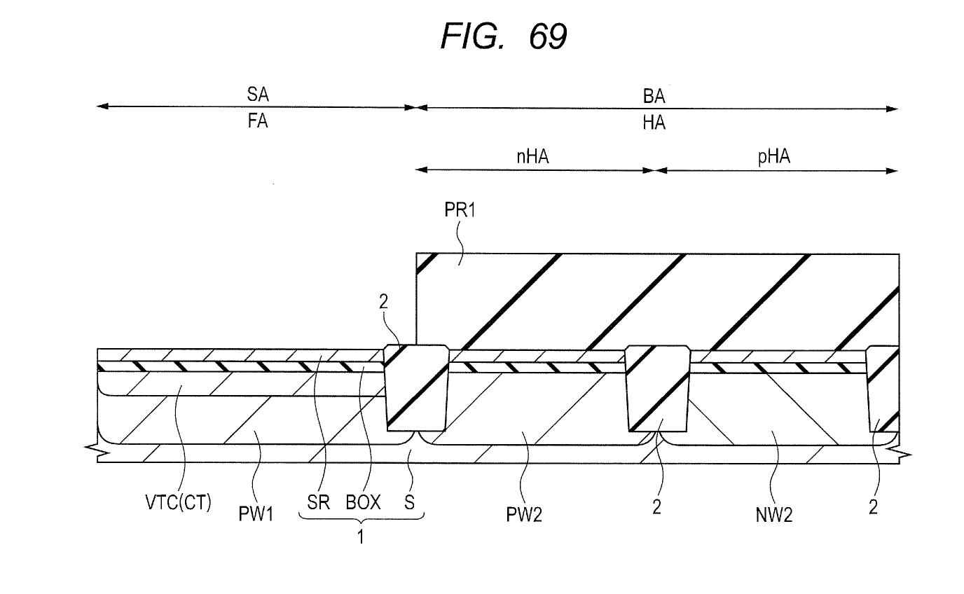

Next, as shown in FIGS. 69 to 71, the impurity region VTC(CT) for adjusting the threshold of the control transistor is formed.

First, over the SOI substrate 1, the photoresist film PR1 having an opening corresponding to the FMONOS formation region FA of the SOI region SA is formed and, into the supporting substrate S under the insulating layer BOX in the SOI region SA, an impurity for threshold adjustment is ion-implanted. At this time, into the silicon layer SR in the SOI region SA, ion implantation is preferably performed with such an implantation energy that minimizes the implantation of the impurity. For example, when the film thickness of each of the silicon layer SR and the insulating layer BOX is about 50 nm and boron (B) is ion-implanted as the impurity for threshold adjustment, ion implantation is performed with an implantation energy of 40 keV and a dosage of 2e13 (2×10¹³) cm⁻². As a result, in the supporting substrate S under the insulating layer BOX in the SOI region SA, a p-type impurity region is formed as the impurity region VTC (CT) for adjusting the threshold of the control transistor. Note that the implantation conditions need to be adjusted appropriately in accordance with the film thickness of the silicon layer SR, the film thickness of the insulating layer BOX, and a target threshold value. Then, the photoresist film PR1 is removed by ashing treatment or the like.

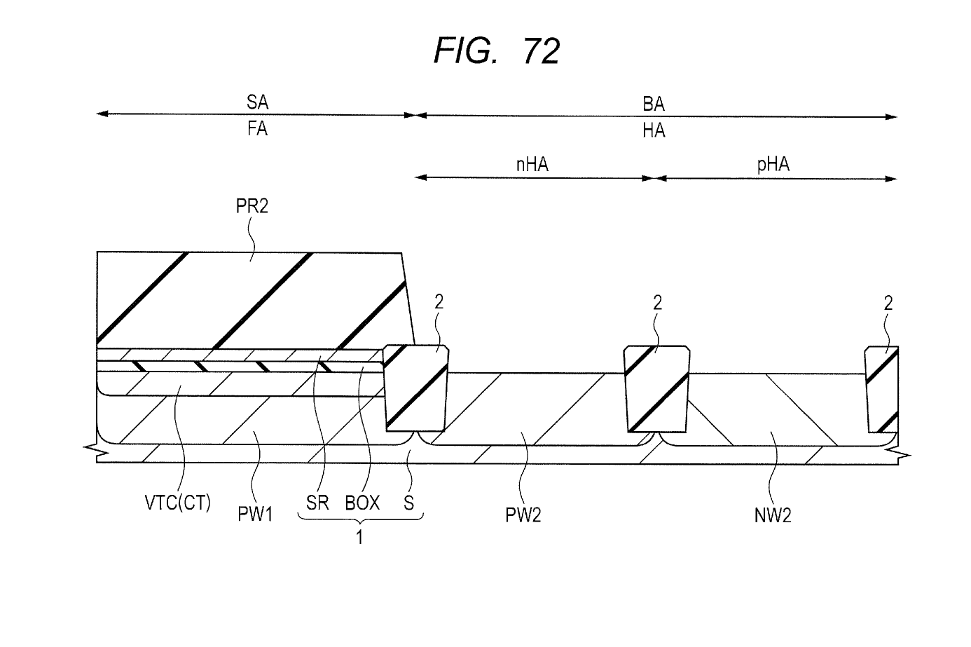

Then, as shown in FIGS. 72 to 74, the silicon layer SR and the insulating layer BOX in the bulk region BA (regions nLA, pLA, nHA, and pHA) are removed to expose the surface of the supporting substrate S.

For example, over the SOI substrate 1, the photoresist film PR2 having an opening corresponding to the bulk region BA (regions nLA, pLA, nHA, and pHA) is formed, and the silicon layer SR and the insulating layer BOX in the bulk region BA are successively removed by dry etching. Then, the photoresist film PR2 is removed by ashing treatment or the like. As a result, the surface of the supporting substrate S in the bulk region BA is exposed. Here, using the photoresist film PR2 as a mask, the silicon layer SR, and the insulating layer BOX in the bulk region BA are etched. However, the silicon layer SR and the insulating layer BOX may also be etched using a hard mask formed of a silicon oxide film or a silicon nitride film.

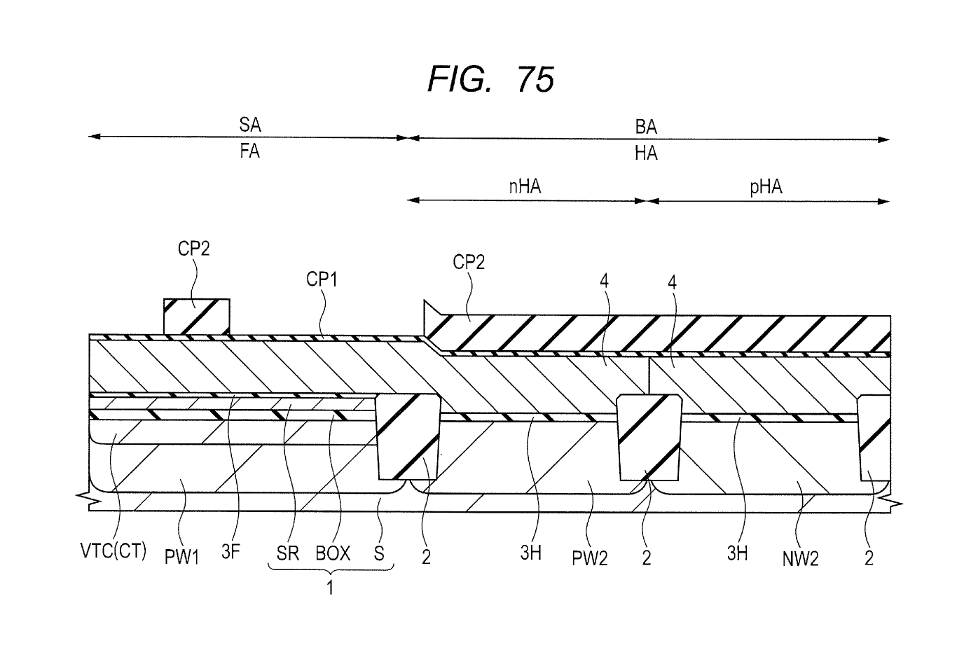

Next, by diluted hydrofluoric acid cleaning or the like, the surface of each of the SOI region SA and the bulk region BA is cleaned. Then, as shown in FIGS. 75 to 77, over the main surface of the silicon layer SR in the SOI region SA and the main surface of the supporting substrate S (p-type wells PW2 and PW3 and n-type wells NW2 and NW3) in the bulk region BA, the gate insulating films 3F, 3L, 3H, and 3S are formed. Here, over the main surface of the silicon layer SR in the FMONOS formation region FA of the SOI region SA, the relatively thin gate insulating film 3F is formed. On the other hand, over the high-breakdown-voltage MISFET formation region HA (regions nHA and pHA) of the bulk region BA, the relatively thick gate insulating film 3H is formed while, over the low-breakdown-voltage MISFET formation region LA (regions nLA and pLA) the bulk region BA, the relatively thin gate insulating film 3L is formed. Also, over the main surface of the silicon layer SR in the SRAM formation region SRA of the SOI region SA, the relatively thin gate insulating film 3S is formed.

For example, over the main surface of the silicon layer SR in the SOI region SA and the main surface of the supporting substrate S in the low-breakdown-voltage MISFET formation region (regions nLA and pLA) of the bulk region BA, a silicon oxide film having a first thickness (e.g., about 3 nm) is formed by a thermal oxidation method. Then, for example, over the main surface of the supporting substrate in the high-breakdown-voltage MISFET formation region HA (regions nHA and pHA) of the bulk region BA, a silicon oxide film having a second thickness (e.g., about 16 nm) larger than the first thickness is formed by a thermal oxidation method.

As the gate insulating films 3F, 3L, 3H, and 3S, not only the silicon oxide films, but also other insulating films such as a silicon oxynitride film may also be used. Alternatively, a metal oxide film having a high dielectric constant higher than that of a silicon nitride film, such as a hafnium oxide film, an aluminum oxide film (alumina), or a tantalum oxide film or a laminate film of an oxide film or the like and a metal oxide film may also be formed. The gate insulating films 3F, 3L, 3H, and 3S may also be formed using not only the thermal oxidation method, but also a CVD method. The gate insulating films 3F, 3L, 3H, and 3S may also be formed of different types of films to have different thicknesses.

Next, over the gate insulating films 3F, 3L, 3H, and 3S, the silicon film 4 is formed as a conductive (conductor) film. As the silicon film 4, e.g., a polysilicon film is formed using a CVD method or the like to a thickness of about 80 nm. As the silicon film 4, an amorphous silicon film may also be deposited and crystallized by being subjected to heat treatment. The silicon film 4 serves as the control gate electrode CG of the memory cell MC in the FMONOS formation region FA of the SOI region SA and serves as the gate electrode GE of each of the transistors Tn1 and Tn2 in the SRAM formation region SRA of the SOI region SA. The silicon film 4 also serves as the gate electrode GE of each of the high-breakdown-voltage n-channel MISFET (HTn) and the high-breakdown-voltage p-channel MISFET (HTp) in the high-breakdown-voltage MISFET formation region HA (regions nHA and pHA) of the bulk region BA. On the other hand, in the low-breakdown-voltage MISFET formation region LA (regions nLA and pLA) of the bulk region BA, the silicon film 4 serves as the gate electrode GE of each of the low-breakdown-voltage re-channel MISFET (LTn) and the low-breakdown-voltage p-channel MISFET (LTp).

Next, into the silicon film 4 in each of the SOI region SA, the region nLA of the bulk region BA where the low-breakdown-voltage n-channel MISFET (LTn) is formed, and the region nHA of the bulk region BA where the high-breakdown-voltage n-channel MISFET (HTn) is formed, an n-type impurity (such as, e.g., arsenic (As) or phosphorus (P)) is implanted using a photoresist film (not shown) as a mask. For example, the impurity is implanted under the same conditions as in Embodiment 1.

Next, into the silicon film 4 in each of the region pLA of the bulk region BA where the low-breakdown-voltage p-channel MISFET (LTp) is formed and the region pHA of the bulk region BA where the high-breakdown-voltage p-channel MISFET (HTp) is formed, a p-type impurity (such as, e.g., boron (B)) is implanted using a photoresist film (not shown) as a mask. For example, the impurity is implanted under the same conditions as in Embodiment 1.

Next, the surface of the silicon film 4 corresponding to a thickness of about 3 to 10 nm is thermally oxidized to form the thin silicon oxide film CP1. Note that the silicon oxide film CP1 may also be formed using a CVD method. Then, over the silicon oxide film CP1, using a CVD method or the like, the silicon nitride film (cap insulating film) CP2 having a thickness of about 50 to 150 nm is formed.

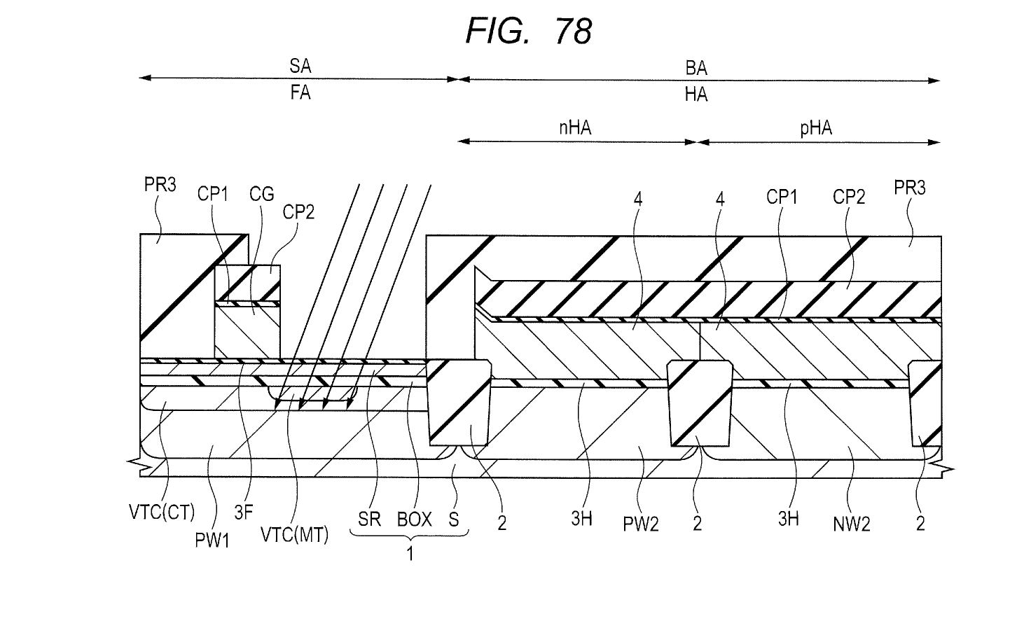

Next, over the region where the control gate electrode CG is to be formed, the SRAM formation region SRA, and the bulk region BA, a photoresist film (not shown) is formed using photolithographic method and, using the photoresist film as a mask, the silicon nitride film CP2 is etched. Then, by removing the photoresist film (not shown) by ashing or the like, the silicon nitride film CP2 and the silicon oxide film CP1 are left in the region where the control gate electrode CG is to be formed, the SRAM formation region SRA, and the bulk region BA. Thereafter, using the silicon nitride film CP2 as a mask, the silicon film 4 and the like are etched. In this manner, the control gate electrode CG (having a gate length of, e.g., about 80 nm) is formed (see FIGS. 78 to 80). Here, over the control gate electrode CG, the silicon nitride film CP2 and the silicon oxide film CP1 are formed. However, these films may also be omitted.

Here, in the SOI region SA, the gate insulating film 3F remaining under the control gate electrode CG serves as the gate insulating film 3F of the control transistor. Note that the gate insulating film 3F except for the portion thereof covered with the control gate electrode CG can be removed by the subsequent patterning step or the like. In the bulk region BA and the SRAM formation region SRA, the silicon nitride film CP2, the silicon oxide film CP1, and the silicon film 4 are left (see FIGS. 75 to 77).

Next, as shown in FIGS. 78 to 80, using a photoresist film PR3 having an opening on one side of the control gate electrode CG (in the region where the memory gate electrode MG is formed) as a mask, an n-type impurity (such as, e.g., arsenic (As) or phosphorus (P) of the conductivity type opposite to the p-type or the like is implanted in the same manner as in Embodiment 1. As a result, in the supporting substrate S under the memory gate electrode MG, a p-type impurity region is formed as the impurity region VTC(MT) for adjusting the threshold of the memory transistor. At this time, the p-type impurity is obliquely implanted to allow the impurity region VTC(MT) for threshold adjustment to be formed so as to extend to the end portion (boundary portion between the memory gate electrode MG and the control gate electrode CG) of the memory gate electrode MG. For example, the impurity is implanted under the same conditions as in Embodiment 1. Then, the photoresist film PR3 is removed by ashing treatment or the like.

Thus, by implanting an n-type impurity (such as, e.g., arsenic (As) or phosphorus (P)) of the conductivity type opposite to the p-type, the impurity region VTC(MT) for adjusting the threshold of the memory transistor can be formed which has a concentration lower than that of the impurity region VTC(CT) for adjusting the threshold of the control transistor. The “concentration lower” used herein means that the effective concentration of the impurity (carrier concentration) is lower.

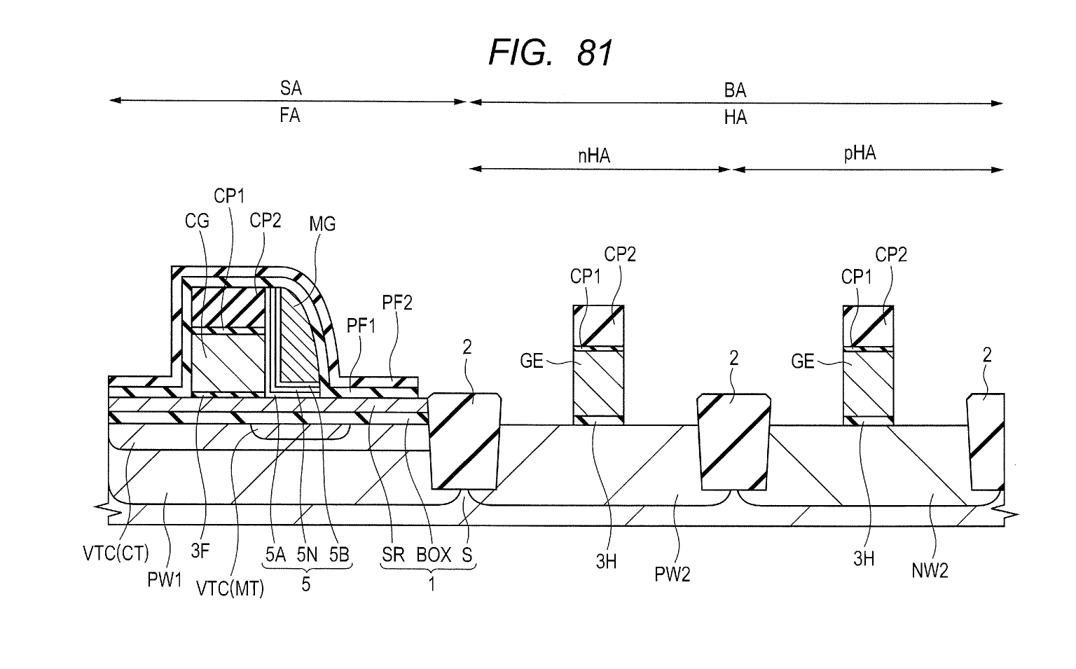

Next, as shown in FIGS. 81 to 83, in the same manner as in Embodiment 1, the insulating film 5 (5A, 5N, and 5B) is formed and the silicon film 6 is formed as a conductive film (conductor film) and then etched back. This allows the silicon film 6 to remain in sidewall shapes (side-wall film shapes) over the both side wall portions of the control gate electrode CG each via the insulating film 5. The silicon film 6 remaining over one of the both side wall portions of the foregoing control gate electrode CG forms the memory gate electrode MG. On the other hand, the silicon film 6 remaining on the other side wall portion forms the silicon spacer SP1. Then, after the unneeded silicon spacer SP1 and the like are etched, a laminate film of the silicon oxide film PF1 and the silicon nitride film PF2 is formed as the protective film covering the FMONOS formation region FA of the SOI region SA (see FIGS. 81 to 83).

Next, by etching the silicon nitride film CP2, the silicon oxide film CP1, and the silicon film 4 in the same manner as in Embodiment 1, the respective gate electrodes GE of the high-breakdown-voltage n-channel MISFET (HTn) and the high-breakdown-voltage p-channel MISFET (HTp) are formed in the high-breakdown-voltage MISFET formation region HA (regions nHA and pHA) of the bulk region BA. On the other hand, the respective gate electrodes GE of the low-breakdown-voltage re-channel MISFET (LTn) and the low-breakdown voltage p-channel MISFET (LTp) are formed in the low-breakdown-voltage MISFET formation region LA (regions nLA and pLA) of the bulk region BA. Also, in the SRAM formation region SRA of the SOI region SA, the respective gate electrodes GE of the transistors Tn1 and Tn2 forming the memory cell in the SRAM are formed. The gate length (e.g., about 0.6 μm) of the gate electrode GE of each of the high-breakdown-voltage n-channel MISFET (HTn) and the high-breakdown-voltage p-channel MISFET (HTp) is larger than the gate length (e.g., about 0.055 μm) of the gate electrode GE of each of the low-breakdown-voltage n-channel MISFET (LTn) and the low-breakdown-voltage p-channel MISFET (Lp). The gate length (e.g., about 0.6 μm) of the gate electrode GE of each of the high-breakdown-voltage n-channel MISFET (HTn) and the high-breakdown-voltage p-channel MISFET (HTp) is also larger than the gate length (e.g., about 0.060 μm) of the gate electrode GE of each of the transistors Tn1 and Tn2 forming the memory cell in the SRAM.

The gate insulating films 3H remaining under the gate electrodes GE serve as the gate insulating films 3H of the MISFETs (HTn and HTp). The gate insulating films 3L remaining under the gate electrodes GE serve as the gate insulating films 3L of the MISFETs (LTn and LTp). The gate insulating films 3S remaining under the gate electrodes GE serve as the gate insulating films 3S of the transistors Tn1 and Tn2. Note that the gate insulating films 3H, 3L, and 3S except for the portions thereof covered by the gate electrodes GE may be removed during the formation of the foregoing gate electrodes GE or may be removed by the subsequent patterning step or the like.

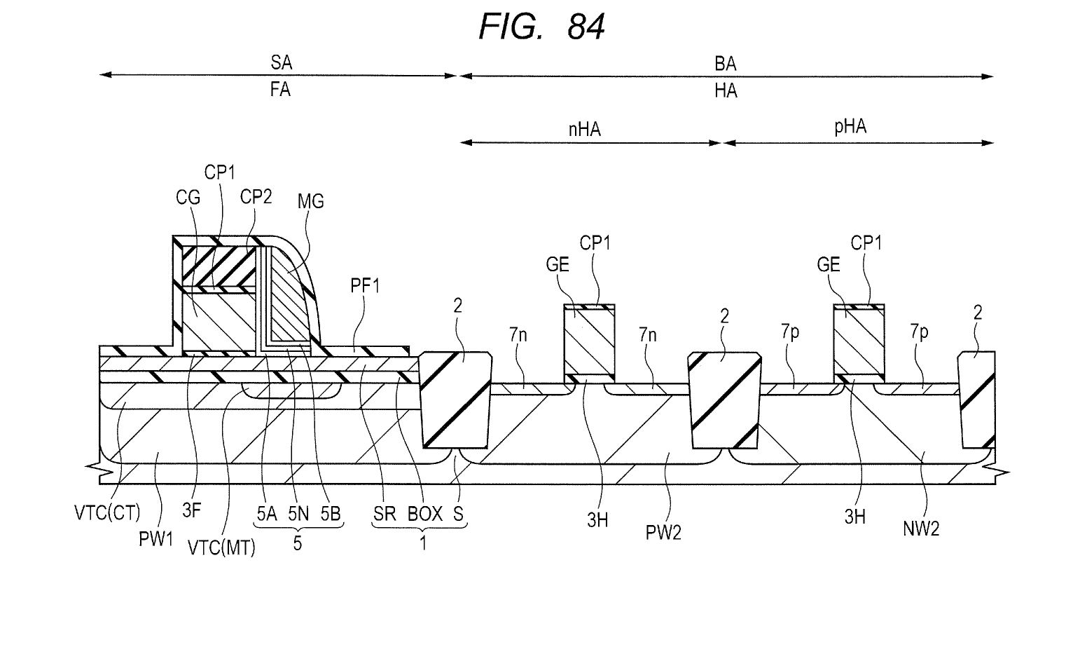

Next, as shown in FIGS. 84 to 86, the silicon nitride film PF2 forming the protective film and the silicon nitride film CP2 over each of the gate electrodes GE are removed by etching. Then, in the same manner as in Embodiment 1, in the supporting substrate S (p-type wells PW2 and PW3 and n-type wells NW2 and NW3) on both sides of the gate electrodes GE in the bulk region BA, the halo regions (impurity regions) HL, the n⁻-type semiconductor regions 7n, and the p⁻-type semiconductor regions 7p are formed. At this time, in the silicon layer SR on both sides of the gate electrode GE in the SRAM formation region SRA of the SOI region SA, the n⁻-type semiconductor regions 7n are formed.

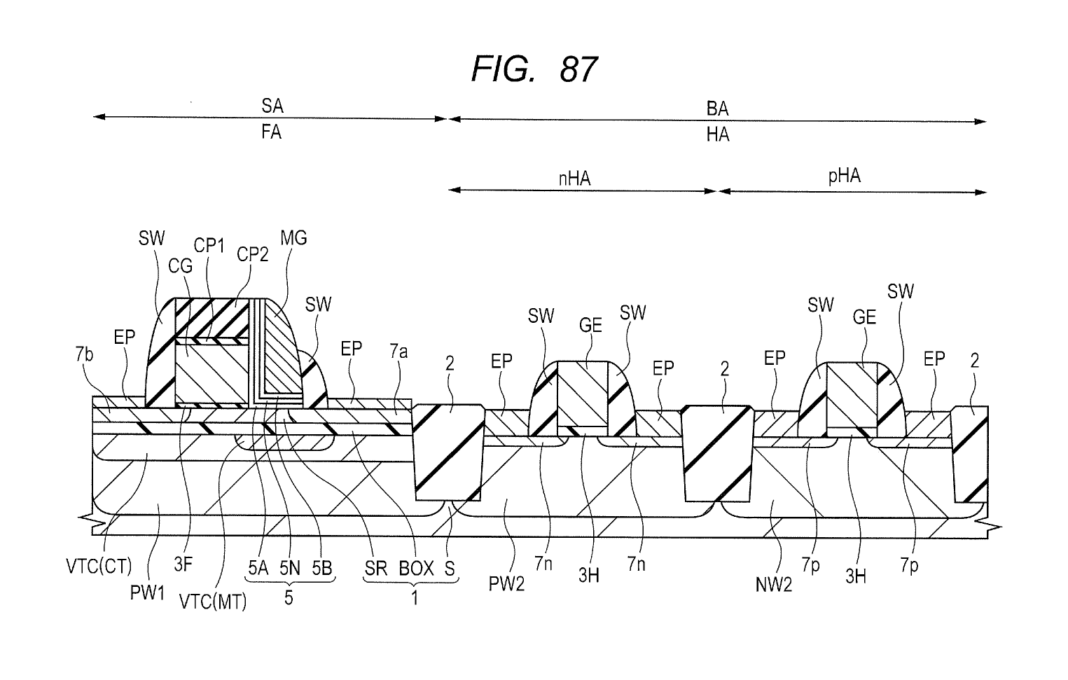

Then, as shown in FIGS. 87 to 89, the silicon oxide film PF1 forming the protective film and the silicon oxide films CP1 over the gate electrodes GE are removed by etching. Then, in the same manner as in Embodiment 1, in the silicon layer SR in the SOI region SA, an n-type impurity such as arsenic (As) or phosphorus (P) is implanted to form the n⁻-type semiconductor region 7a and the n⁻-type semiconductor region 7b. At this time, the n⁻-type semiconductor region 7a is formed by self-alignment with the side wall (side wall opposite to the side wall adjacent to the control gate electrode CG via the insulating film 5) of the memory gate electrode MG. On the other hand, the n⁻-type semiconductor region 7b is formed by self-alignment with the side wall (side wall opposite to the side wall adjacent to the memory gate electrode MG via the insulating film 5) of the control gate electrode CG.

Next, in the same manner as in Embodiment 1, in the FMONOS formation region FA of the SOI region SA, the side-wall insulating films SW are formed over the side wall portions of the composite pattern of the control gate electrode CG and the memory gate electrode MG. On the other hand, in the bulk region BA and in the SRAM formation region SRA of the SOI region, the side-wall insulating films SW are formed over the side wall portions of the gate electrodes GE.

Next, over the supporting substrate S (n⁻-type semiconductor regions 7n and 7p) exposed in the bulk region BA and over the silicon layer SR (n⁻-type semiconductor regions 7a, 7b, and 7n) exposed in the SOI region SA, the epitaxial layers EP are formed using an epitaxial growth method (FIGS. 87 to 89).

Next, as shown in FIGS. 90 to 92, in the same manner as in Embodiment 1, in the region pLA of the bulk region BA where the low-breakdown-voltage p-channel MISFET (LTp) is formed and the region pHA of the bulk region BA where the high-breakdown-voltage p-channel MISFET (HTp) is formed, the p⁺-type semiconductor regions 8p are formed. Also in the same manner as in Embodiment 1, in the region nLA of the bulk region BA where the low-breakdown-voltage n-channel MISFET (LTn) is formed, the region nHA of the bulk region BA where the high-breakdown-voltage n-channel MISFET (HTn) is formed, and the SOI region SA, the n⁺-type semiconductor regions 8a, 8b, and 8n are formed.

By the foregoing steps, in the FMONOS formation region FA of the SOI region SA, the n-type drain region MD including the n⁻-type semiconductor region 7b and the n⁺-type semiconductor region 8b and functioning as the drain region of the memory transistor is formed and the n-type source region MS including the n⁻-type semiconductor region 7a and the n⁺-type semiconductor region 8a and functioning as the source region of the memory transistor is formed. On the other hand, in the bulk region BA, the source/drain regions each having an LDD structure including a lower-concentration impurity region and a higher-concentration impurity region are formed. Also, in the SRAM formation region SRA of the SOI region SA, the source/drain regions each having an LDD structure including a lower-concentration impurity region and a higher-concentration impurity region are formed.

Next, to activate the impurities introduced in the source region MS (n⁻-type semiconductor region 7a and n⁺-type semiconductor region 8a), the drain region MD (n⁻-type semiconductor region 7b and n⁺-type semiconductor region 8b), and the source/drain regions (7n, 7p, 8n, and 8p), in the same manner as in Embodiment 1, heat treatment (activation treatment) is performed.

By the foregoing steps, the memory cells MC and the transistors Tn1 and Tn2 forming the memory cell in the SRAM are formed in the SOI region SA and the MISFETs (LTn, LTp, HTn, and HTp) are formed in the bulk region BA (see FIGS. 90 to 92).

Note that the steps of forming the memory cells MC and the steps of forming each of the MISFETs are not limited to the foregoing steps.

Thereafter, in the same manner as in Embodiment 1, using a salicide technique, a metal silicide layer (metal silicide film) SIL is formed over each of the memory gate electrode MG, the n⁺-type semiconductor region 8a, and the n⁺-type semiconductor region 8b in the FMONOS formation region FA of the SOI region SA, though the illustration thereof is omitted. The metal silicide layer (metal silicide film) SIL is also formed over each of the gate electrode GE and the n⁺-type semiconductor regions 8n in the SRAM formation region SRA of the SOI region SA. On the other hand, in the bulk region BA, the metal silicide layer SIL is formed over each of the gate electrodes GE, the n⁺-type semiconductor regions 8n, and the p⁺-type semiconductor regions 8p.

The metal silicide layers SIL can reduce resistances such as diffusion resistance and contact resistance. Subsequently, in the same manner as in Embodiment 1, the insulating film (interlayer insulating film) IL1, the plugs P1, and the first-layer interconnects M1 are formed. Then, by a dual damascene method or the like, the second-layer and higher-order-layer interconnects M2, M3, M4, plugs P2, and the like are further formed.

Thus, according to the present embodiment, the memory cells MC are placed in the SOI region SA, and the impurity region VTC(CT) for adjusting the threshold of the control transistor and the impurity region VTC(MT) for adjusting the threshold of the memory transistor are provided. This can improve the performance of the memory cell MC, as described in detail in Embodiment 1.

Also, the impurity regions VTC(CT) for adjusting the threshold of the control transistor is formed by ion-implanting a p-type impurity (such as boron (B)), and the impurity region VTC(MT) for adjusting the threshold of the memory transistor is formed by ion-implanting an n-type impurity (such as arsenic or phosphorus (P)) of the conductivity type opposite to the p-type into the region in which the p-type impurity has been ion-implanted. This facilitates the adjustment of the impurity concentrations.

Also in the present embodiment, in the SOI region SA, the transistors Tn1 and Tn2 forming the memory cell in the SRAM are formed. This can reduce a parasitic capacitance resulting from a diffusion region formed in the silicon layer. As a result, it is possible to achieve an improvement in the operating speed of a circuit formed using the memory cell in the SRAM and a reduction in the power consumed thereby. It is also possible to reduce the concentration of the impurity in the silicon layer SR. This allows reductions in random variations in the transistors Tn1 and Tn2 forming the SRAM memory cell forming the SRAM.

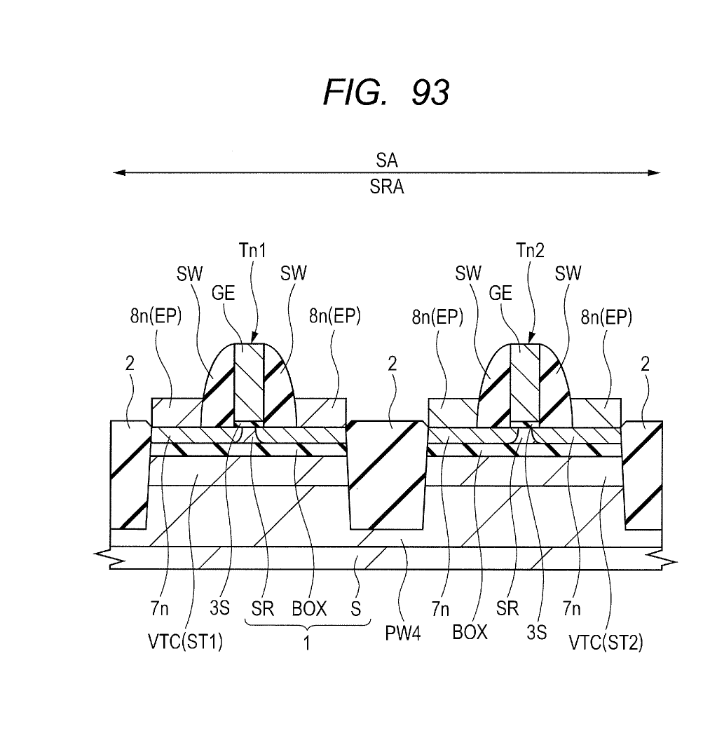

Note that, in the present embodiment, for the transistors Tn1 and Tn2 forming the memory cell in the SRAM, impurity regions for threshold adjustment are not provided. However, as shown in FIG. 93, impurity regions VTC(ST1) and VTC(ST2) for threshold adjustment may also be provided. FIG. 93 is a cross-sectional view showing another configuration of the semiconductor device of the present embodiment.

As shown in FIG. 93, in the SRAM formation region SRA of the SOI region SA, in the supporting substrate S located under the gate electrode GE and the insulating layer BOX, the impurity region VTC(ST1) for adjusting the threshold of the transistor Tn1 is formed. Also, in the supporting substrate S located under the gate electrode GE and the insulating layer BOX, the impurity region VTC(ST2) for adjusting the threshold of the transistor Tn2 is formed.

Since the impurity regions VTC(ST1) and VTC(ST2) for threshold adjustment are thus provided, the performance of the SRAM can be improved. Specifically, variations in the thresholds of the transistors (Tn1 and Tn2) forming the SRAM can be reduced. In addition, the GiDL can be reduced.

The impurity regions VTC(ST1) and VTC(ST2) for threshold adjustment can be formed by, e.g., ion-implanting an impurity for threshold adjustment into the supporting substrate S located under the insulating layers BOX in the SOI region SOI before the step of forming the gate electrodes GE of the transistors (Tn1 and Tn2).

### Embodiment 3

In the present embodiment, a description will be given of the layout of the FMONOS formation region FA of the SOI region SA. Note that the same parts as in Embodiments 1 and 2 are designated by the same reference numerals and a repeated description thereof is omitted.

### First Example

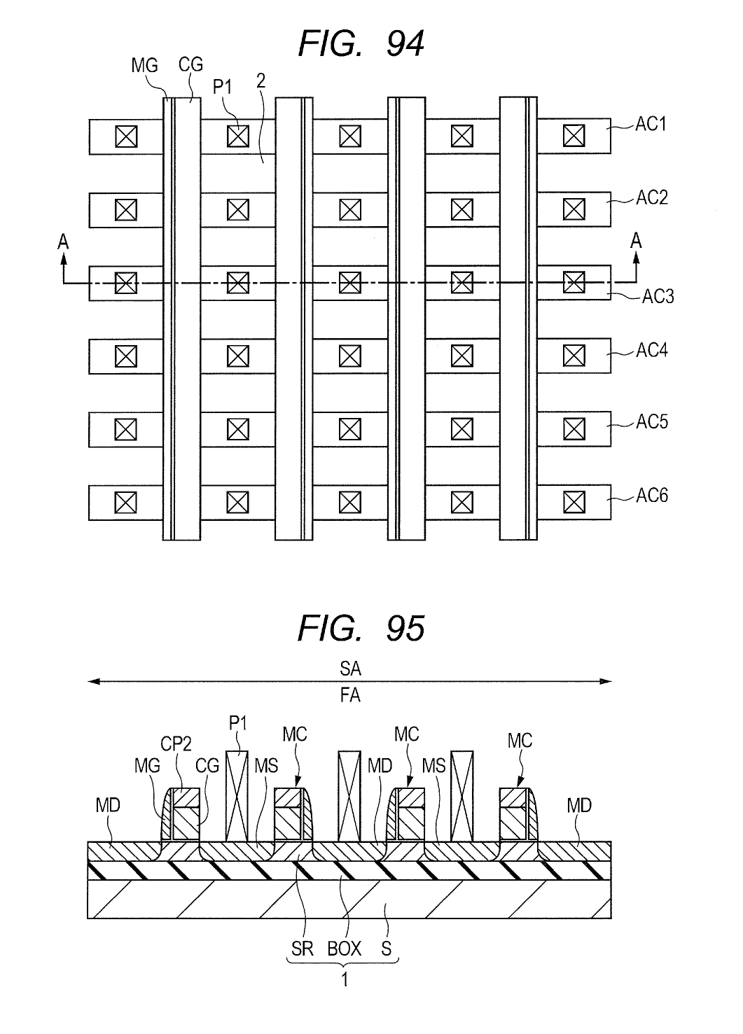

FIGS. 94 and 95 are views each showing a configuration of a semiconductor device of a first example of the present embodiment, of which FIG. 94 is a plan view and FIG. 95 is a schematic cross-sectional view. The cross-sectional view of FIG. 95 corresponds to, e.g., a cross section along the line A-A in FIG. 94.

As shown in FIG. 95, in the FMONOS formation region FA of the SOI region SA, the plurality of memory cells MC are placed. For example, on the right side of the leftmost first memory cell MC shown in FIG. 95, the second memory cell MC is placed substantially symmetrically therewith with the source region (MS) interposed therebetween. On the right side of the second memory cell MC, the third memory cell MC is placed substantially symmetrically therewith with the drain region (MD) interposed therebetween. Thus, the memory cells MC are arranged in a lateral direction (gate length direction) in FIG. 95 such that the shared source regions (MS) and the shared drain regions (MD) are alternately located to form a memory cell row.

Also, as shown in FIG. 94, in a vertical direction (gate width direction) in the drawing, the plurality of memory cell rows are arranged. Thus, the plurality of memory cells MC are arranged in an array configuration.

Here, in the first example, the active regions (AC1, AC2, AC3, AC4, AC5, and AC6) where the memory cell rows are formed are each defined by the isolation region 2. In this case, the active regions (AC1, AC2, AC3, AC4, AC5, and AC6) are each formed of the silicon layer SR including the n⁻-type semiconductor regions 7a and 7b. Consequently, the side surfaces of each of the active regions are covered with the isolation region 2, while the bottom surface of each of the active regions is covered with the insulating layer BOX.

By thus forming the memory cells MC in the SOI region SA and isolating the active regions (AC1, AC2, AC3, AC4, AC5, and AC6) where the memory cell rows are formed using the isolation region 2 on a per memory-cell-row basis, potentials in the active regions (silicon layers SR) of the individual memory cell rows can be independently controlled. As a result, it is possible to, e.g., erase data written in the memory cells MC on a per memory-cell-row (bit) basis. For example, by applying a zero potential to the active region of the selected memory cell row, applying a high potential for erasing to the memory gates MG, applying a zero potential to the control gate electrodes CG, applying an erase potential to the source regions (MS), and applying a zero potential to the drain regions (MD), it is possible to erase the data written in the memory cells MC in the selected memory cells MC. At this time, by applying a zero potential to the active regions of the unselected memory cell rows, it is possible to prevent the data written in the memory cells MC in the unselected memory cell rows from being erased.

It may also be possible to control a substrate potential via plugs coupled to the substrate. In this case, threshold potentials Vth can be individually reduced to allow an improvement in erasing speed.

### Second Example

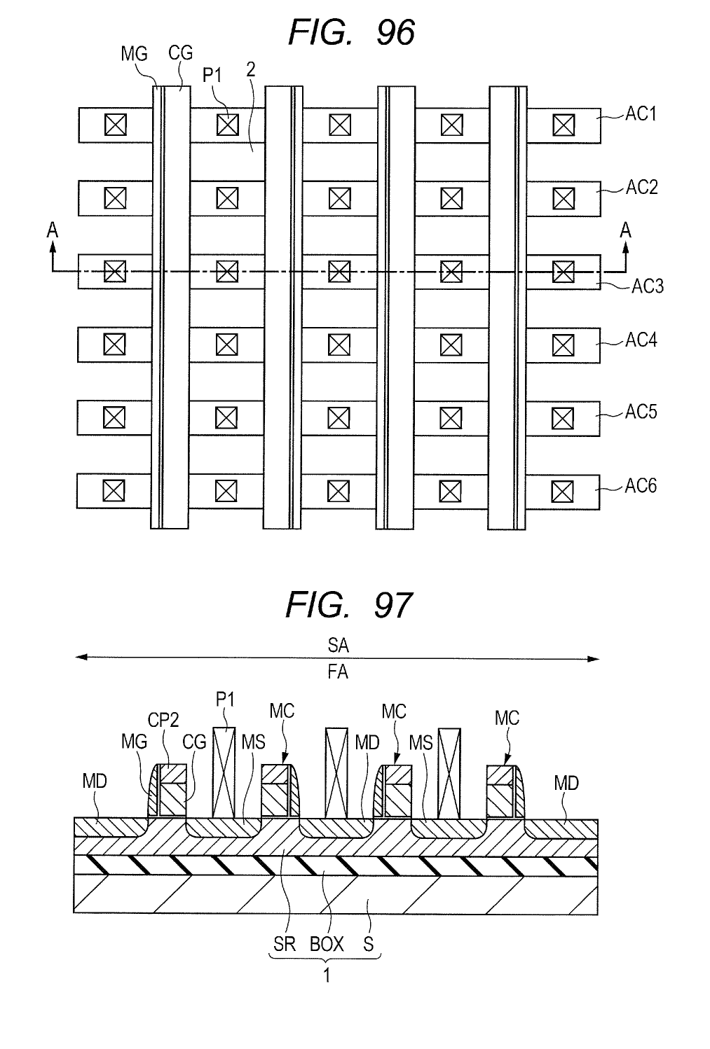

FIGS. 96 and 97 are views each showing a configuration of a semiconductor device of a second example of the present embodiment, of which FIG. 96 is a plan view and FIG. 97 is a schematic cross-sectional view. The cross-sectional view of FIG. 97 corresponds to, e.g., a cross section along the line A-A in FIG. 96.

In the first example, the complete-depletion-type memory cell MC is shown by way of example in which the bottom surfaces of the source region (MS) and the drain, region (MD) reach the bottom surface of the silicon layer SR, and the silicon layer SR therebetween is completely depleted. However, the partial-depletion-type memory cell MC may also be used.

In this case, as shown in FIG. 97, the bottom surfaces of the source region (MS) and the drain region (MD) are located at middle points in the silicon layer SR so that only a part of the silicon layer SR is depleted. For such a partial-depletion-type memory cell MC also, by isolating the active regions (AC1, AC2, AC3, AC4, AC5, and AC6) where the memory cell rows are formed using the isolation region 2 on a per memory-cell-row basis as described in detail in the first example, it is possible to erase the data written in the memory cells MC on a per memory-cell-row (bit) basis.

Note that, in Embodiments 1 and 2 also, the configuration of the partial-depletion-type memory cell MC may be used. That is, the bottom surfaces of the source region (MS) and the drain region (MD), i.e., the bottom surfaces of the n⁻-type semiconductor regions 7a and 7b may also be located at middle points in the silicon layer SR (see FIG. 4 and the like).

### Third Example

In the foregoing first and second examples, the active regions (AC1 to AC6) where the memory cell rows are formed are isolated using the isolation region 2 on a per memory-cell-row basis. However, it will be appreciated that, as described as a third example, a configuration obtained by coupling the active regions where the memory cell rows are formed to each other may also be used. In this case, data erasing is performed on a per memory-cell-array basis, but it will be appreciated that the effects according to the memory cells MC described in Embodiments 1 and 2 are achieved.

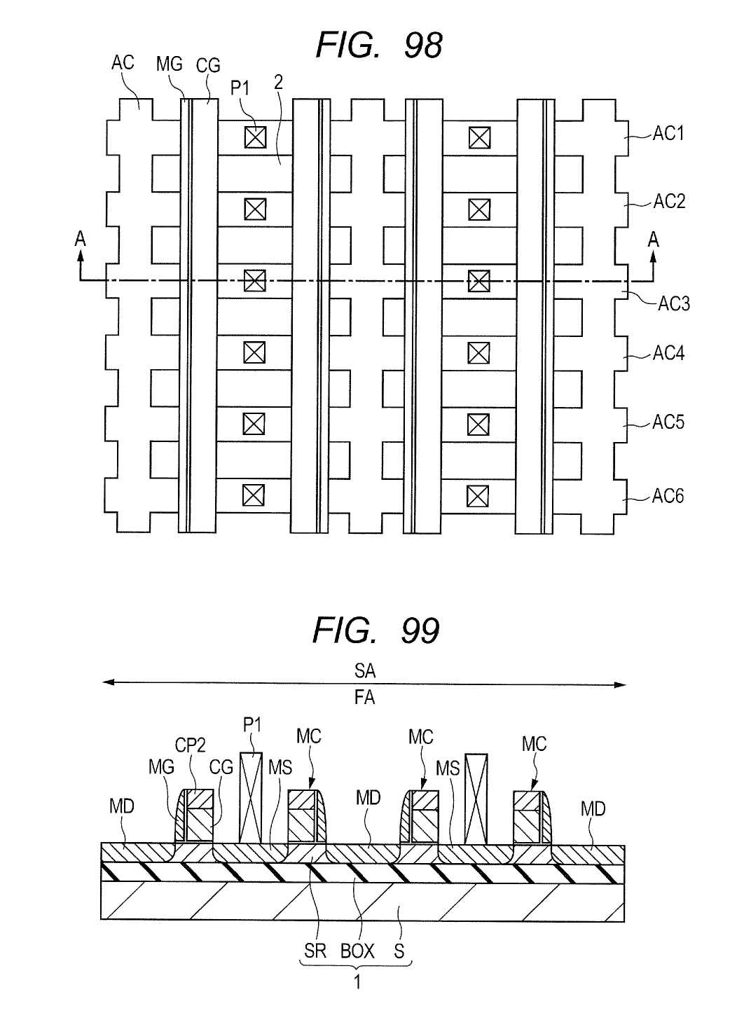

FIGS. 98 and 99 are views each showing a configuration of a semiconductor device in a third example of the present embodiment, of which FIG. 98 is a plan view and FIG. 99 is a schematic cross-sectional view. The cross-sectional view of FIG. 99 corresponds to, e.g., a cross section along the line A-A in FIG. 98.

In this case, as shown in FIG. 98, the active regions (AC1, AC2, AC3, AC4, AC5, and AC6 in FIGS. 94 and 96) where the memory cell rows are formed are coupled by coupling active regions in the drain region (MD) portion. In other words, the active regions are longitudinally and laterally arranged.

In such a configuration also, as described above, the effects according to the memory cells MC described in Embodiments 1 and 2 are achieved.

While the invention achieved by the present inventors has been specifically described heretofore based on the embodiments thereof, the present invention is not limited to the foregoing embodiments. It will be appreciated that various changes and modifications can be made in the invention within the scope not departing from the gist thereof.

What is claimed is:

1. A semiconductor device, comprising:
a substrate having a semiconductor substrate, an insulating layer formed over the semiconductor substrate, and a semiconductor layer formed over the insulating layer;
a first gate electrode formed above the semiconductor layer;
a second gate electrode formed above the semiconductor layer so as to be adjacent to the first gate electrode;
a first insulating film formed between the first gate electrode and the semiconductor layer;
a second insulating film formed between the second gate electrode and the semiconductor layer and having a charge storage portion therein;
a first semiconductor region formed in the semiconductor substrate under the first gate electrode; and
a second semiconductor region formed in the semiconductor substrate under the second gate electrode and having an effective carrier concentration lower than that of the first semiconductor region.

2. A semiconductor device according to claim 1,
wherein the second insulating film is formed of a laminate film of a first oxide film, a nitride film, and a second oxide film.

3. A semiconductor device according to claim 2,
wherein a thickness of the laminate film is larger than a thickness of the first insulating film.

4. A semiconductor device according to claim 3,
wherein the first semiconductor region contains an impurity of a first conductivity type, and
wherein the second semiconductor region contains the impurity of the first conductivity type and an impurity of a second conductivity type opposite to the first conductivity type.

5. A semiconductor device according to claim 4,
wherein a bottom surface of the second semiconductor region is located at a position shallower than that of a bottom surface of the first semiconductor region.

6. A semiconductor device, comprising:
a substrate including a semiconductor substrate having a first region and a second region, an insulating layer formed over the first region of the semiconductor substrate, and a semiconductor layer formed over the insulating film;
a first element formed in main surface of the semiconductor layer located in the first region; and
a second element formed in a main surface of the semiconductor substrate located in the second region,
wherein the first element includes:
a first gate electrode formed above the semiconductor layer;
a second gate electrode formed above the semiconductor layer so as to be adjacent to the first gate electrode;
a first insulating film formed between the first gate electrode and the semiconductor layer;
a second insulating film formed between the second gate electrode and the semiconductor layer and having a charge storage portion therein;
a first semiconductor region formed in the semiconductor substrate under the first gate electrode; and
a second semiconductor region formed in the semiconductor substrate, under the second gate electrode and having an effective carrier concentration lower than that of the first semiconductor region, and
wherein the second element includes:
a third gate electrode formed above the semiconductor substrate; and
a third insulating film formed between the third gate electrode and the semiconductor substrate.

7. A semiconductor device according to claim 6,
wherein the second insulating film is formed of a laminate film of a first oxide film, a nitride film, and a second oxide film.

8. A Semiconductor device according to claim 7,
wherein a thickness of the laminate film is larger than a thickness of the first insulating film.

9. A semiconductor device according to claim 8,
wherein the first semiconductor region contains an impurity of a first conductivity type, and
wherein the second semiconductor region contains the impurity of the first conductivity type and an impurity of a second conductivity type opposite to the first conductivity type.

10. A semiconductor device according to claim 9,
wherein a bottom surface of the second semiconductor region is located at a position shallower than that of a bottom surface of the first semiconductor region.

11. A semiconductor device according to claim 6, further comprising:
a third element formed in the main surface of the semiconductor substrate located in the second region,
wherein the third element includes:
a fourth gate electrode formed above the semiconductor substrate; and
a fourth insulating film formed between the fourth gate electrode and the semiconductor substrate.

12. A semiconductor device according to claim 11,
wherein a gate length of the fourth gate electrode is shorter than a gate length of the third gate electrode.

13. A semiconductor device according to claim 6, further comprising:
a fourth element formed in the main surface of the semiconductor layer located in the first region,
wherein the fourth element includes:
a fifth gate electrode formed above the semiconductor layer; and
a fifth insulating film formed between the fifth gate electrode and the semiconductor layer.

14. A semiconductor device according to claim 13,
wherein the fourth element is a MISFET forming a SRAM.

15. A method of manufacturing a semiconductor device, comprising the steps of:
(a) providing a substrate having a semiconductor substrate, an insulating layer formed over the semiconductor substrate, and a semiconductor layer formed over the insulating layer;
(b) ion-implanting an impurity of a first conductivity type into the semiconductor substrate through the semiconductor layer and the insulating layer to form a first semiconductor region;
(c) forming a first gate electrode over the semiconductor layer located above the first semiconductor region via a first insulating film;
(d) ion-implanting an impurity of a second conductivity type opposite to the first conductivity type using the first gate electrode as a mask to form a second semiconductor region in the first semiconductor region; and
(e) forming a second gate electrode over the semiconductor layer located above the second semiconductor region via a second insulating film.

16. A method of manufacturing a semiconductor device according to claim 15,
wherein the second semiconductor region has an effective carrier concentration lower than that of the first semiconductor region.

17. A method of manufacturing a semiconductor device according to claim 16,
wherein the second insulating film is formed of a laminate film of a first oxide film, a nitride film, and a second oxide film.

18. A method of manufacturing a semiconductor device according to claim 17,
wherein a thickness of the laminate film is larger than a thickness of the first insulating film.

19. A method of manufacturing a semiconductor device according to claim 15,
wherein the impurity of the second conductivity type has an atomic weight larger than that of the impurity of the first conductivity type.

20. A method of manufacturing a semiconductor device according to claim 15, further comprising the step of:
(f) removing the semiconductor layer and the insulating layer from a region in a part of the substrate.
